(19) United States
(12) Patent Application Publication
(10) Pub. No.: US 2019/0334099 A1
(43) Pub. Date: Oct. 31, 2019

(54) TRANSITION METAL COMPLEX AND APPLICATION THEREOF, MIXTURE AND ORGANIC ELECTRONIC DEVICE

(71) Applicant: GUANGZHOU CHINARAY OPTOELECTRONIC MATERIALS LTD., Guangzhou (CN)

(72) Inventors: Chi Ming LEUNG, Guangzhou (CN); Hong HUANG, Guangzhou (CN); Junyou PAN, Guangzhou (CN)

(73) Assignee: GUANGZHOU CHINARAY OPTOELECTRONIC MATERIALS LTD., Guangzhou (CN)

(21) Appl. No.: 16/440,503

(22) Filed: Jun. 13, 2019

Related U.S. Application Data
(63) Continuation of application No. PCT/CN2017/115983, filed on Dec. 13, 2017.

(30) Foreign Application Priority Data
Dec. 13, 2016 (CN) CN201611147271.5

(51) Int. Cl. H01L 51/00; C07F 15/00; C09K 11/06

(52) U.S. Cl. CPC H01L 51/0085; H01L 51/5088; C09K 11/06; C07F 15/0033

(57) ABSTRACT

A transition metal complex and an application thereof, a mixture and an organic electronic device, the structure of the transition metal complex being represented by general formula (I), wherein the definition of the symbols in general formula (I) is the same as that provided in the description.

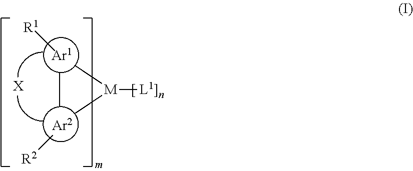

The present application is a continuation application of International Application No. PCT/CN2017/115983, filed on Dec. 13, 2017, which claims priority benefit of Chinese Patent Application No. 201611147271.5, entitled “A Transition Metal Complex Material and Application thereof in Electronic Devices”, filed on Dec. 13, 2016. The entire contents of both aforementioned applications are herein incorporated by reference for all purposes.

### TECHNICAL FIELD

The present disclosure relates to the technical field of organic optoelectronic materials, and in particular to a transition metal complex and its application, mixture and organic electronic device.

### BACKGROUND

In flat-panel display and lighting applications, Organic Light-Emitting Diode (OLED) has the advantages of low cost, light weight, low operating voltage, high brightness, color adjustability, wide viewing angle, ease of assembly onto flexible substrates, and low energy consumption, thus it has become the most promising display technology. In order to improve the luminous efficiency of the organic light-emitting diode, various light-emitting material systems based on fluorescence and phosphorescence have been developed. The organic light-emitting diode using fluorescent materials has high reliability, but its internal electroluminescence quantum efficiency is limited to 25% under electric field excitation. In contrast, since the branching ratio of singlet excited state to triplet excited state of the exciton is 1:3, an organic light-emitting diode using phosphorescent materials can achieve an internal luminescence quantum efficiency of almost 100%. For small molecule OLEDs, the triplet excitation is effectively obtained by doping the heavy metal center so as to improve the spin orbital coupling, resulting in the intersystem crossing to triplet state.

Complexes based on the metal iridium (III) are a class of materials widely used for high efficiency OLEDs, which have relatively high efficiency and stability. Baldo et al. reported an OLED with high quantum efficiency using fac-tris(2-phenylpyridine)iridium(III) [Ir(ppy)₃] as phosphorescent materials, and 4,4′-N, N′-dicarbazole-1,1′-biphenyl (CBP) as matrix materials (Appl. Phys. Lett. 1999, 75, 4). Another example of phosphorescent materials is the sky blue complex, bis[2-(4′,6′-difluorophenyOpyridinato-N,C2]-picolinate iridium-(III) (Flrpic), which exhibits extremely high photoluminescence quantum efficiency of approximately 60% in solution and almost 100% in solid film when it is doped into high triplet energy matrix (Appl. Phys. Lett. 2001, 79, 2082). Although iridium (III) systems based on 2-phenylpyridine and its derivatives have been widely used for the fabrication of OLEDs, the device performance, particularly lifetime, still needs to be improved.

One of the effective ways to improve the luminous efficiency and stability of complexes is to use ligands with a rigid structure. Thompson group reported a iridium complex Ir(BZQ)2(acac) which is based on the rigid ligand BZQ (Benzo[h]quinolone-C2,N′) in 2001, but it has not been widely used due to its poor emitting color and the like. Thereafter, the rigid ligand-based iridium complexes Ir(DBQ)₂ (acac), Ir(MDQ)₂ (acac), and the like have been reported (DBQ=Dibenzo[f,h]quinoxaline, MDQ=Methyldibenzo[f,h]quinoxaline). These organic electroluminescent devices prepared by iridium complexes with rigid ligands used as the guest luminescent material have very high luminescent efficiency and brightness. On the other hand, when the iridium complexes Ir(DBA)₂(acac) and Ir(BA)₂(acac) based on the rigid ligands DBA (5,6-Dihydro-benzo[c]acridine) and BA (Benzo[c]acridine) are respectively used for preparing light-emitting devices, the maximum brightness and the maximum external quantum efficiency of the devices are only 9,540 cd·m⁻² and 4.66%. Although saturated red light is achieved, the efficiency and the brightness of the device are quite far behind the expectation.

### SUMMARY

According to various embodiments of the present application, a transition metal complex and its application, mixture, organic electronic device are provided, and one or more of the problems involved in the background are solved.

A transition metal complex for organic electronic devices has a structure represented by general formula (I):

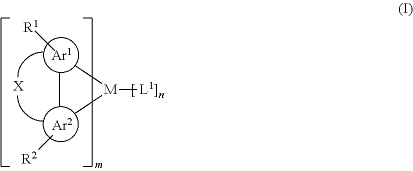

wherein

M is a metal atom selected from the group consisting of iridium, gold, platinum, ruthenium, rhodium, osmium, rhenium, nickel, copper, silver, zinc, tungsten or palladium;

m is selected from 1, 2 or 3;

L¹ is an auxiliary ligand selected from bidentate chelating ligand.

n is 0, 1 or 2;

Ar¹ is selected from the group consisting of an aromatic containing 5 to 20 ring atoms, a heteroaromatic containing 5 to 20 ring atoms, or a non-aromatic ring system containing 5 to 20 ring atoms; the Ar¹ has a substituent R¹, and R¹ is the same or different in multiple occurrences;

Ar² is selected from the group consisting of an aromatic containing 5 to 20 ring atoms, a heteroaromatic containing 5 to 20 ring atoms, or a non-aromatic ring system containing 5 to 20 ring atoms; the Ar² has a substituent R², and R² is the same or different in multiple occurrences;

X is selected from a non-aromatic doubly-bridging group;

R¹ and R² are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms.

A polymer in which at least one repeating unit includes the transition metal complex described above is provided.

A mixture including at least one organic functional material and the above transition metal complex or the above polymer is provided; the organic functional material is selected from the group consisting of a hole injection material, a hole transport material, an electron transport material, an electron injection material, an electron blocking material, a hole blocking material, emitter, a host material, or a doped material.

A formulation comprising an organic solvent and the above transition metal complex or the above polymer or the above mixture is provided.

Use of the above transition metal complex or the above polymer or the above mixture or the above formulation in organic electronic devices is provided.

An organic electronic device comprising the above transition metal complex or the above polymer or the above mixture is provided.

The details of one or more embodiments of the present disclosure are set forth in the accompanying drawings and the description below. Other features, objects and advantages of the present disclosure will become apparent from the description, the accompanying drawings, and the claims.

### BRIEF DESCRIPTION OF THE DRAWINGS

In order to better illustrate the technical solutions in the embodiments of the present application or the prior art, the accompanying drawings used in the embodiments or the prior art description are briefly described below. Obviously, the drawings in the following description are only several embodiments of the present application, while it will be understood that other drawings may be obtained according to these drawings without any inventive step for those skilled in the art.

FIG. 1 is an emission spectrum of the complexes of each embodiment.

### DETAILED DESCRIPTION OF THE EMBODIMENTS

The objects, technical solution and advantages of the present application will become more apparent and understandable by further describing the present disclosure in detail with reference to the accompanying drawings and embodiments. It should be noted that, the specific embodiment illustrated herein is merely for the purpose of explanation, and should not be deemed to limit the disclosure.

Formulation, printing ink and ink herein, have the same meaning and may be used interchangeably. Host material, matrix material, Host or Matrix material herein have the same meaning and they can be used interchangeably. Metal organic clathrate, transition metal complex, and organic metal complex herein have the same meaning and are interchangeable.

A transition metal complex of an embodiment for organic electronic devices has a structure represented by formula (I):

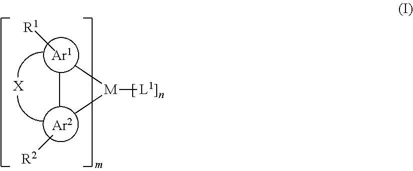

wherein

M is a metal atom selected from the group consisting of iridium, gold, platinum, ruthenium, rhodium, osmium, rhenium, nickel, copper, silver, zinc, tungsten or palladium;

m is selected from 1, 2 or 3;

L¹ is an auxiliary ligand selected from bidentate chelating ligand.

n is 0, 1 or 2;

Ar¹ is the same or different at each occurrence, selected from the group consisting of an aromatic containing 5 to 20 ring atoms, a heteroaromatic containing 5 to 20 ring atoms, or a non-aromatic ring system containing 5 to 20 ring atoms; the Ar¹ has a substituent R¹, and R¹ is the same or different in multiple occurrences;

Ar² is the same or different at each occurrence, selected from the group consisting of an aromatic containing 5 to 20 ring atoms, a heteroaromatic containing 5 to 20 ring atoms, or a non-aromatic ring system containing 5 to 20 ring atoms; the Ar² has a substituent R², and R² is the same or different in multiple occurrences;

X is selected from a non-aromatic doubly-bridging group;

R¹ and R² are independently selected from the group consisting of hydrogen, deuterium, a halogen atom, a linear alkyl group containing 1 to 20 carbon atoms, a branched alkyl group containing 1 to 20 carbon atoms, a linear alkenyl group containing 1 to 20 carbon atoms, a branched alkenyl group containing 1 to 20 carbon atoms, an alkane ether containing 1 to 20 carbon atoms, an aromatic containing 1 to 20 carbon atoms, a heteroaromatic containing 1 to 20 carbon atoms or a non-aromatic ring system containing 1 to 20 carbon atoms.

It should be noted that, L¹ may be the same or different in multiple occurrences. X may be the same or different in multiple occurrences.

The use of the above transition metal complex in OLED, particularly as a dopant in emissive layer, can provide higher efficiency and device lifetime. It is because such transition metal complex with novel structure comprises heteroatomic rigid ligand. Since such ligand increases the additional cyclization and linkage between the pyridine ring and the benzene ring, the rigidity of the molecule is enhanced relative to the general 2-phenylpyridine ligand. Hence, the whole complex has better chemical, optical, electrical and thermal stability. The heteroatom in the ring is linked to the pyridine ring, thus the wavelength of the maximum emission peak can be effectively adjusted, and a more saturated and more stable emitting color can be achieved.

In an embodiment, M is selected from the group consisting of ruthenium, rhodium, palladium, gold, osmium, rhenium, iridium or platinum. Further, M is selected from iridium, gold, or platinum. Further, M is specifically selected from iridium.

In terms of heavy atom effect, it is particularly preferred to use iridium as the metal center M of the above transition metal complex. This is because iridium is chemically stable and has significant heavy atom effect resulting in high luminescence efficiency.

In an embodiment, m is 2 or 3. Further, m is 2. In an embodiment, n is 0 or 1. Further, n is 1.

In an embodiment, Ar¹ is selected from the group consisting of a substituted or unsubstituted aromatic containing 5 to 20 ring atoms, or a substituted or unsubstituted heteroaromatic containing 5 to 20 ring atoms. In an embodiment, Ar¹ is selected from the group consisting of a substituted or unsubstituted aromatic containing 5 to 18 ring atoms, or a substituted or unsubstituted heteroaromatic containing 5 to 18 ring atoms. In an embodiment, Ar¹ is selected from the group consisting of a substituted or unsubstituted aromatic containing 5 to 12 ring atoms, or a substituted or unsubstituted heteroaromatic containing 5 to 12 ring atoms.

In an embodiment, Ar² is selected from a substituted or unsubstituted heteroaromatic ring containing 5 to 20 ring atoms, which comprises at least one ring heteroatom N. In an embodiment, Ar² is selected from a substituted or unsubstituted heteroaromatic ring containing 5 to 18 ring atoms, which comprises at least one ring heteroatom N. In an embodiment, Ar² is selected from a substituted or unsubstituted heteroaromatic ring containing 5 to 14 ring atoms, which comprises at least one ring heteroatom N. In an embodiment, Ar² is selected from a substituted or unsubstituted heteroaromatic ring containing 5 to 12 ring atoms, which comprises at least one ring heteroatom N.

The aromatic group refers to a hydrocarbon group containing at least one aromatic ring, including monocyclic group and polycyclic ring system. A heteroaromatic group refers to a hydrocarbon group (containing a heteroatom) containing at least one heteroaromatic ring, including monocyclic group and polycyclic ring system. Such polycyclic rings may have two or more rings wherein two carbon atoms are shared by two adjacent rings, i.e., a fused ring. At least one ring of such polycyclic ring is aromatic or heteroaromatic. For the purpose of the present disclosure, the aromatic or heteroaromatic ring systems not only include aromatic or heteroaromatic systems, but also have a plurality of aryl groups or heteroaryl groups interrupted by short non-aromatic units (<10% of non-H atoms, such as C, N or O atoms). Therefore, systems such as 9,9′-spirobifluorene, 9,9-diarylfluorene, triarylamine, diaryl ether and the like are also considered to be aromatic ring systems for the purpose of this disclosure. In an embodiment, a plurality of aryl groups or heteroaryl groups may also be spaced by short non-aromatic units (<5% of non-H atoms).

Specifically, the aromatic groups may be selected from benzene, naphthalene, anthracene, phenanthrene, perylene, tetracene, pyrene, benzopyrene, triphenylene, acenaphthene, fluorene, or derivatives thereof.

Specifically, examples of the heteroaromatic group may include: furan, benzofuran, thiophene, benzothiophene, pyrrole, pyrazole, triazole, imidazole, oxazole, oxadiazole, thiazole, tetrazole, indole, carbazole, pyrroloimidazole, pyrrolopyrrole, thienopyrrole, thienothiophene, furopyrrole, furofuran, thienofuran, benzoisoxazole, benzoisothiazole, benzoimidazole, pyridine, pyrazine, pyridazine, pyrimidine, triazine, quinoline, isoquinoline, o-diazonaphthalene, quinoxaline, phenanthridine, perimidine, quinazoline, quinazolinone, or derivatives thereof.

In an embodiment, Ar¹ or Ar² is selected from an unsubstituted or R substituted non-aromatic ring system containing 5 to 20 ring atoms. One possible benefit of this embodiment is that the triplet excited state energy level of the metal complex can be increased, thus the acquisition of green or blue light emitters can be facilitated.

For the purpose of the present disclosure, the non-aromatic ring system contains 1 to 10 carbon atoms in the ring system and includes not only a saturated but also a partially unsaturated cyclic system, which may be unsubstituted or monosubstituted or polysubstituted by the group R, and the group R may be the same or different at each occurrence. In an embodiment, the non-aromatic ring system contains 1 to 3 carbon atoms in the ring system. In an embodiment, the non-aromatic ring system may also contain one or more heteroatoms. Wherein, the heteroatom is one or more selected from Si, N, P, O, S, and Ge. In an embodiment, the heteroatom is one or more selected from Si, N, P, O and S. These may be, for example, a cyclohexyl-like or piperidine-like system, also may be a cyclooctadiene-like cyclic system. The term is also suitable for the fused non-aromatic ring system. In an embodiment, the non-aromatic ring system contains 1 to 6 carbon atoms in the ring system.

In an embodiment, R is selected from the group consisting of: (1) a C1-C10 alkyl, wherein C1-C10 alkyl may refer to the following groups: methyl, ethyl, n-propyl, isopropyl, cyclopropyl, n-butyl, isobutyl, sec-butyl, tert-butyl, cyclobutyl, 2-methylbutyl, n-pentyl, n-hexyl, cyclohexyl, n-heptyl, cycloheptyl, n-octyl, cyclooctyl, 2-ethylhexyl, trifluoromethyl, pentafluoromethyl, 2,2,2-trifluoroethyl, vinyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl or octynyl; (2) a C1-C10 alkoxy group, wherein the C1-C10 alkoxy group may be methoxyl, ethoxyl, n-propoxyl, isopropoxyl, n-butoxyl, isobutoxyl, or sec-butoxyl, tert-butoxyl or 2-methylbutoxyl; (3) a C2 to C10 aryl or heteroaryl, which may be monovalent or divalent depending on the use, and may also be substituted by the above-mentioned group R¹⁰ and may be attached to an aromatic or heteroaromatic ring at any desired position in each case. In an embodiment, C2 to C10 aryl or heteroaryl is selected from the following groups: benzene, naphthalene, anthracene, pyrene, dihydropyrene, chrysene, perylene, fluoranthene, naphthacene, pentacene, benzopyrene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthoimidazole, phenanthroimidazole, pyridinimidazole, pyrazinoimidazole, quinoxalinimidazole, oxazole, benzoxazole, naphthoxazole, anthracoxazole, phenanthroxazole, isoxazole, 1,2-thiazole, 1,3-thiazole, benzothiazole, pyridazine, benzopyridazine, pyrimidine, benzopyrimidine, quinoxaline, pyrazine, phenazine, 1,5-naphthyridine, nitrocarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine or benzothiadiazole. For the purposes of the present disclosure, aromatic and heteroaromatic ring systems are considered to be particularly the above-mentioned aryl groups and heteroaryl groups, but also to biphenylene, triphenylene, fluorene, spirobifluorene, dihydrophenanthrene, tetrahydropyrene and cis- or trans-indenofluorene.

In an embodiment, Ar¹ and Ar² are independently selected from any one of the following groups:

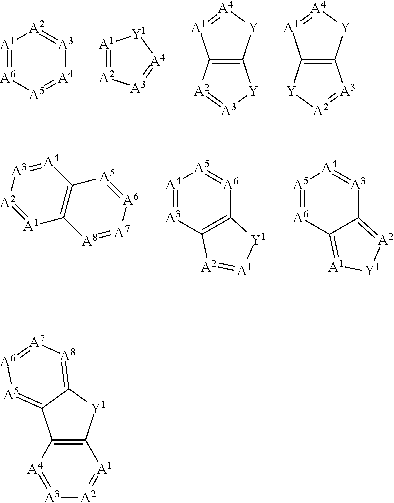

wherein, A¹ to A⁸ are independently selected from CR3 or N;

Y¹ is selected from CR₄R₅, SiR₄R₅, NR₃, C(═O), S or O;

R₃, R₄, and R₅ are independently selected from one or more of the group consisting of H, D, a linear alkyl group containing 1 to 20 C atoms, an alkoxy group containing 1 to 20 C atoms, a thioalkoxy group containing 1 to 20 C atoms, a branched or cyclic alkyl group containing 3 to 20 C atoms, a branched or cyclic alkoxy group containing 3 to 20 C atoms, a branched or cyclic thioalkoxy group containing 3 to 20 C atoms, a branched or cyclic silyl group containing 3 to 20 C atoms, a substituted ketone group containing 1 to 20 C atoms, an alkoxycarbonyl group containing 2 to 20 C atoms, an aryloxycarbonyl group containing 7 to 20 C atoms, a cyano group, a carbamoyl group, a haloformyl group, a formyl group, an isocyano group, an isocyanate group, a thiocyanate group, an isothiocyanate group, a hydroxyl group, a nitro group, a CF₃ group, Cl, Br, F, a crosslinkable group, a substituted or unsubstituted aromatic ring system containing 5 to 40 ring atoms or substituted or unsubstituted heteroaromatic ring system containing 5 to 40 ring atoms, and a aryloxy group containing 5 to 40 ring atoms or heteroaryloxy group containing 5 to 40 ring atoms; at least one of the R₃, R₄ and R₅ may form a monocyclic aliphatic or aromatic ring, or polycyclic aliphatic or aromatic ring with the ring bonded to the groups, or at least two of the R₃, R₄ and R₅ form a monocyclic aliphatic or aromatic ring, or polycyclic aliphatic or aromatic ring with each other.

In an embodiment, Ar¹ and Ar² are independently selected from any one of the following groups. Wherein, H on the ring may be arbitrarily substituted.

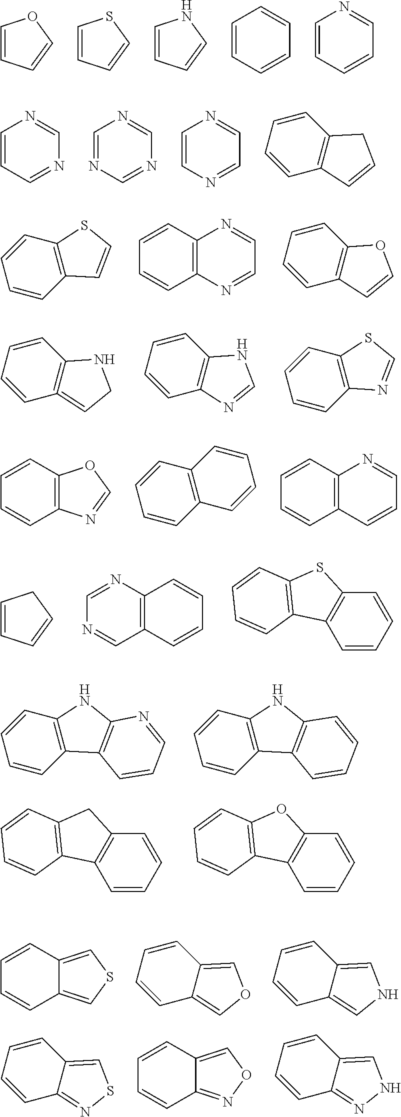

In an embodiment, Ar¹ is selected from any one of the following groups:

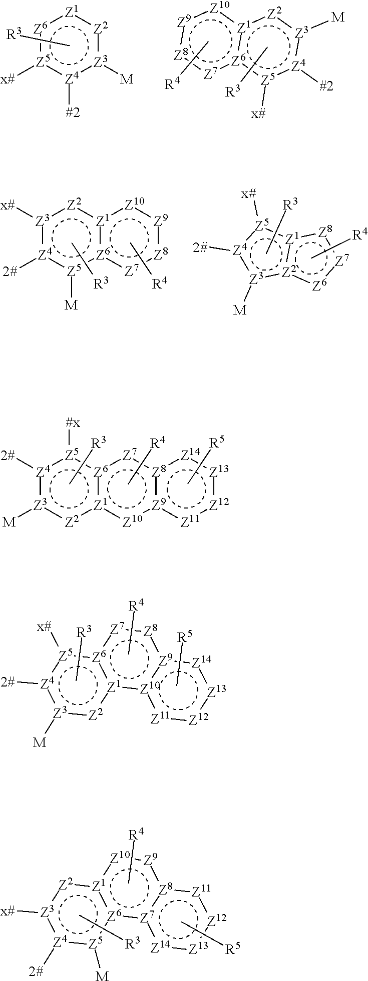

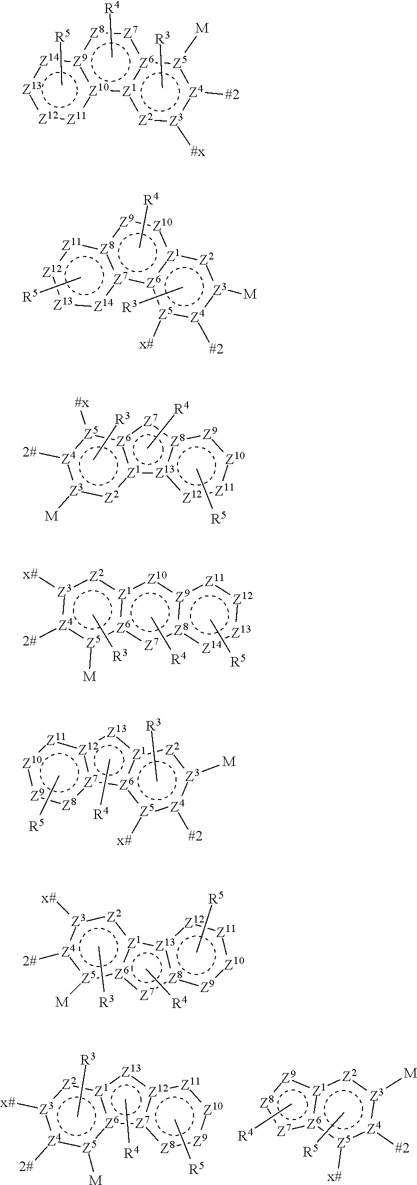

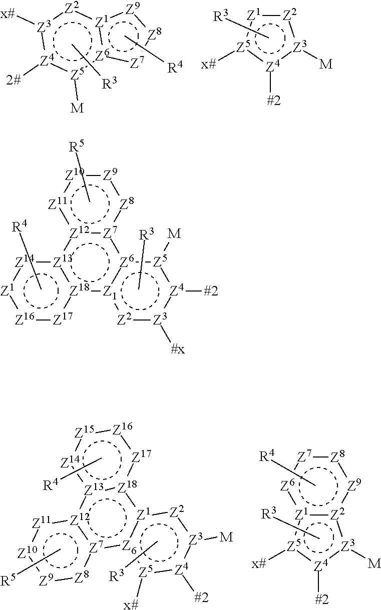

wherein #x indicates bonding to any one of the positions of the X; #2 indicates bonding to any one of the positions of the Are;

Z¹-Z¹⁸ independently contain at least one nitrogen, oxygen, carbon, silicon, boron, sulfur or phosphorus atom;

R³-R⁵ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms. It should be noted that Z¹-Z¹⁸ may independently be the same or different in multiple occurrences. R³-R⁵ may independently be the same or different in multiple occurrences.

In an embodiment, Ar² is selected from any one of the following groups:

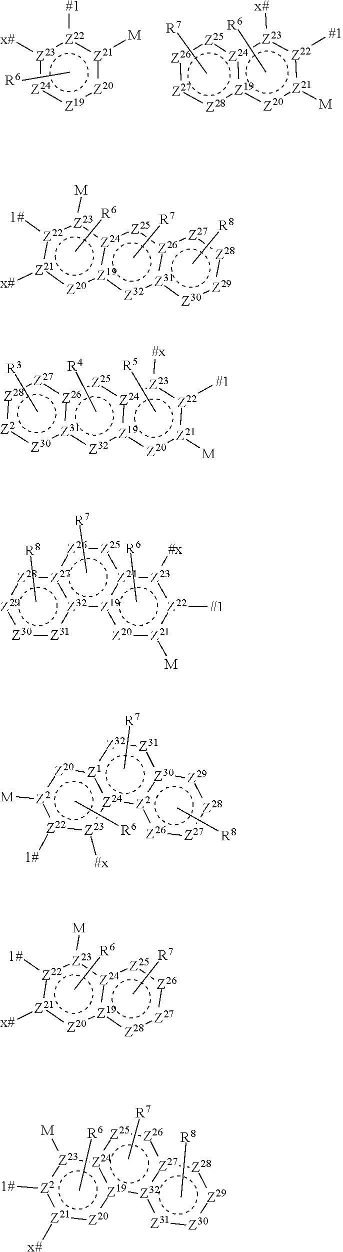

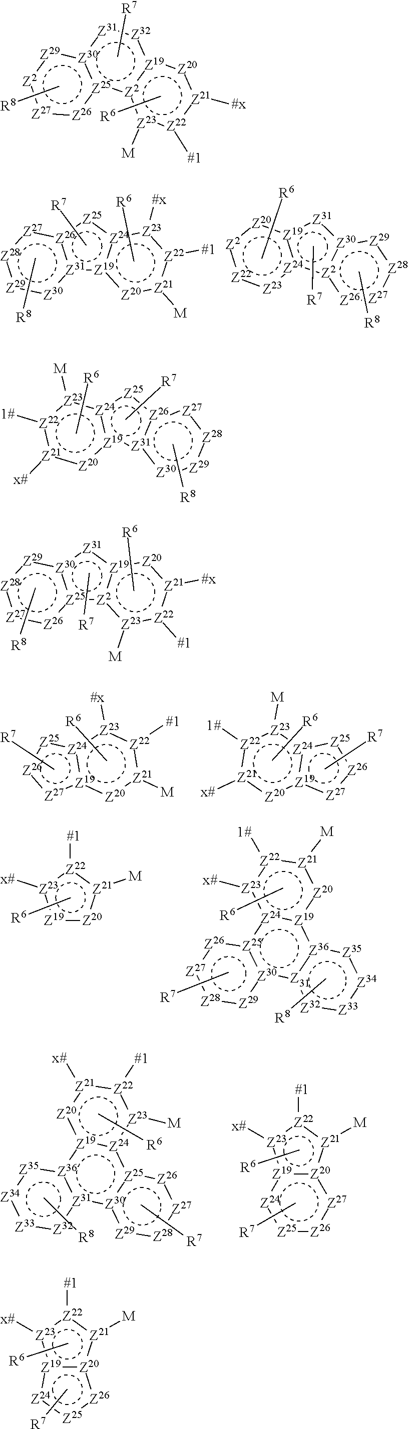

wherein #x indicates bonding to any one of the positions of the X; #1 indicates bonding to any one of the positions of the Ar¹;

Z¹⁹-Z³⁶ independently contain at least one nitrogen, oxygen, carbon, silicon, boron, sulfur or phosphorus atom;

R⁶-R⁸ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms.

It should be noted that M is selected from gold, platinum or palladium. In an embodiment, M is selected from gold.

In an embodiment, X may be the same or different in multiple occurrences, selected from the group consisting of a linear alkyl group containing 0 to 2 carbon atoms, a branched alkyl group containing 0 to 2 carbon atoms, a linear alkenyl group containing 0 to 2 carbon atoms, a branched alkenyl group containing 0 to 2 carbon atoms, an alkane ether group containing 0 to 2 carbon atoms, O, S, S═O, SO₂, N(R), B(R), Si(R)₂, Ge(R)₂, P(R), P(═O)R, P(R)₃, Sn(R)₂, C(R)₂, C═0, C═S, C═Se, C═N(R)₂ or C═C(R)₂. Wherein, R is selected from the group consisting of hydrogen, deuterium, a halogen atom, a linear alkyl group containing 1 to 20 carbon atoms, a branched alkyl group containing 1 to 20 carbon atoms, an alkane ether group containing 1 to 20 carbon atoms, an alkane aromatic ring system containing 1 to 20 carbon atoms, a alkyl heteroaromatic containing 1 to 20 carbon atoms or an alkyl non-aromatic ring system containing 1 to 20 carbon atoms. In an embodiment, X contains at least one non-carbon atom.

In an embodiment, X is selected from any one of the following groups:

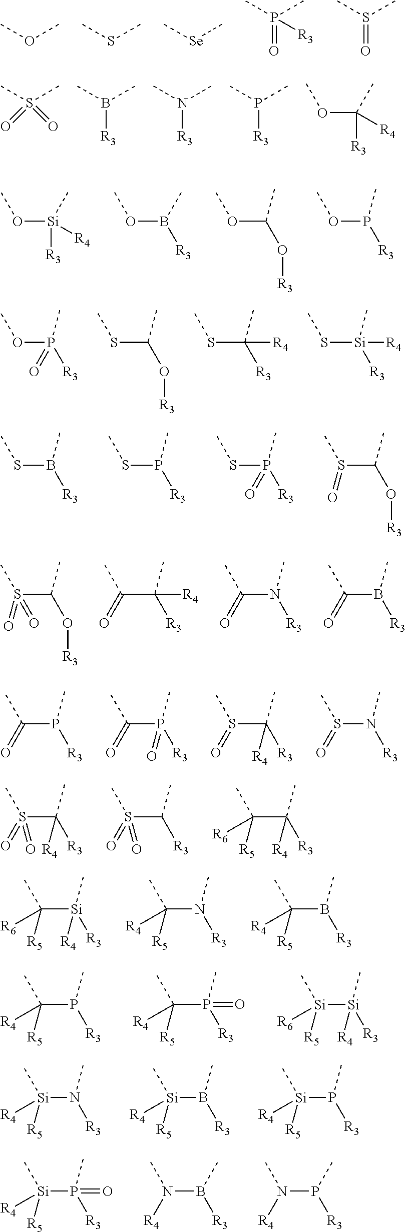

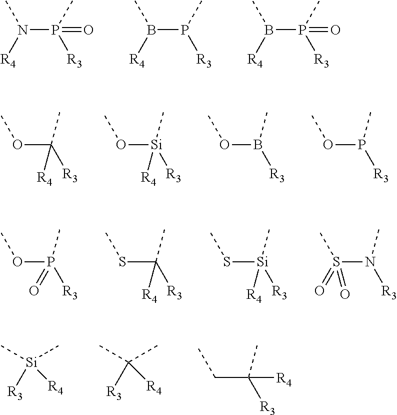

wherein, the symbols R₃, R₄, and R₅, R₆ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms; the dotted line represents a bond bonded to the Ar¹ or Ar².

In an embodiment, the transition metal complex is one selected from the complexes represented by the general formulas (I-1) to (I-12).

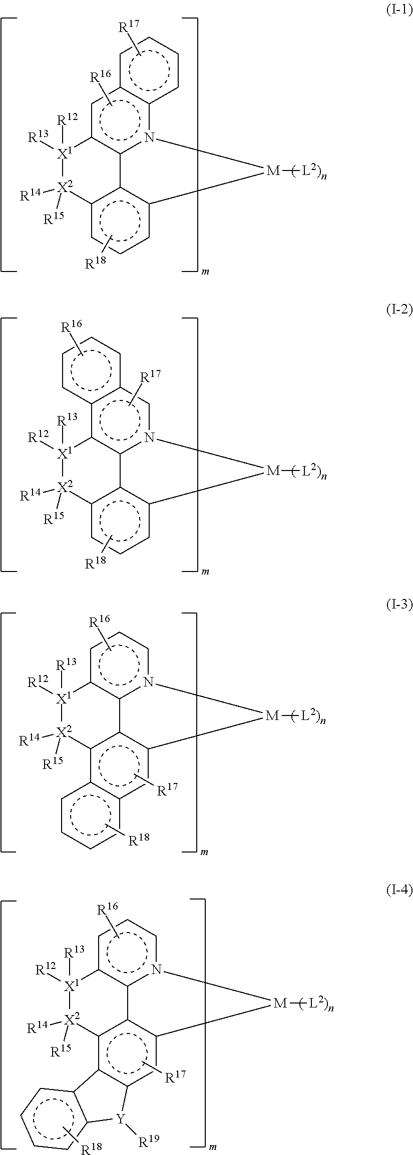

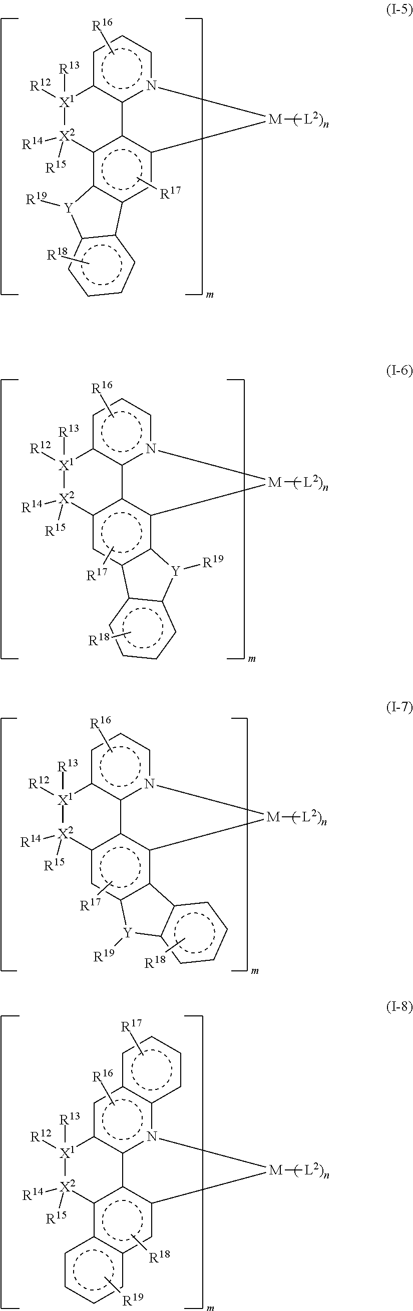

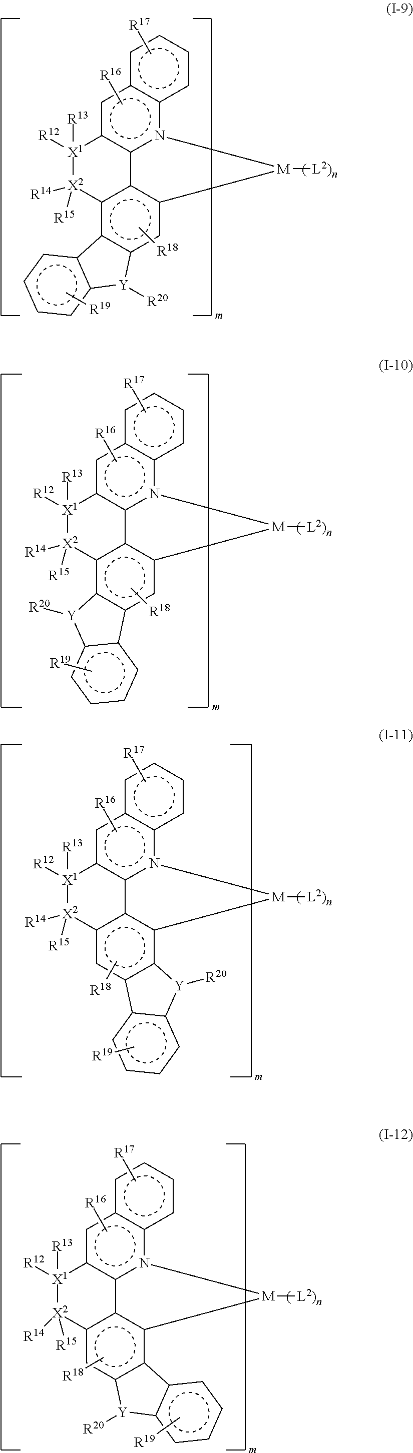

Wherein X¹ and X² independently contain at least one non-carbon heteroatom selected from nitrogen, oxygen, silicon, boron, sulfur or phosphorus atoms;

Y is the same or different, selected from doubly-bridging group in multiple occurrences.

L² is an auxiliary ligand selected from bidentate chelating ligand.

R¹²-R²⁰ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms.

In an embodiment, Y contains at least one of the group consisting of nitrogen, oxygen, carbon, silicon, boron, sulfur or phosphorus atom. Further, Y is selected from oxygen, sulfur, or silicon atom. In an embodiment, X¹ and X² independently contain at least one oxygen atom.

In an embodiment, X¹ and X² are different structural units, and X¹ and/or X² comprise heteroatoms containing a non-carbon atom.

In an embodiment, Y is selected from the groups listed above for the X.

In an embodiment, the following doubly-bridging group formed by X¹ and X² is one of the doubly-bridging groups listed above for the X.

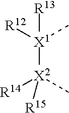

In an embodiment, L¹ or L² is selected from a monoanionic bidentate chelating ligand. L¹ and L² are independently selected from a monoanionic bidentate chelating ligand.

In an embodiment, L¹ and L² are independently selected from any one of the following groups:

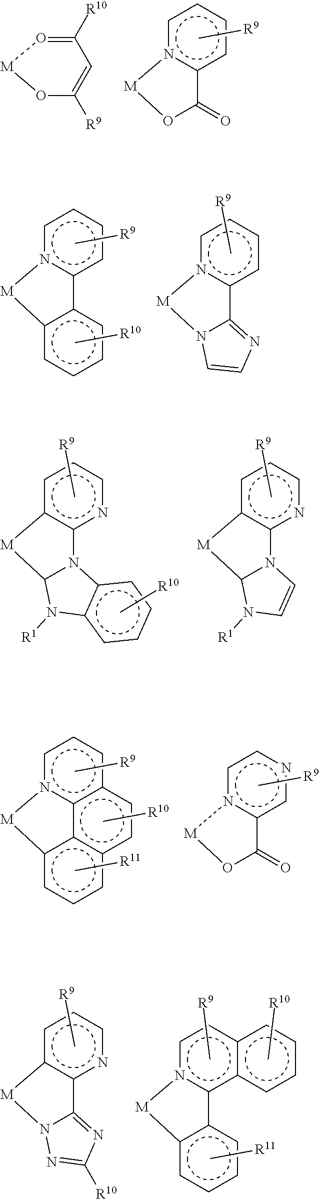

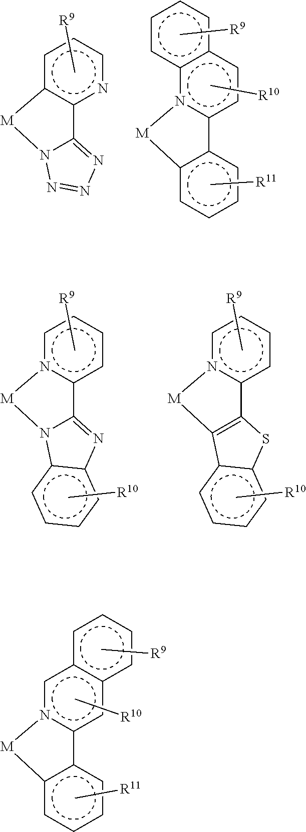

wherein, R⁹-R¹¹ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms.

Specific examples of suitable transition metal complexes according to the present disclosure are given below, but are not limited thereto.

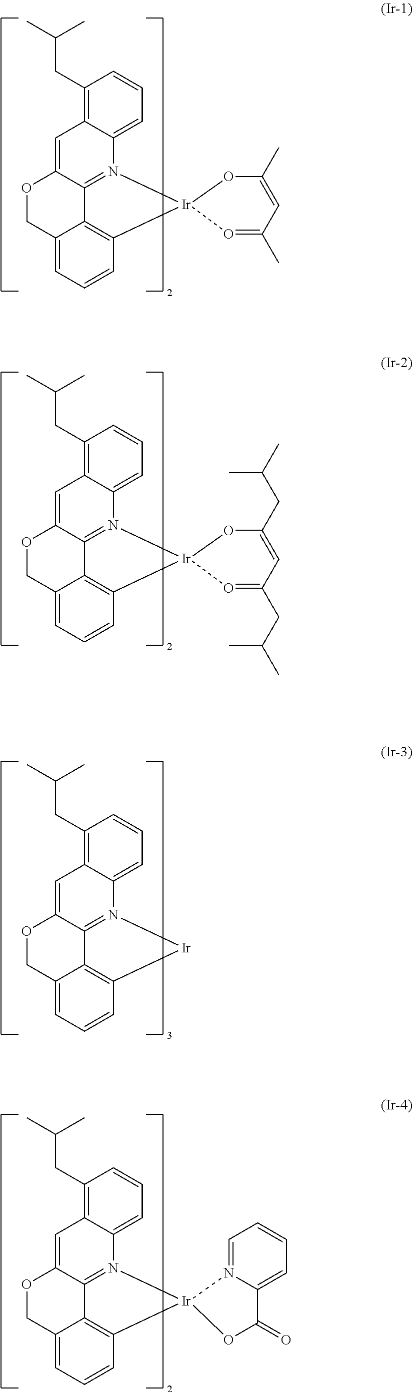

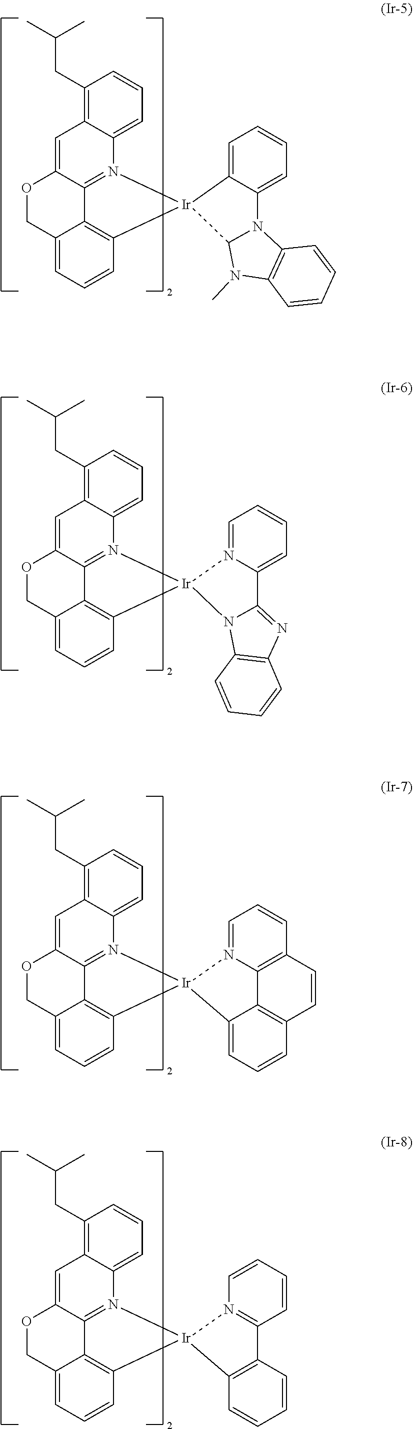

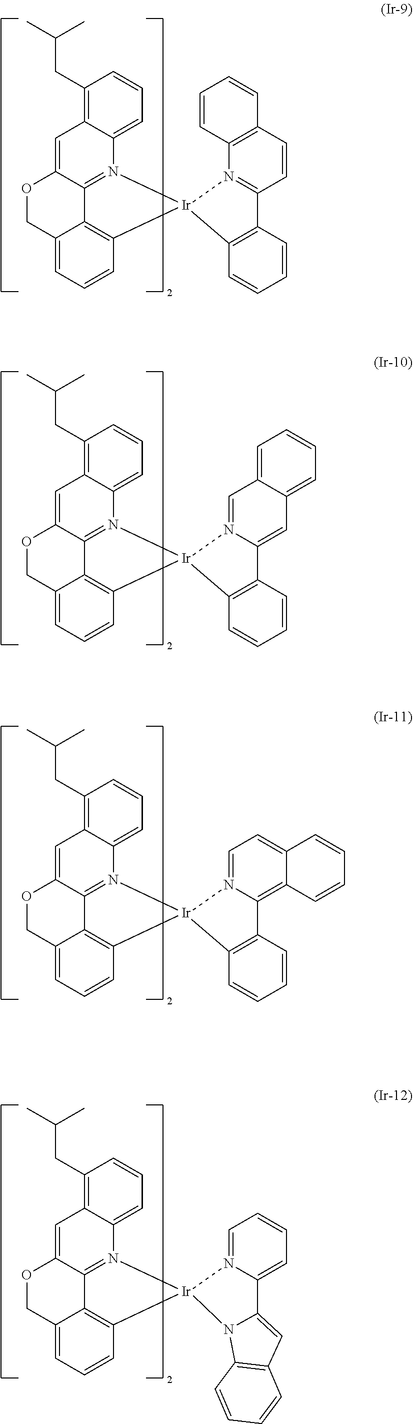

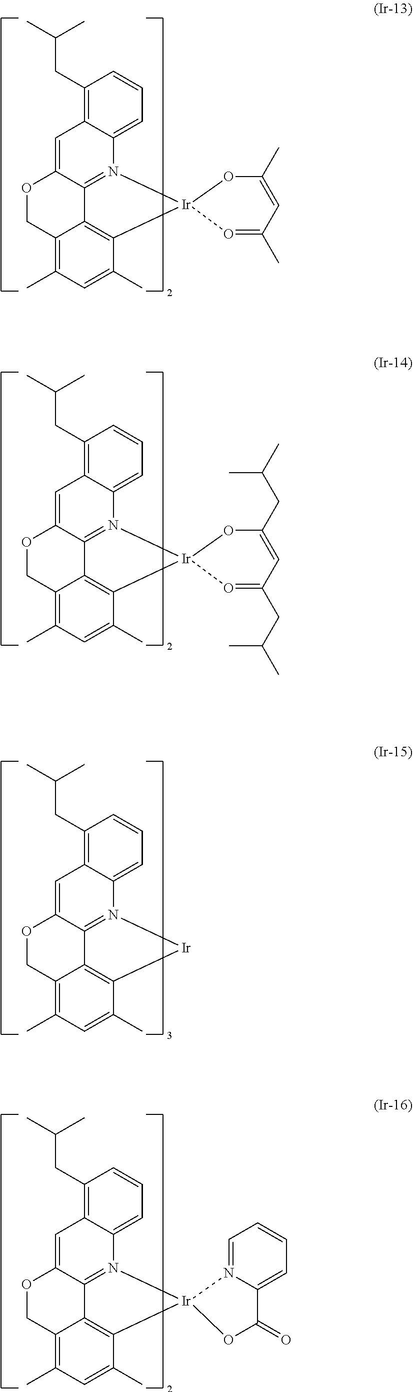

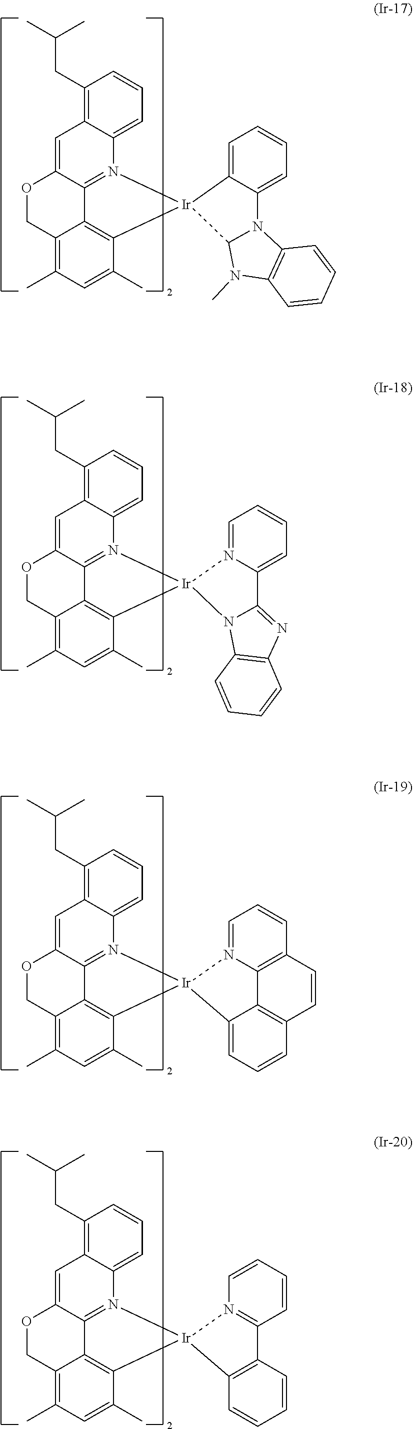

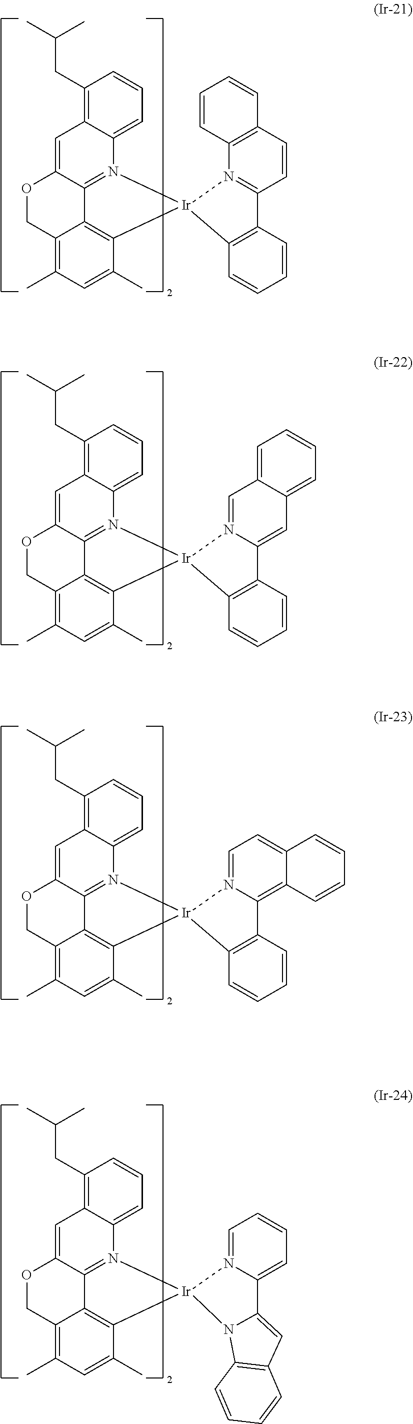

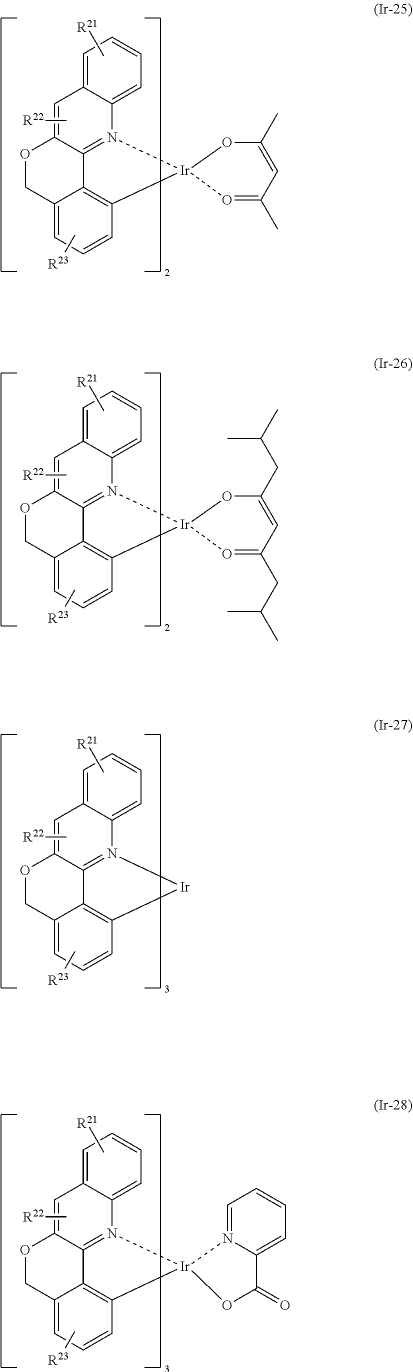

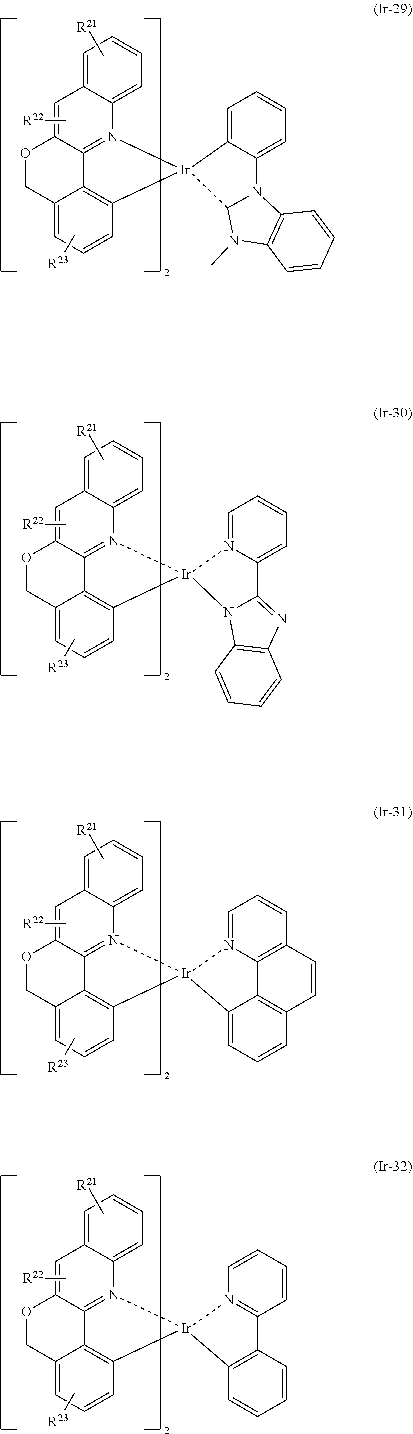

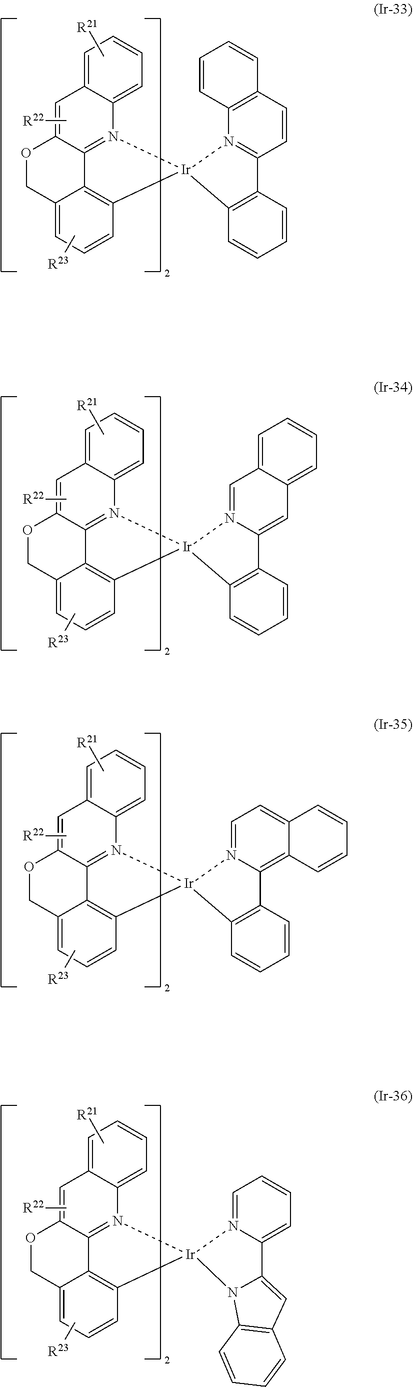

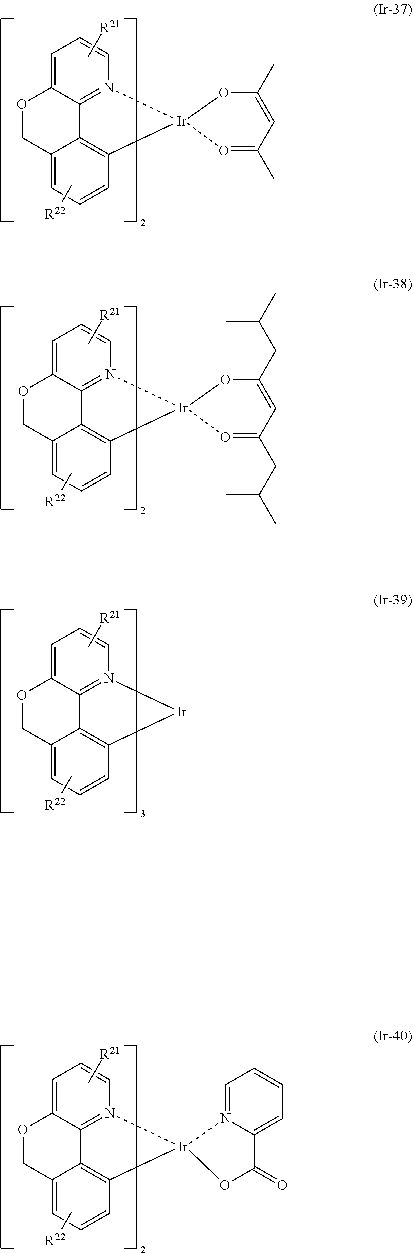

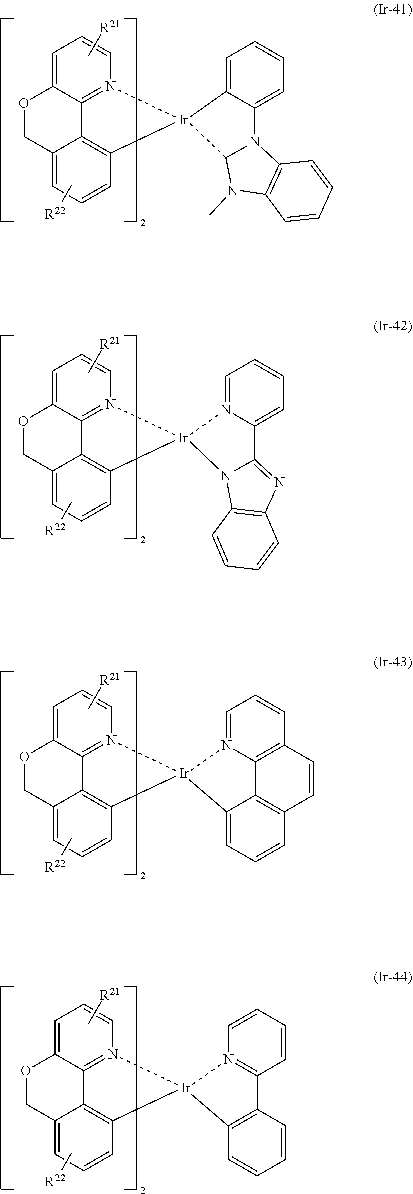

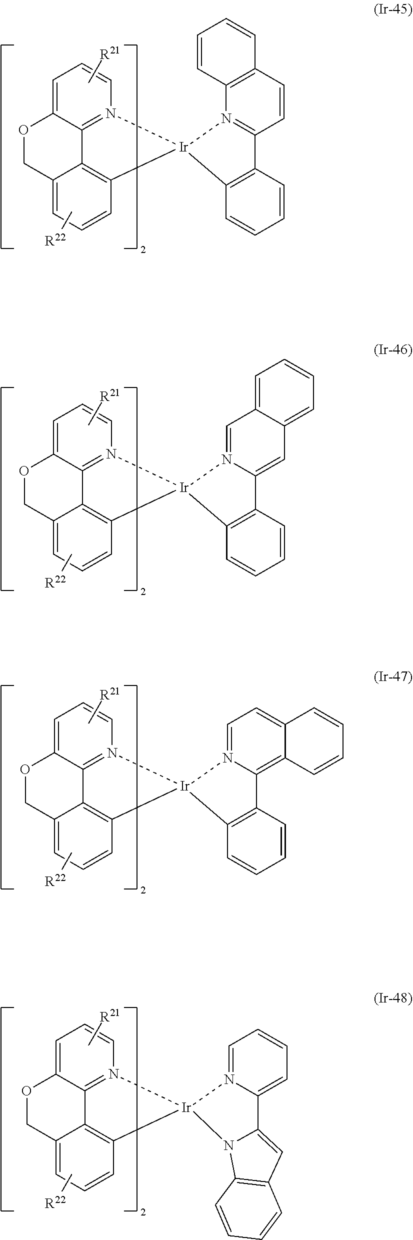

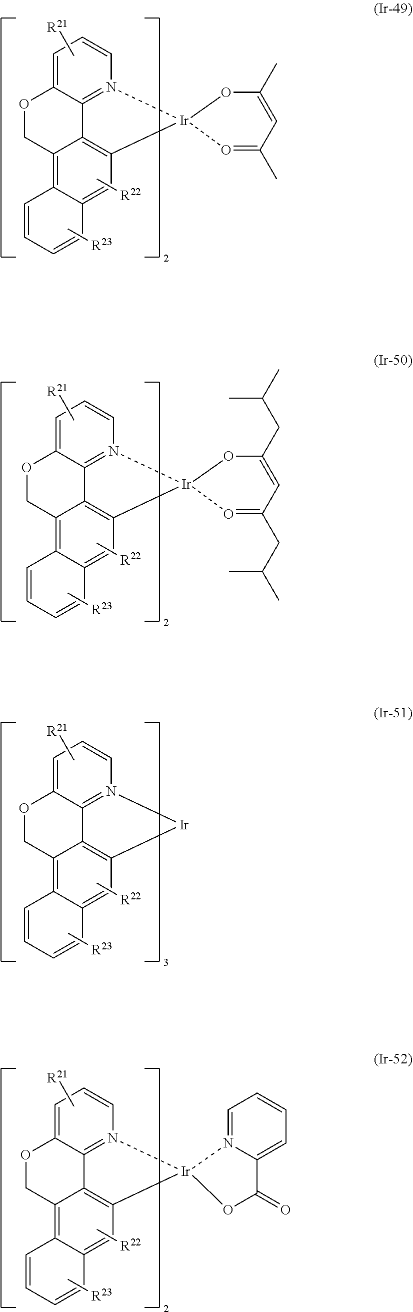

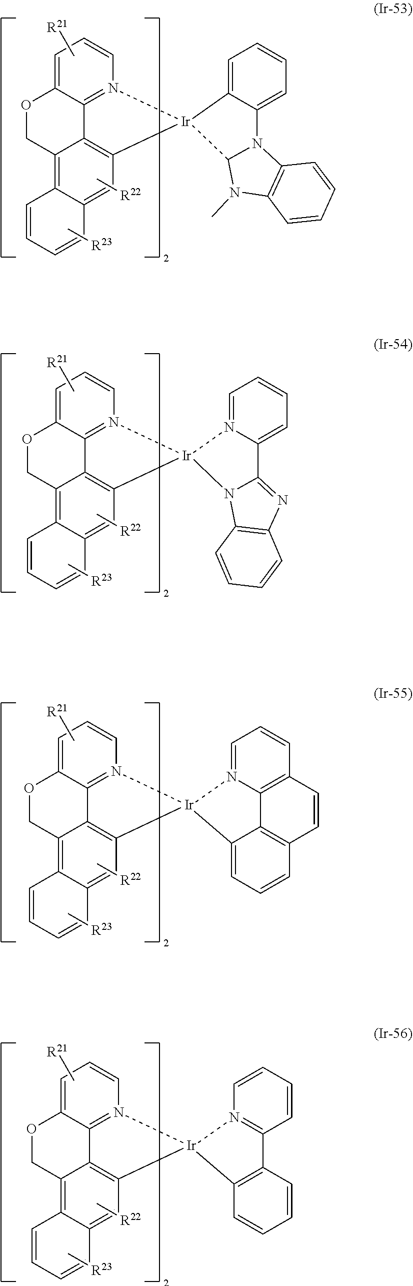

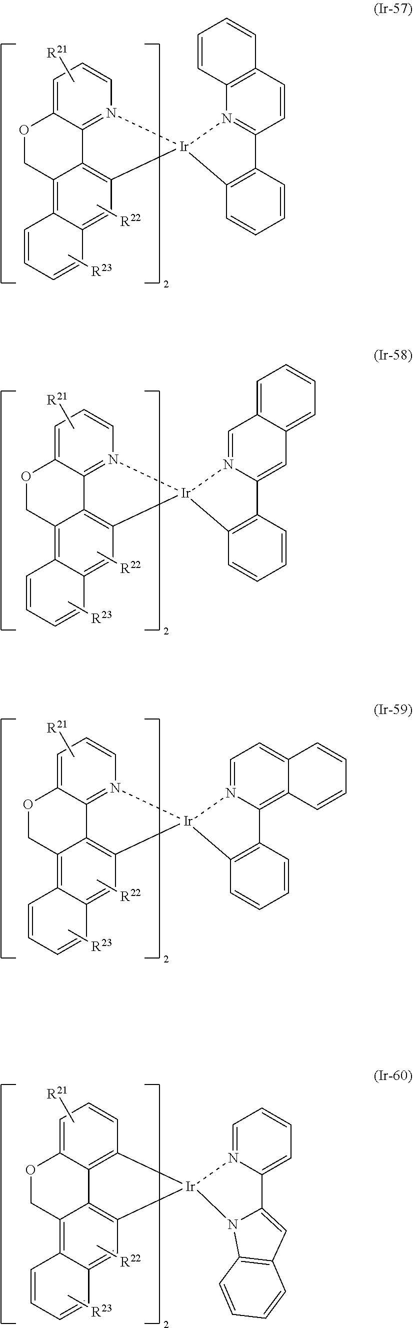

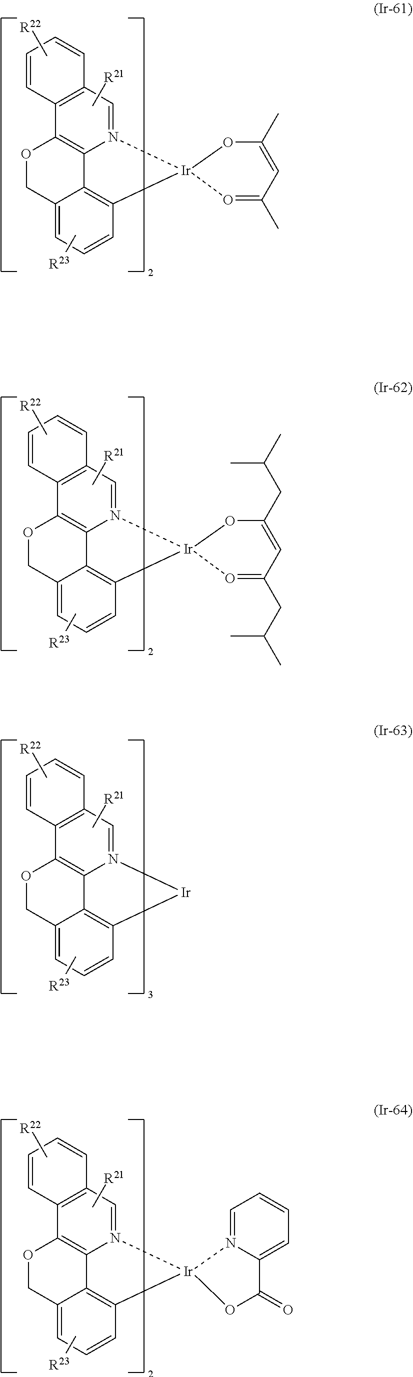

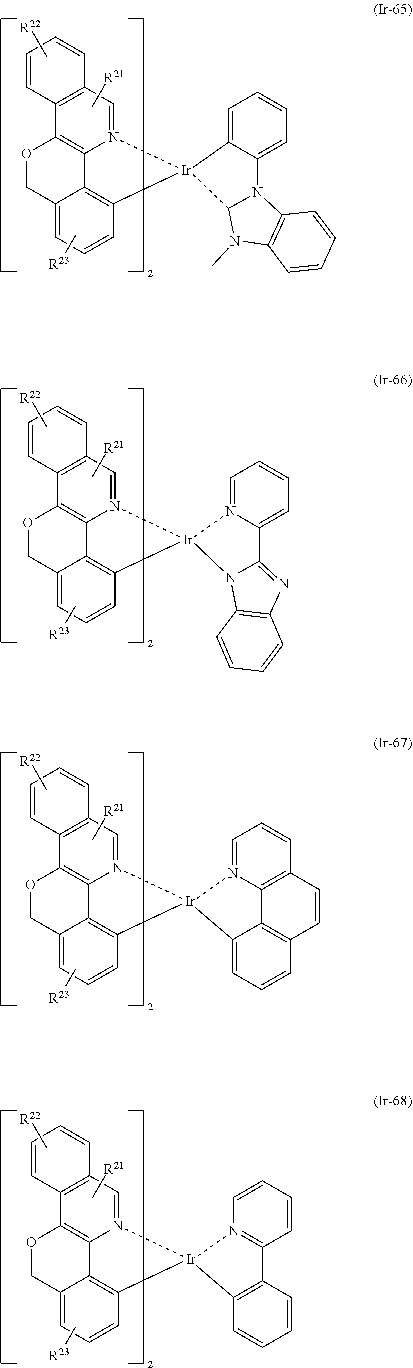

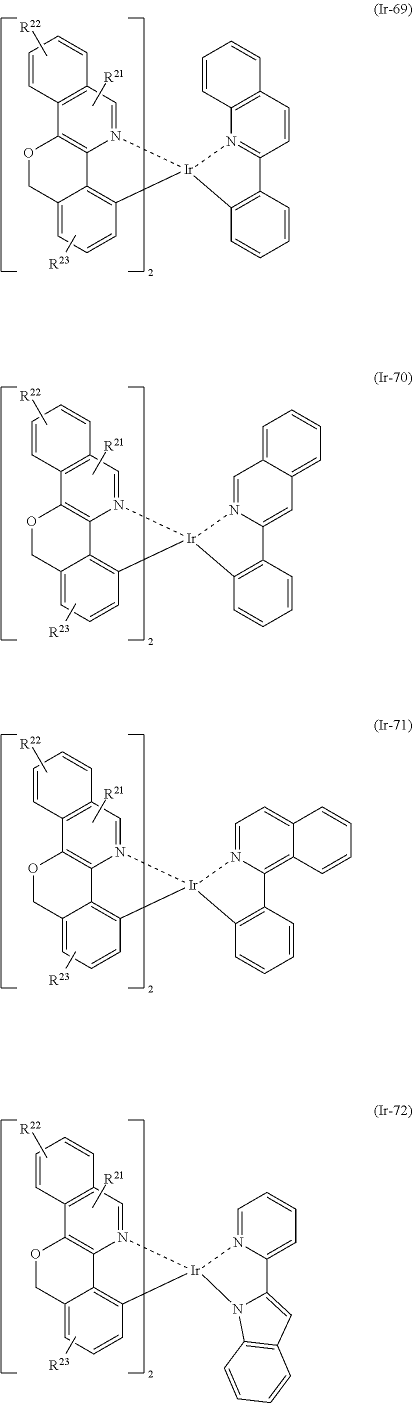

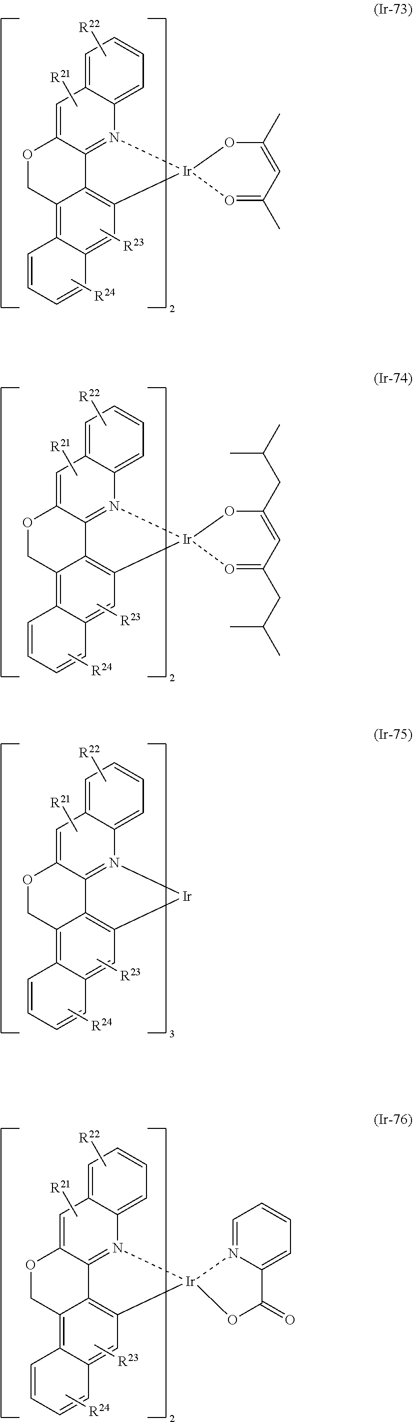

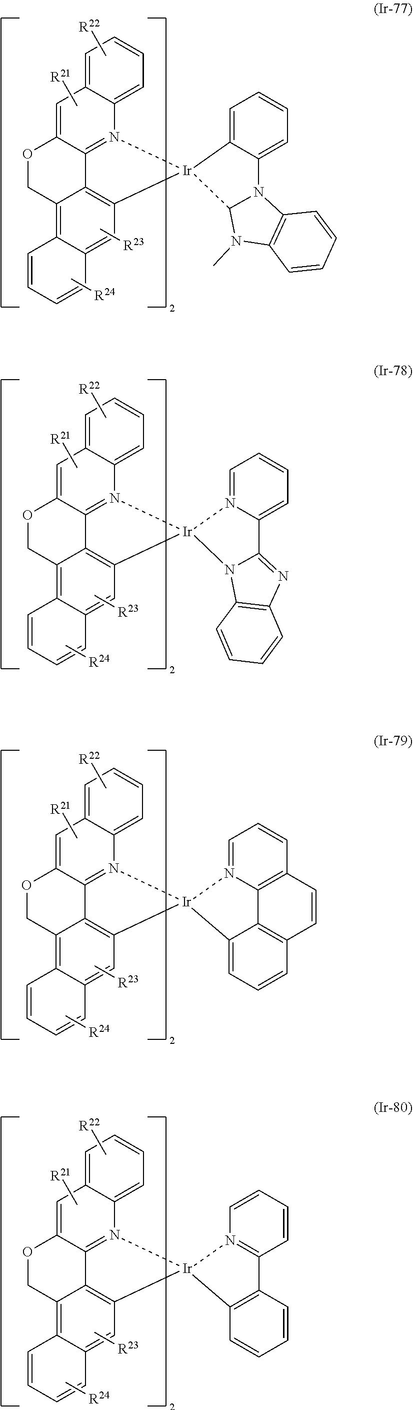

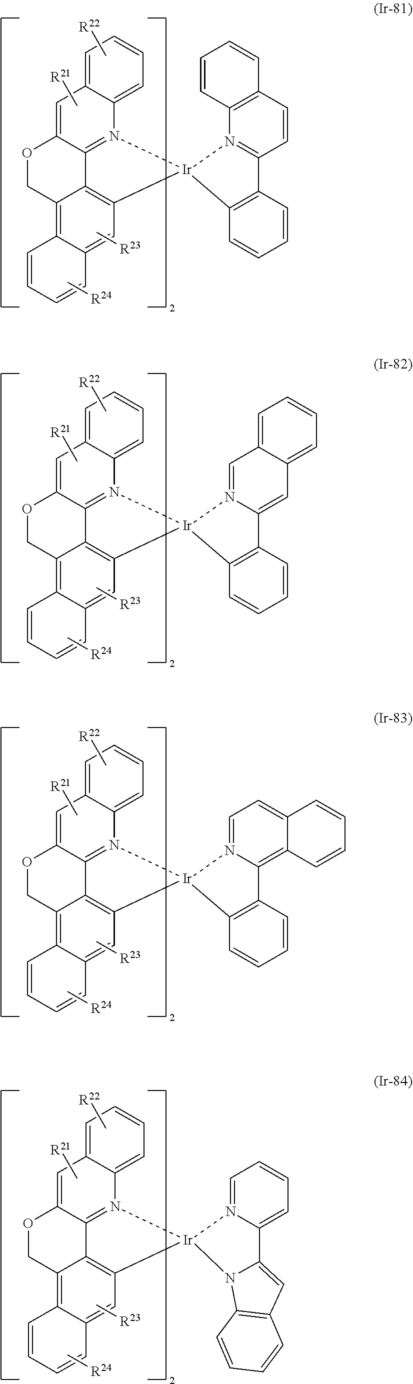

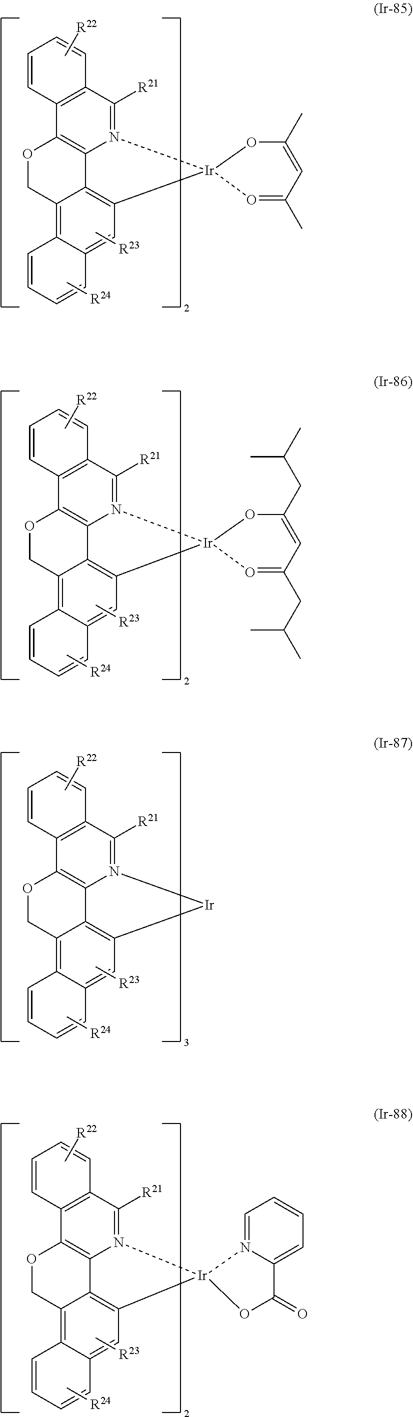

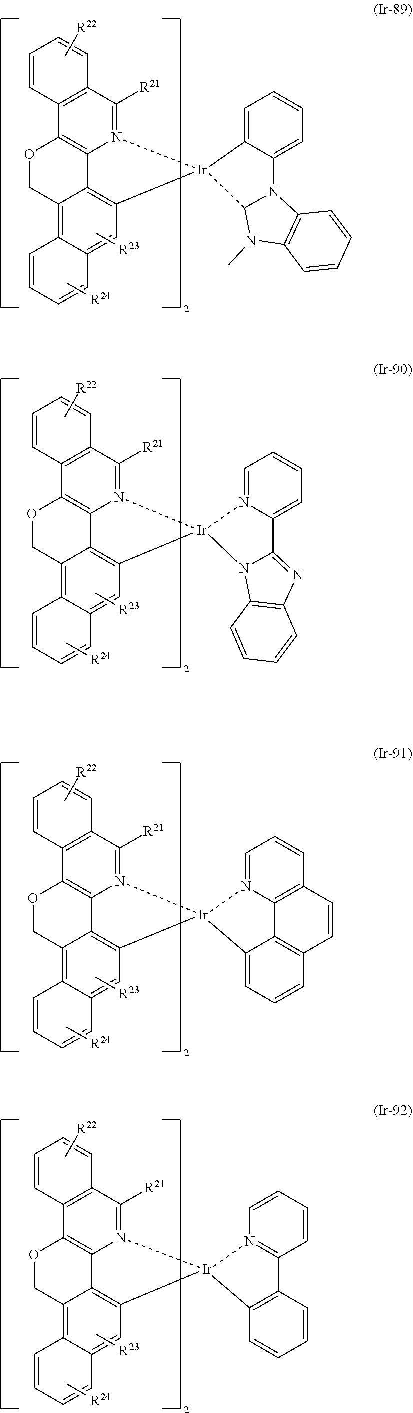

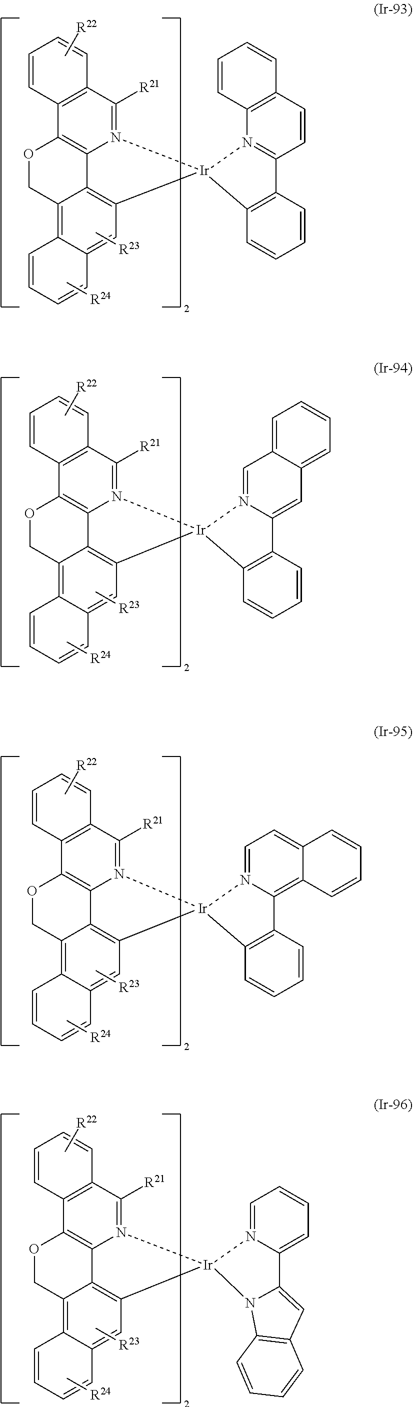

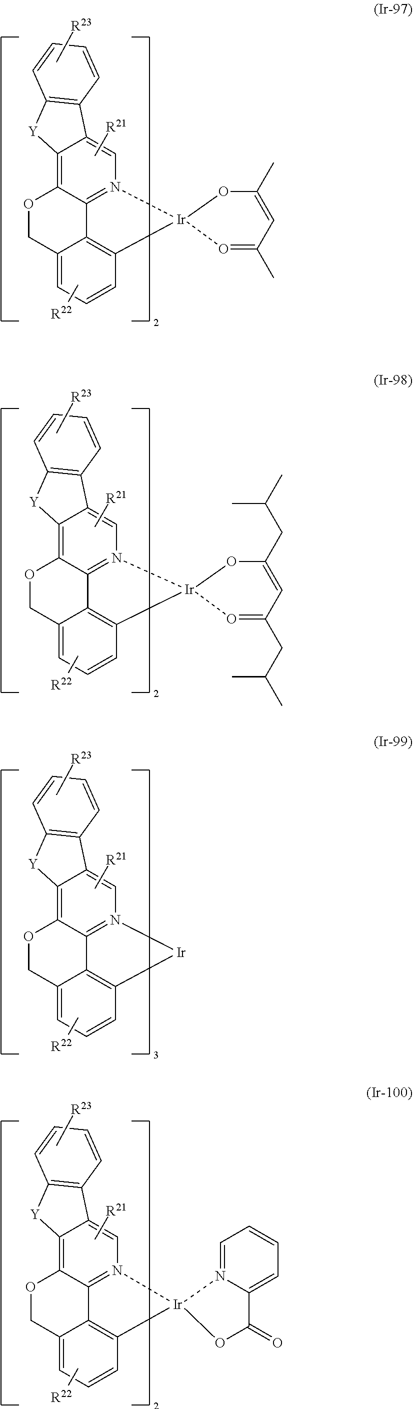

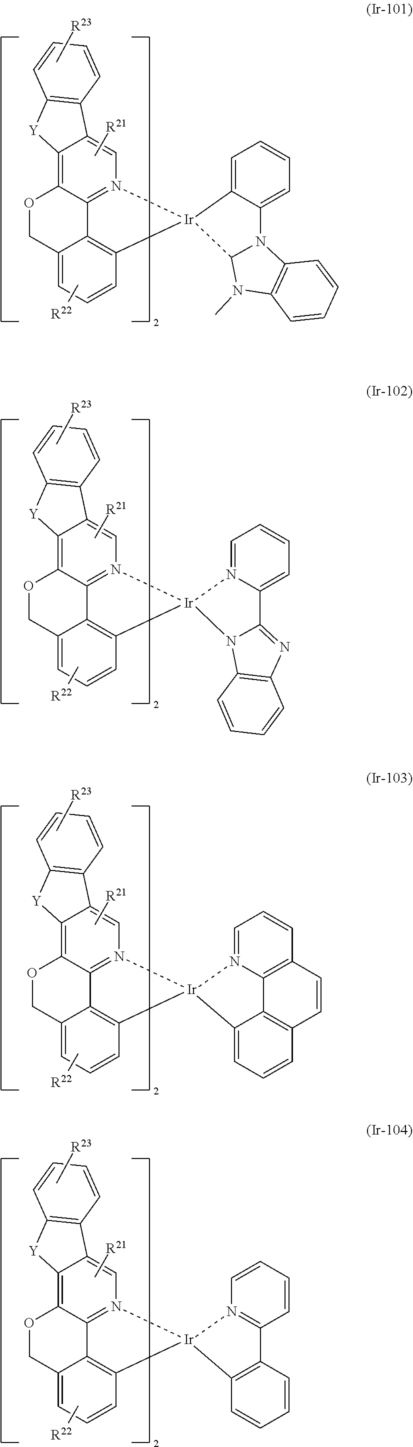

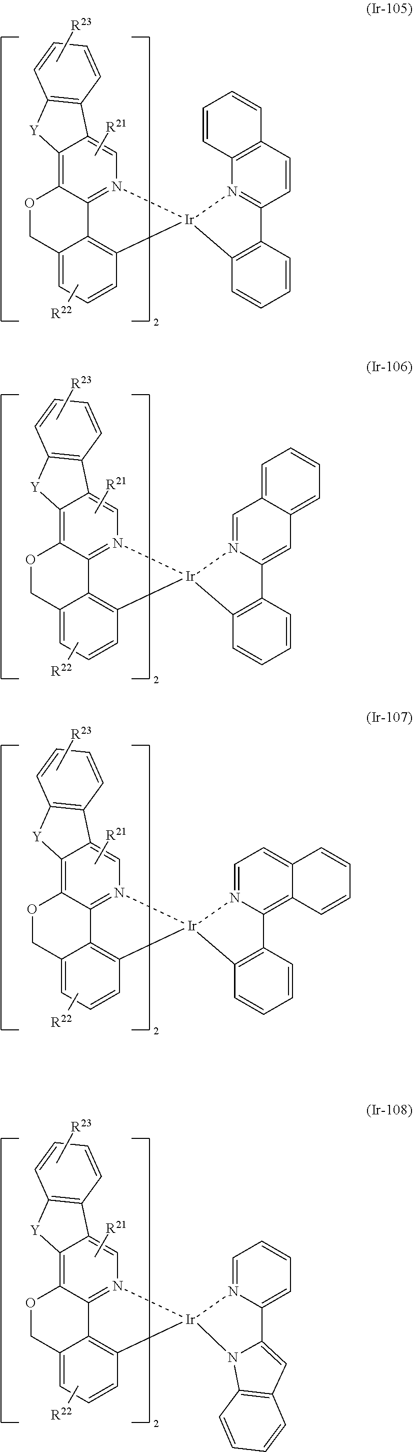

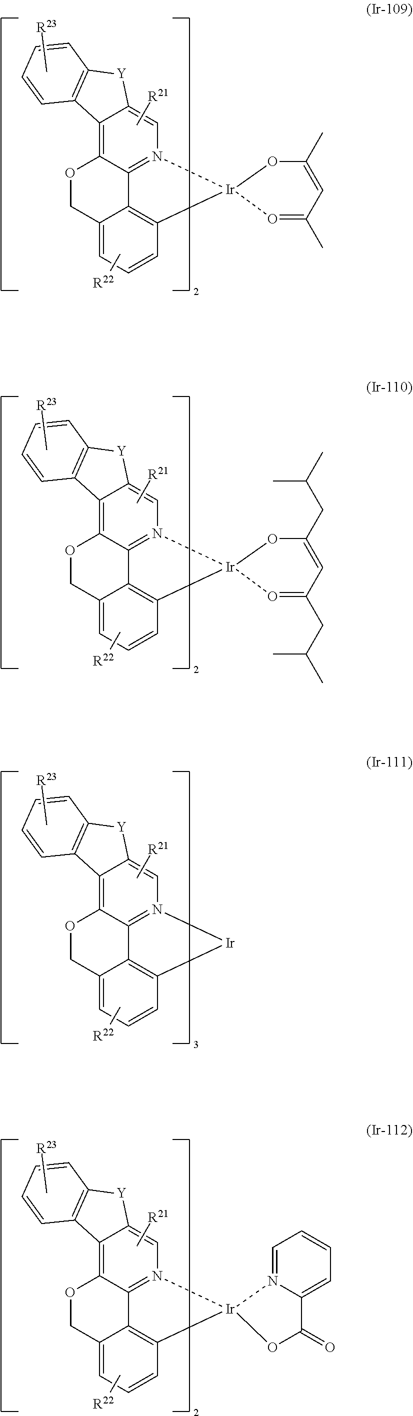

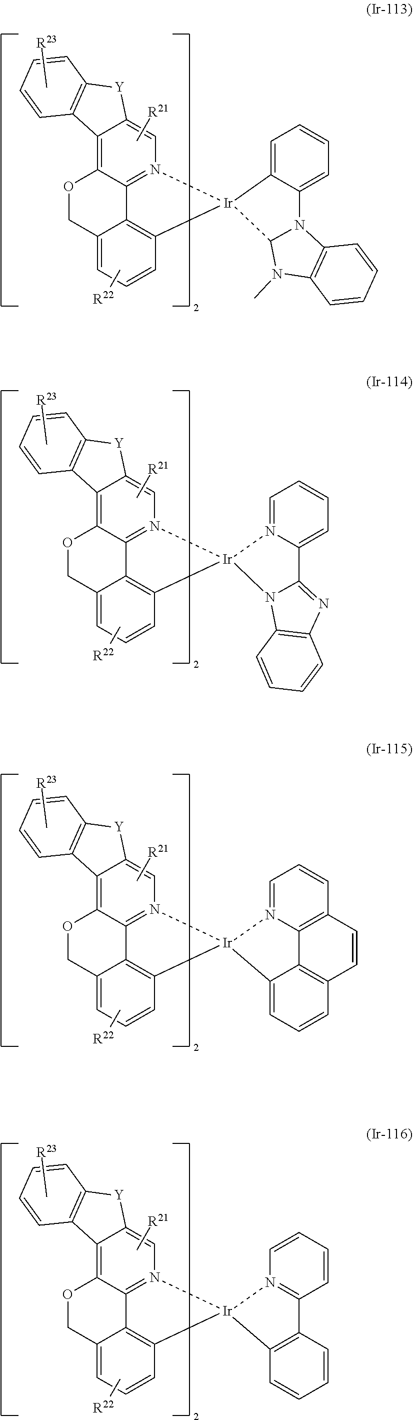

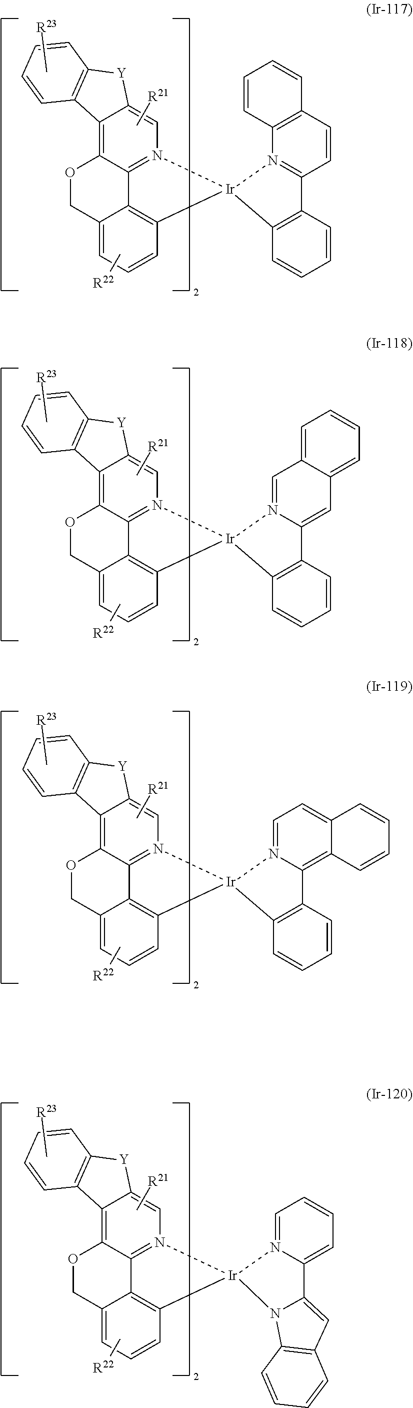

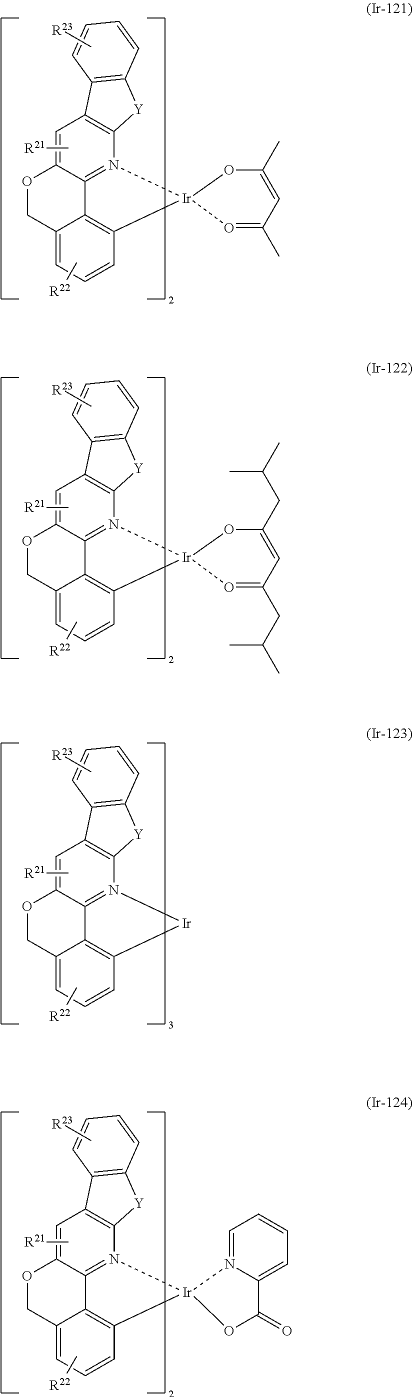

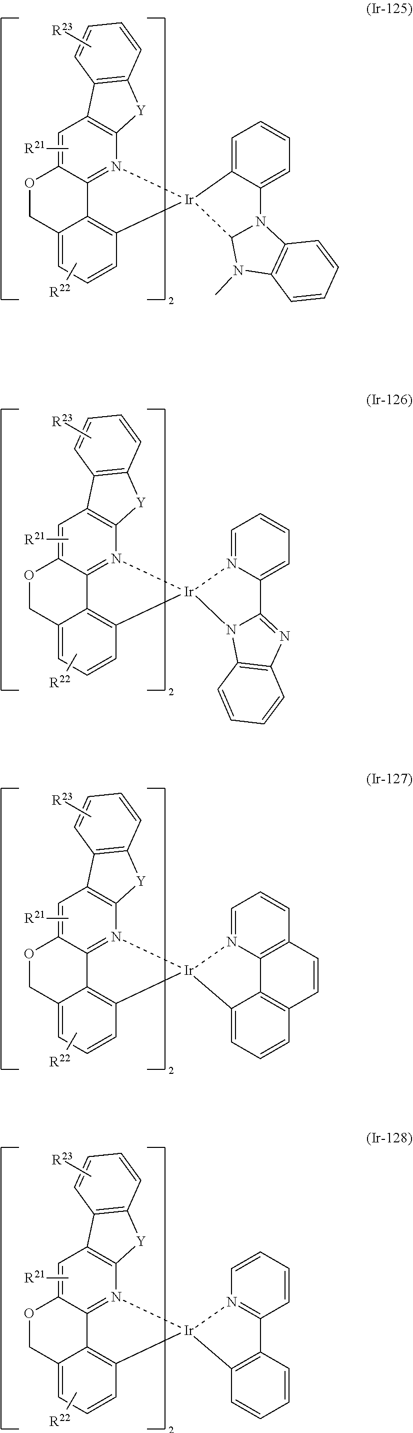

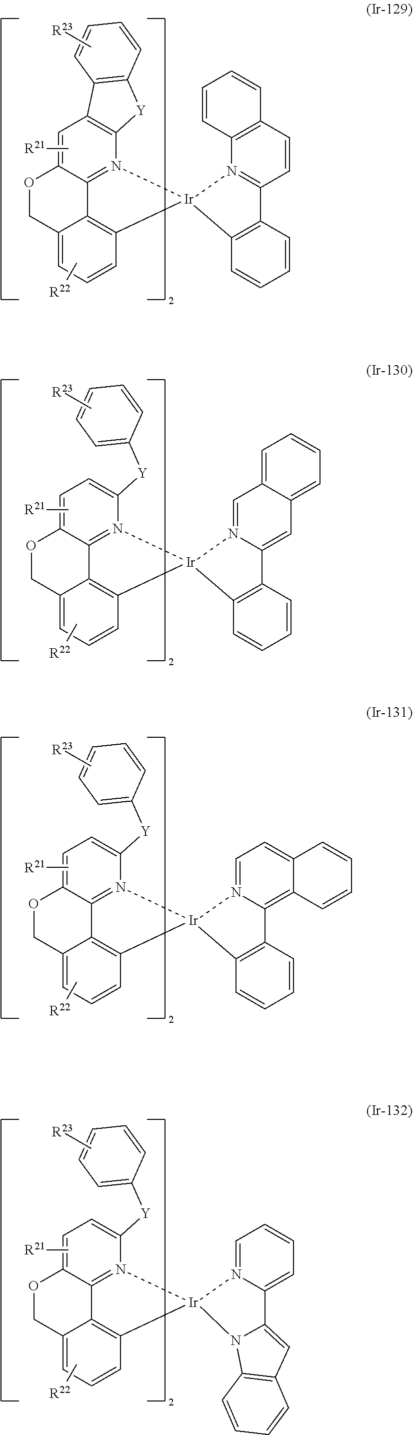

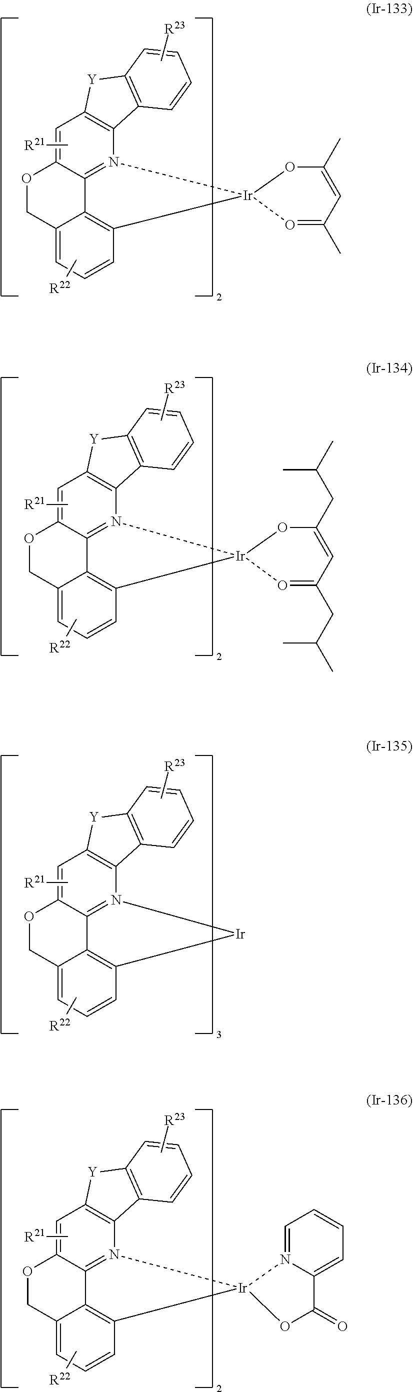

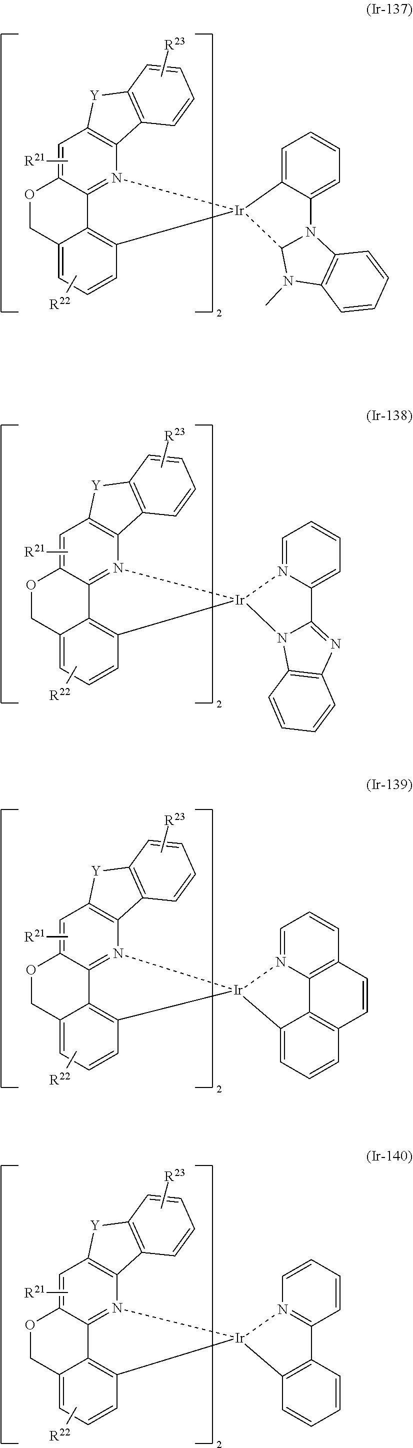

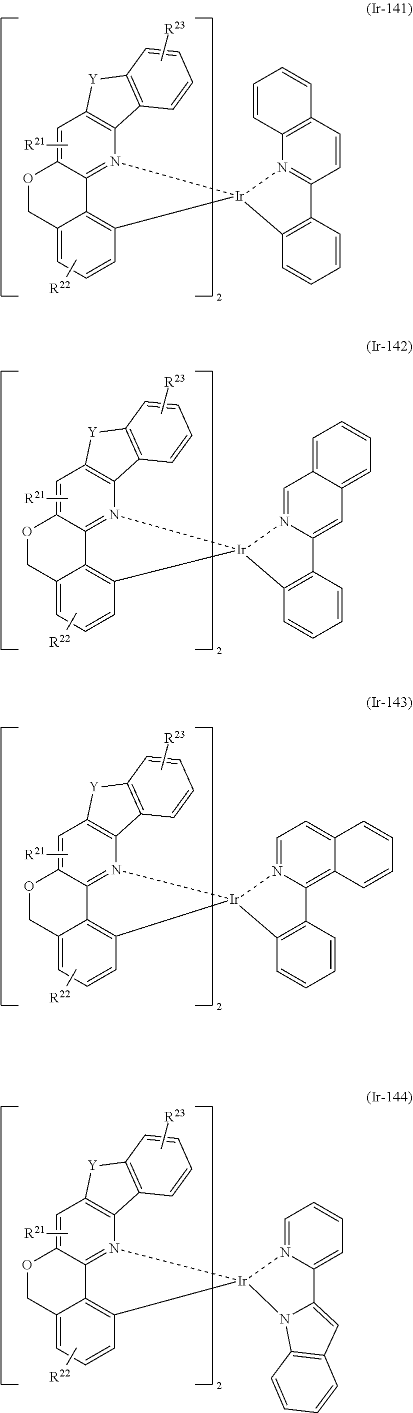

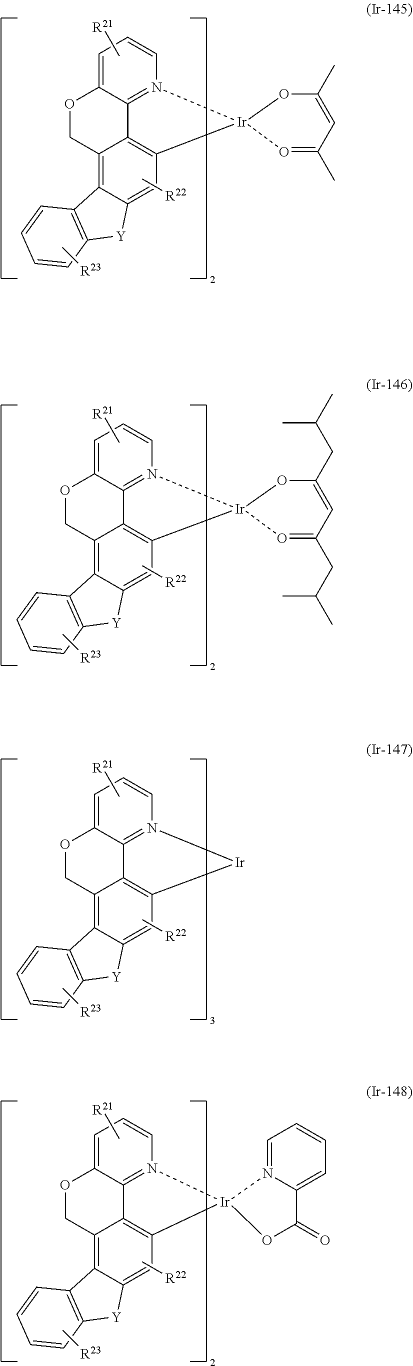

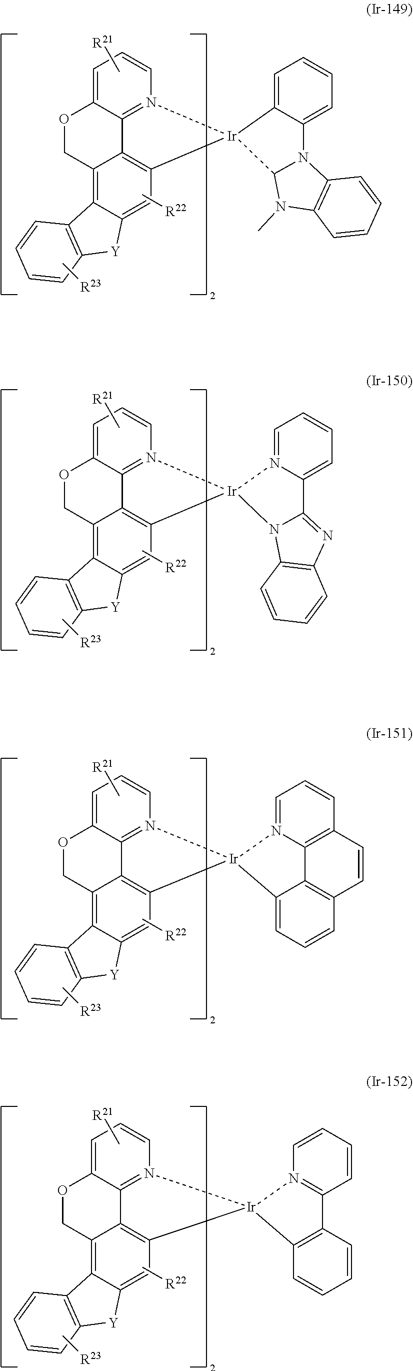

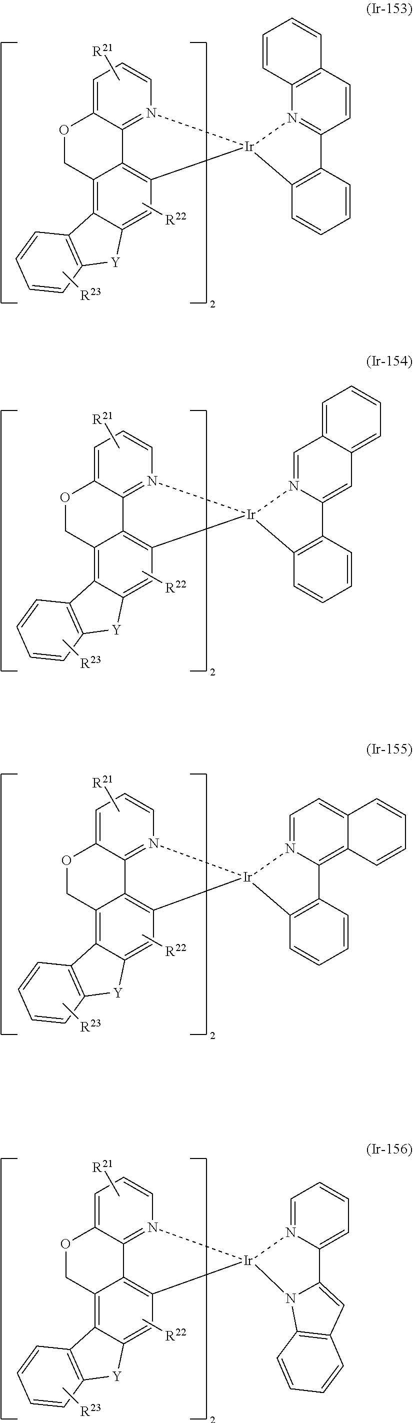

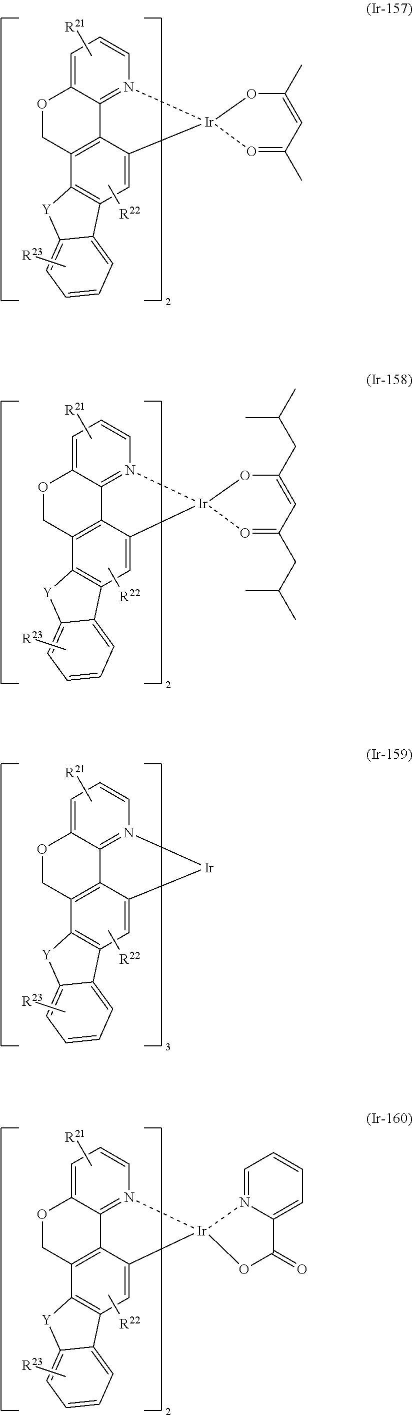

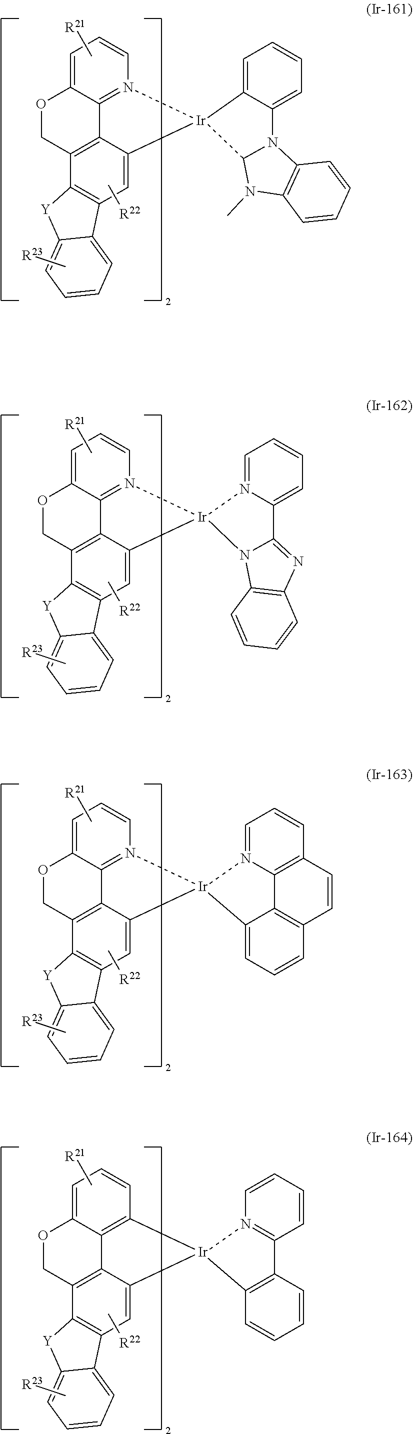

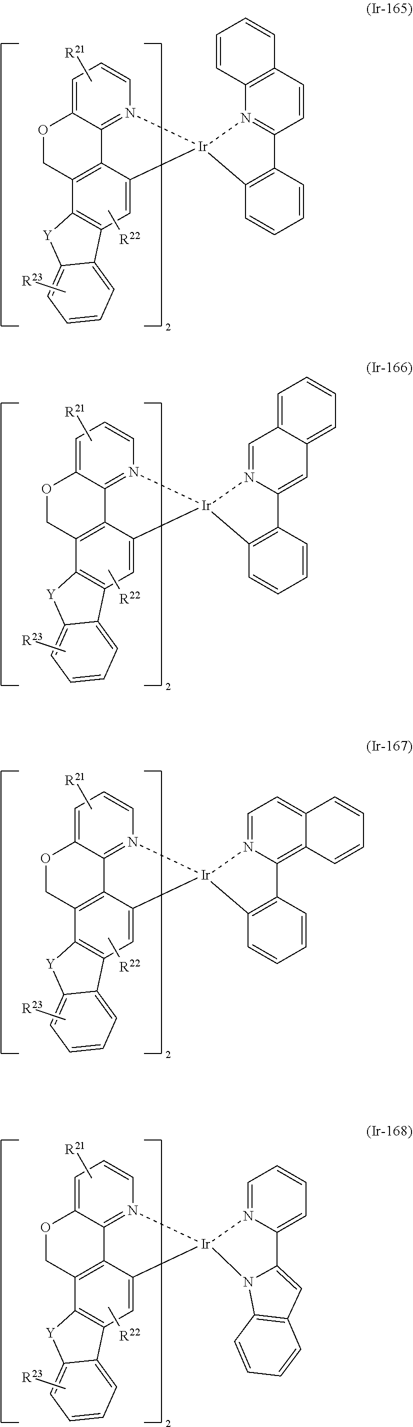

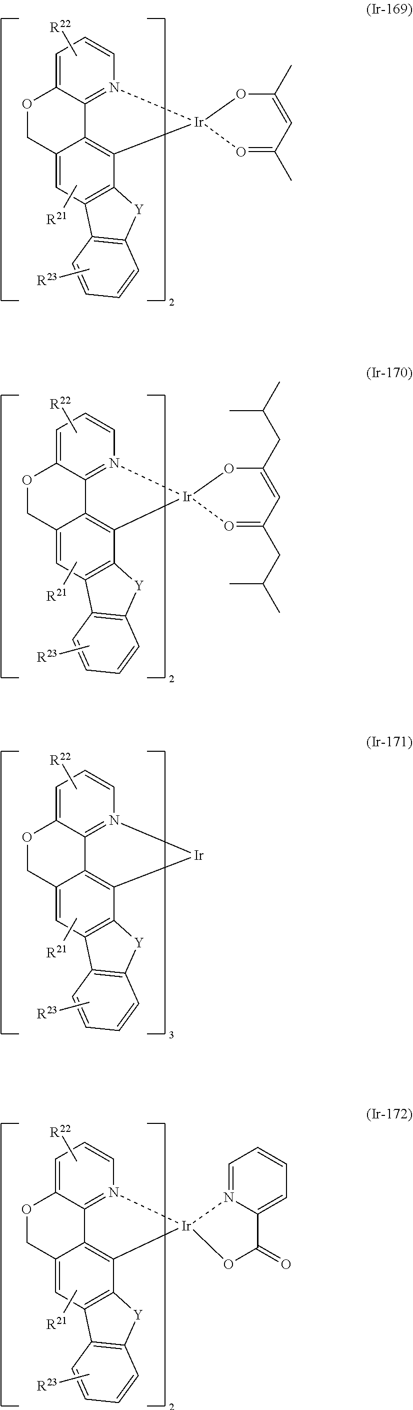

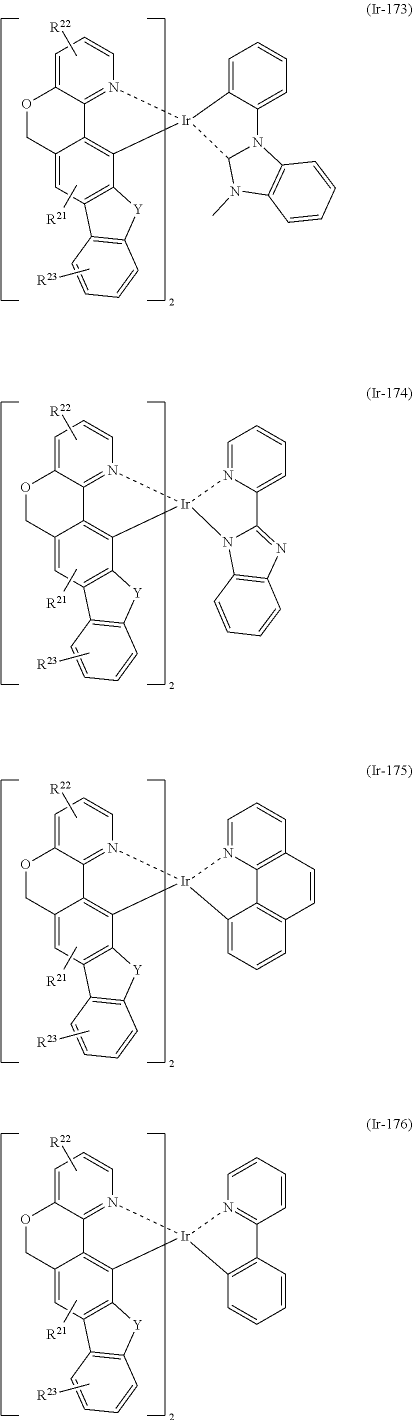

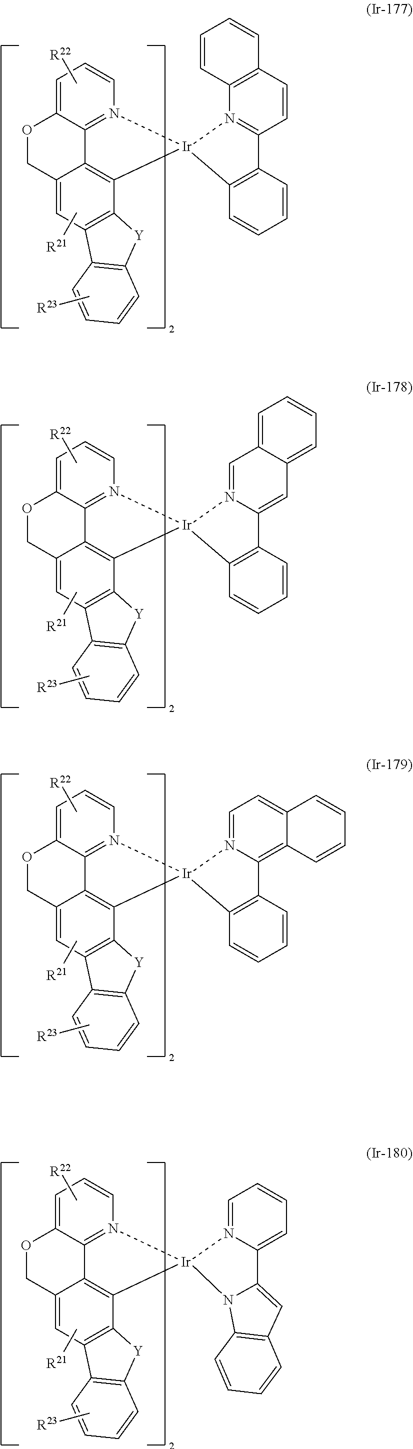

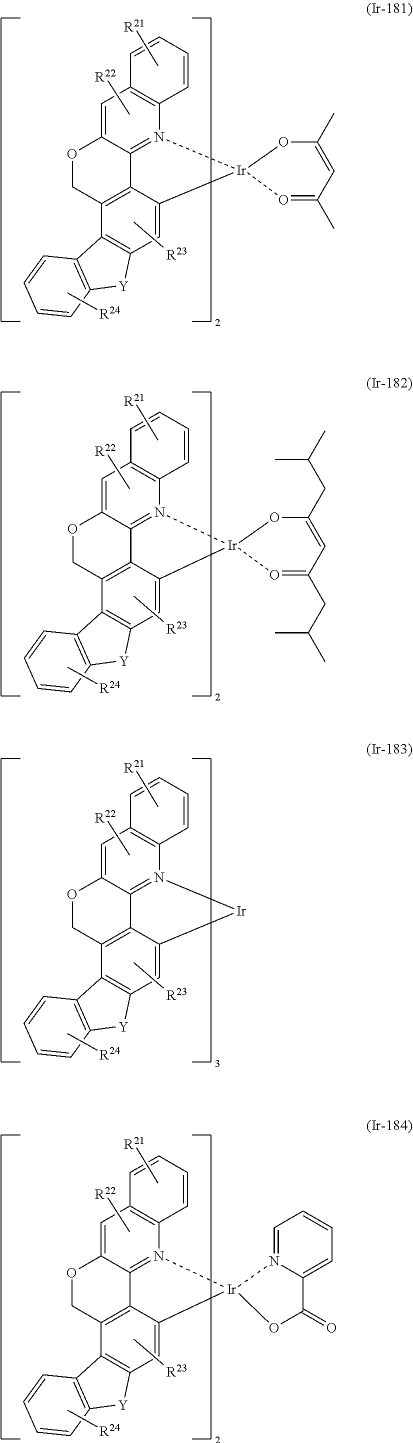

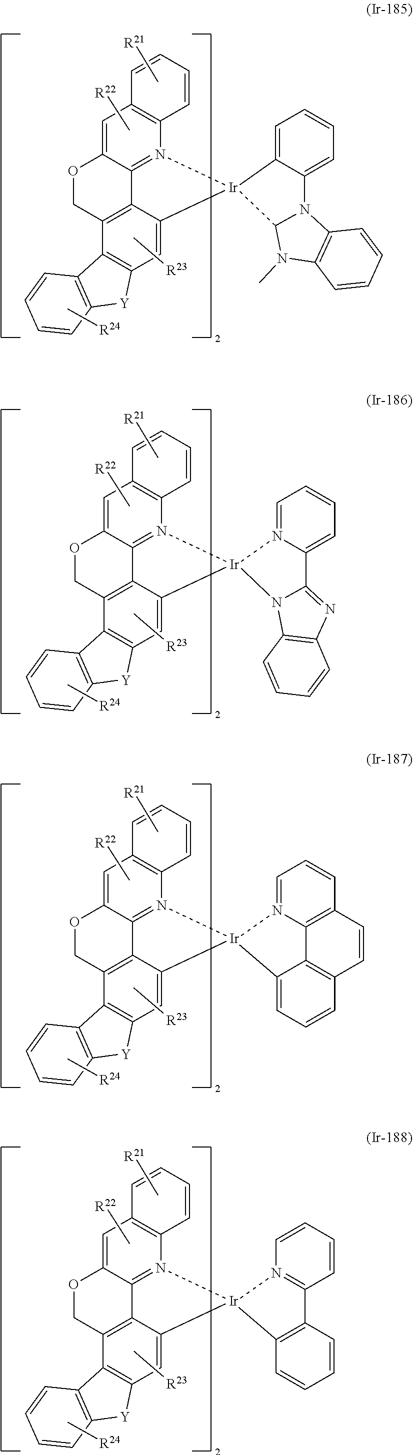

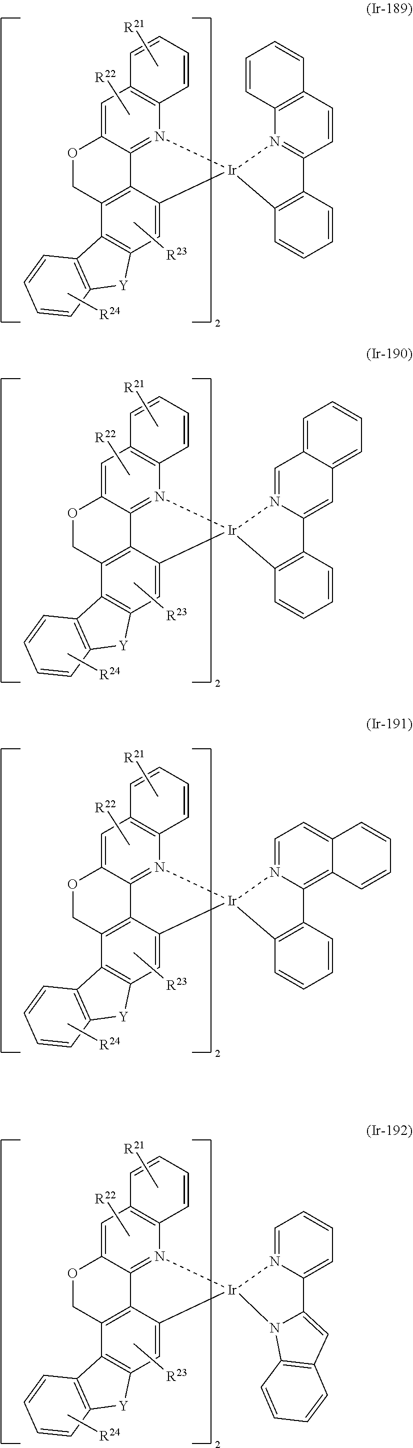

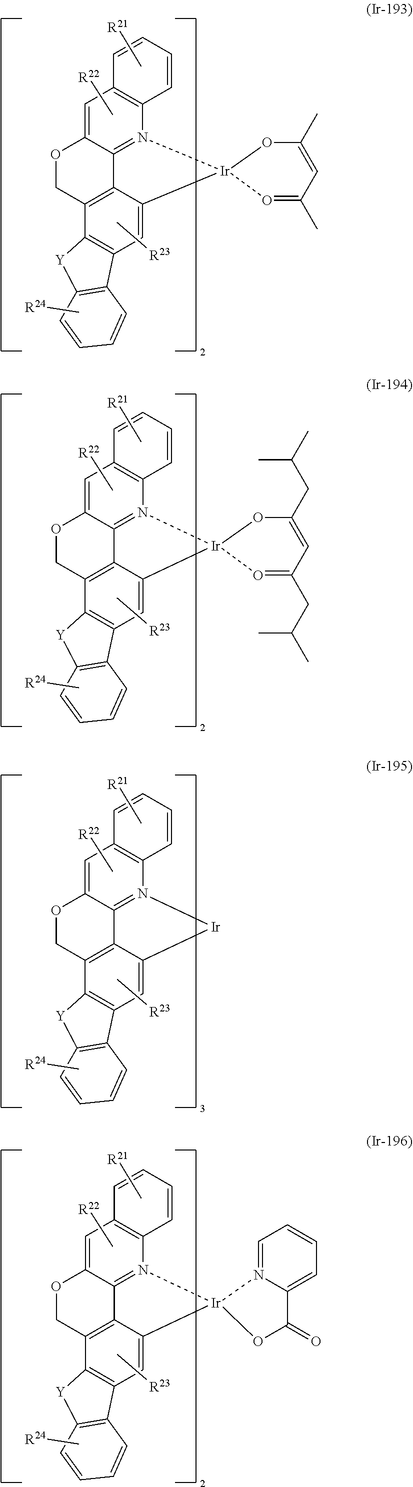

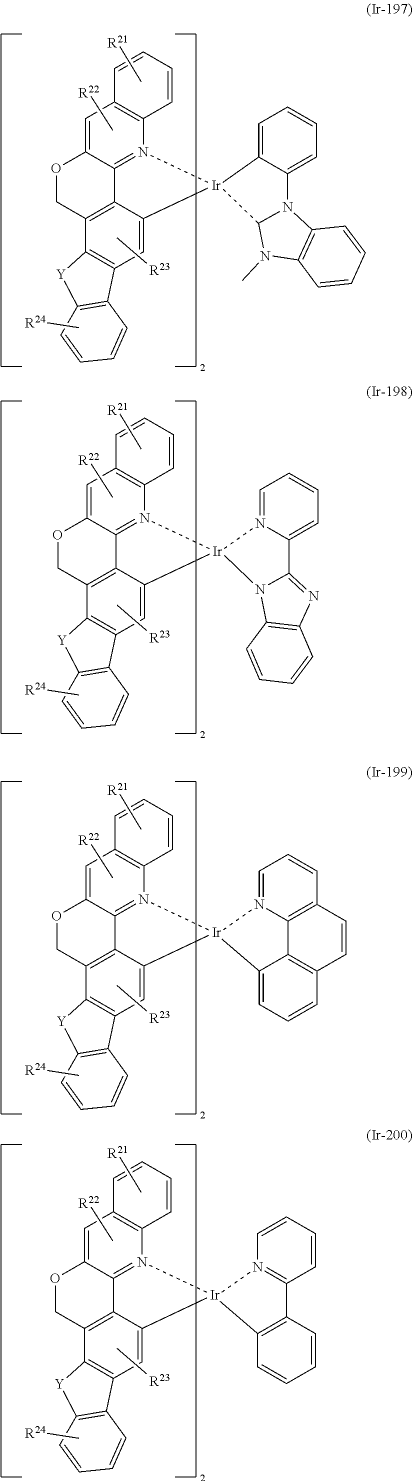

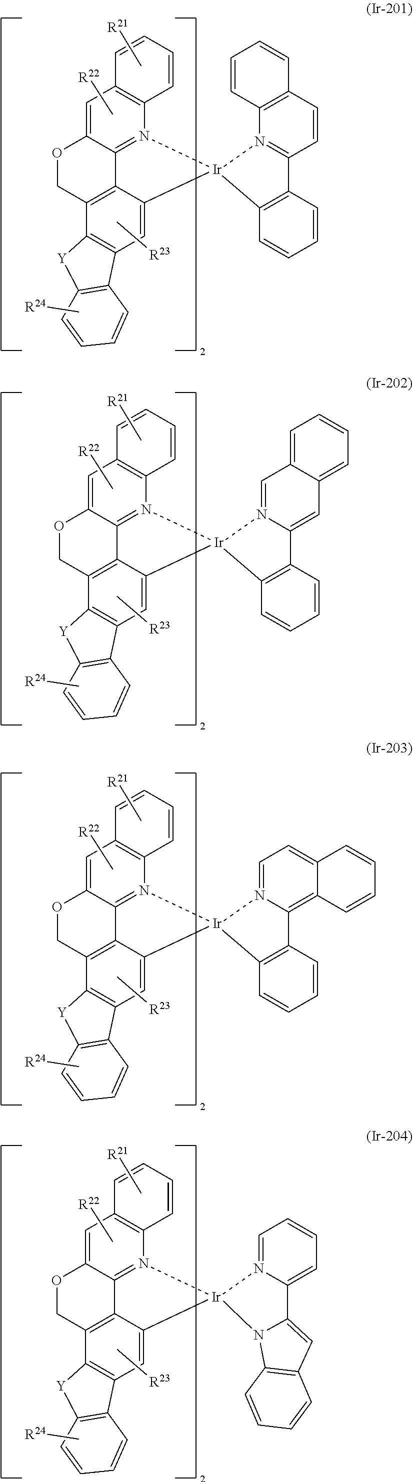

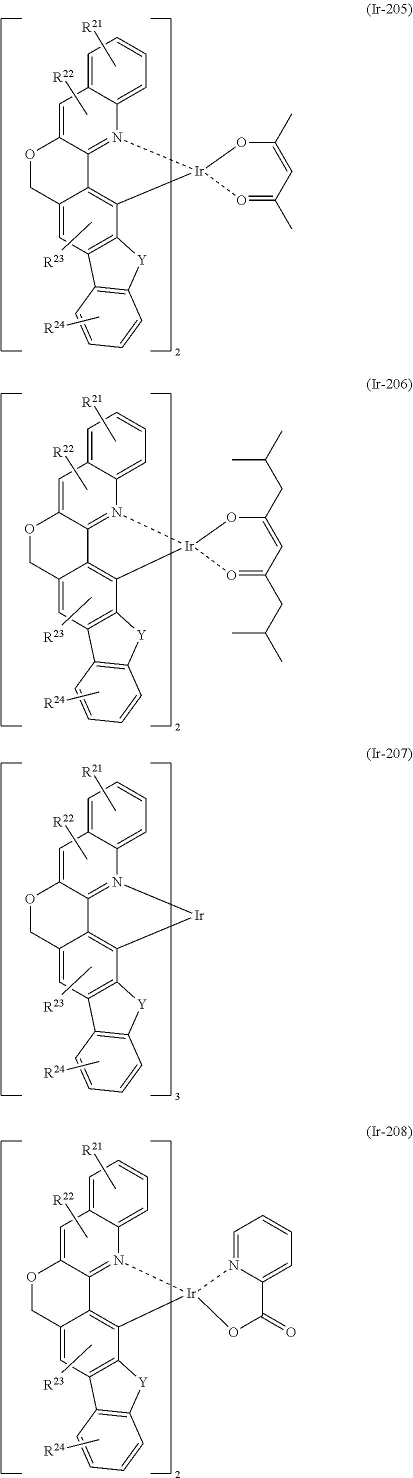

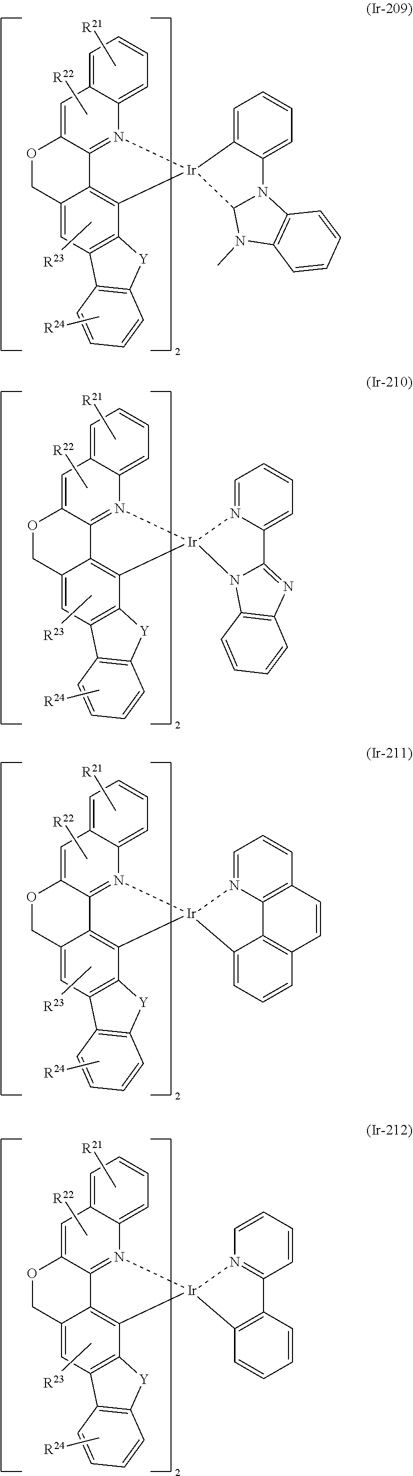

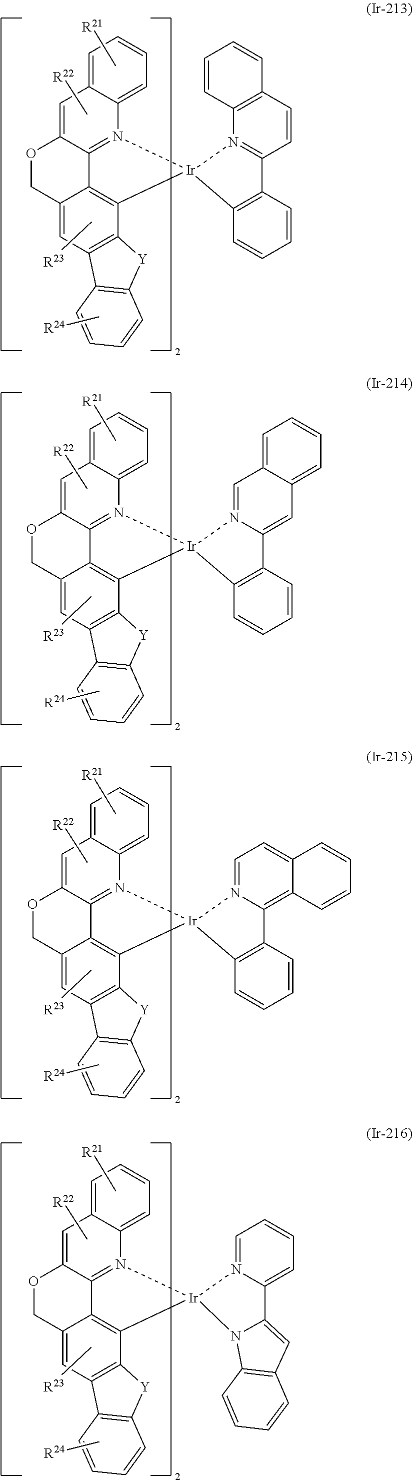

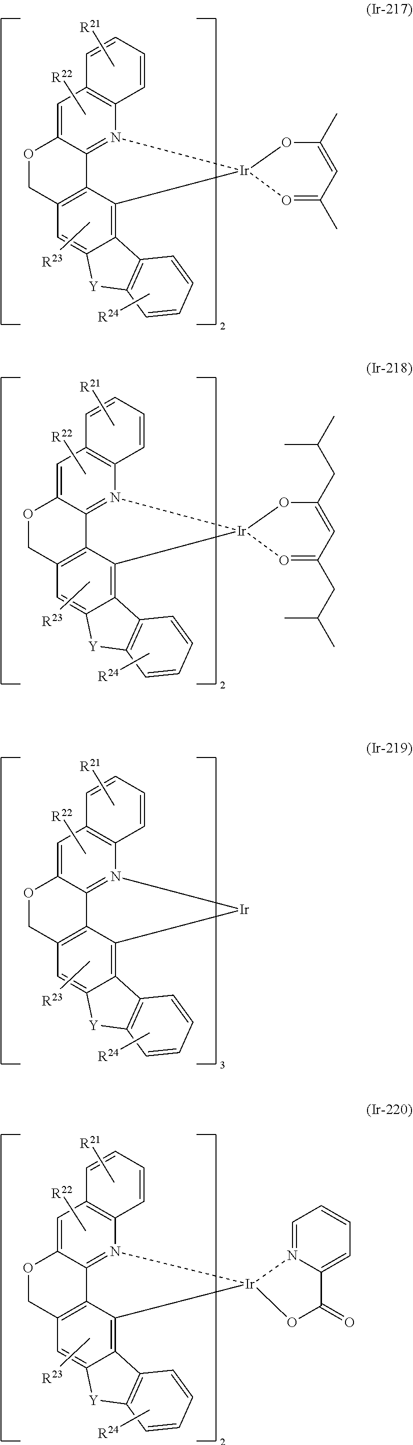

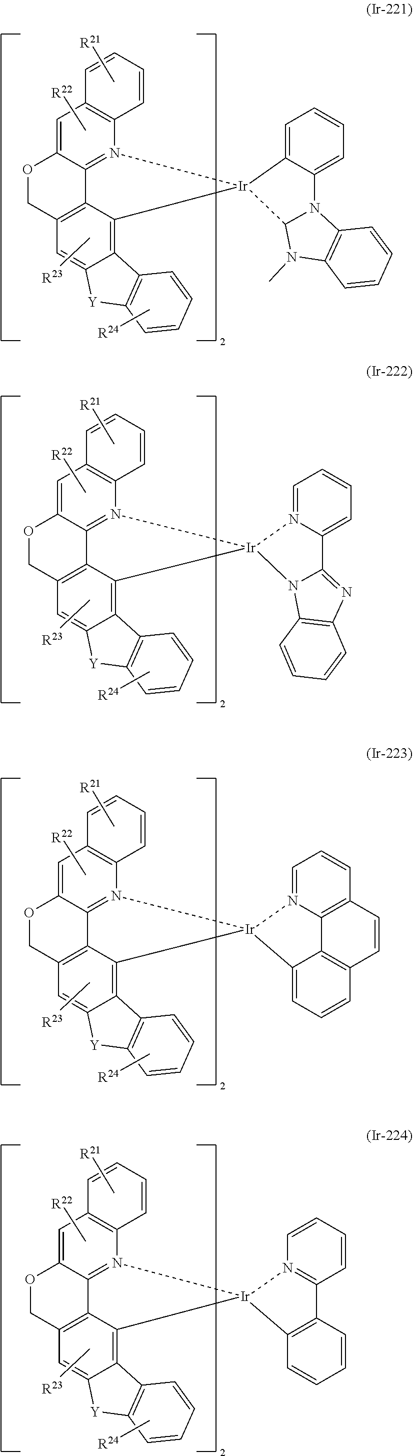

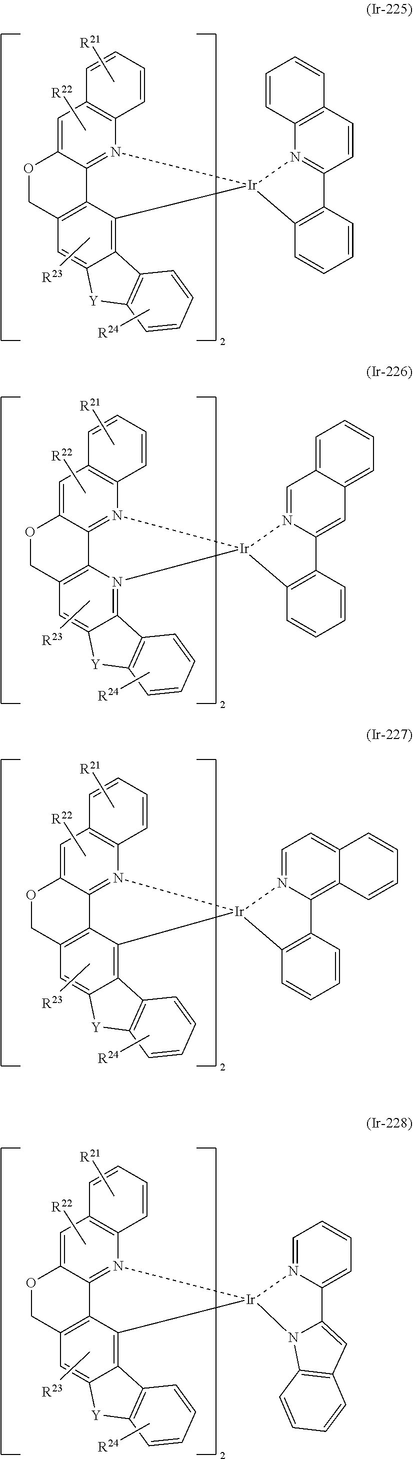

Wherein, R²¹-R²⁸ have the same meaning as R¹²; Y has the same meaning as X.

In an embodiment, the transition metal complex according to the present disclosure is a light-emitting material with light emission wavelength between 300 and 1000 nm. Further, this transition metal complex has light emission wavelength between 350 and 900 nm. In an embodiment, the transition metal complex has light emission wavelength between 400 and 800 nm. The term luminescence/light-emitting herein refers to photoluminescence or electroluminescence. In an embodiment, the transition metal complex has a photoluminescence efficiency of 30%. In an embodiment, the transition metal complex has a photoluminescence efficiency of 40%. In an embodiment, the transition metal complex has a photoluminescence efficiency of 50%. In an embodiment, the transition metal complex has a photoluminescence efficiency of 60%.

In an embodiment, the transition metal complex according to the disclosure may also be a non-light-emitting material.

Use of the above transition metal complex in polymers is provided. Use of the above transition metal complex in mixtures is provided. Use of the above transition metal complex in organic electronic devices is provided.

The polymer of an embodiment is provided, wherein at least one repeating unit comprises the above transition metal complex. In an embodiment, the polymer is a non-conjugated polymer, wherein the structural unit represented by formula (1) is on the side chain. In another embodiment, the polymer is a conjugated polymer.

The mixture of an embodiment comprises at least one organic functional material and the transition metal complex described above. The organic functional material is selected from the group consisting of hole (also called electron hole) injection or transport material (HIM/HTM), hole blocking material (HBM), electron injection or transport material (EIM/ETM), electron blocking material (EBM), organic host material (Host), singlet emitter (fluorescent emitter), triplet emitter (phosphorescent emitter), or organic thermally activated delayed fluorescent material (TADF material). Wherein, the organic thermally activated delayed fluorescent material may be a luminescent organometallic complex. Various organic functional materials are described in detail, for example, in WO2010135519A1, US2009 0134784A1 and WO 2011110277A1, and the entire contents of these three patent documents are hereby incorporated herein by reference. The organic functional materials may be small molecule or polymer materials.

The term “small molecule” as defined herein refers to a molecule that is not a polymer, oligomer, dendrimer, or blend. In particular, there are no repeating structures in the small molecule. The small molecule has a molecular weight ≤3000 g/mol. Further, the small molecule has a molecular weight ≤2000 g/mol. Further, the small molecule has a molecular weight ≤1500 g/mol.

Polymer includes homopolymer, copolymer and block copolymer. In addition, in the present disclosure, the polymer also includes dendrimer. The synthesis and application of dendrimers can be found in Dendrimers and Dendrons, Wiley-VCH Verlag GmbH & Co. KGaA, 2002, Ed. George R. Newkome, Charles N. Moorefield, Fritz Vogtle.

Conjugated polymer is a polymer whose backbone is primarily formed by the sp² hybridization orbital of C atoms. Taking polyacetylene and poly (phenylene vinylene) as typical examples, the C atoms on the backbones of which may also be substituted by other non-C atoms, and which are still considered to be conjugated polymers when the sp² hybridization on the backbones is interrupted by some natural defects. In addition, the conjugated polymer in the present disclosure also comprises aryl amine, aryl phosphine and other heteroaromatics, organometallic complexes, and the like on the backbone.

In an embodiment, the content of the transition metal complex is from 0.01 wt % to 30 wt %. In an embodiment, the content of the transition metal complex is from 0.1 wt % to 20 wt %. In an embodiment, the content of the transition metal complex is from 0.2 wt % to 20 wt %. In an embodiment, the content of the transition metal complex is from 2 wt % to 15 wt %.

In an embodiment, the mixture comprises the transition metal complex described above and a triplet matrix material. At this point, the transition metal complex is used as a guest (phosphorescent emitter), and the weight percentage of the transition metal complex in the mixture is ≤30 wt %. In an embodiment, the weight percentage of the transition metal complex in the mixture is ≤20 wt %. Furthermore, the weight percentage of the transition metal complex in the mixture is ≤15 wt %.

In an embodiment, the mixture comprises the transition metal complex described above, a triplet matrix material and another triplet emitter.

In an embodiment, the mixture comprises the transition metal complex described above and a thermally activated delayed fluorescence material (TADF).

The triplet matrix materials, triplet emitters and TADF materials are described in more detail below (but are not limited thereto).

1. Triplet Host Material:

Examples of triplet host material are not particularly limited, and any metal complex or organic compound may be used as a host as long as its triplet energy is higher than that of an emitter, particularly a triplet emitter or a phosphorescent emitter. Examples of metal complex that can be used as a triplet host includes, but are not limited to, the following general structures:

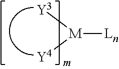

M is a metal; (Y³-Y⁴) is a bidentate ligand, Y³ and Y⁴ are independently selected from the group consisting of C, N, O, P, and S; L is an auxiliary ligand; m is an integer whose value is between 1 and a maximum coordination number of the metal; and m+n is the maximum coordination number of the metal.

In an embodiment, the metal complex that can be used as a triplet host has the following forms:

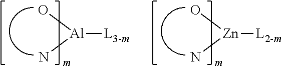

wherein, (O—N) is a bidentate ligand in which the metal is coordinated with O and N atoms.

In an embodiment, M is selected from Ir or Pt.

Examples of organic compounds that may be used as triplet host are selected from the group consisting of: compounds containing cyclic aromatic hydrocarbon groups such as, but not limited to benzene, biphenyl, triphenyl, benzo, and fluorene; and compounds containing aromatic heterocyclic groups, such as triphenylamine, dibenzothiophene, dibenzofuran, dibenzoselenophen, furan, thiophene, benzofuran, benzothiophene, benzoselenophene, carbazole, indolocarbazole, indolopyridine, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazin, oxadiazine, indole, benzimidazole, indoxazine, bisbenzoxazole, isoxazole, benzothiazole, quinoline, isoquinoline, cinnoline, quinazoline, quinoxaline, naphthalene, phthalein, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and groups containing 2 to 10 membered ring structures which may be the same or different types of cyclic aromatic groups or aromatic heterocyclic groups and are bonded to each other directly or through at least one of the following groups, for example: oxygen atom, nitrogen atom, sulfur atom, silicon atom, phosphorus atom, boron atom, chain structure unit, and aliphatic cyclic group; and wherein each Ar may be further optionally substituted, and the substituents may be selected from the group consisting of hydrogen, alkyl, alkoxy, amino, alkene, alkyne, aralkyl, heteroalkyl, aryl and heteroaryl. In an embodiment, the triplet host material may be selected from compounds containing at least one of the following groups:

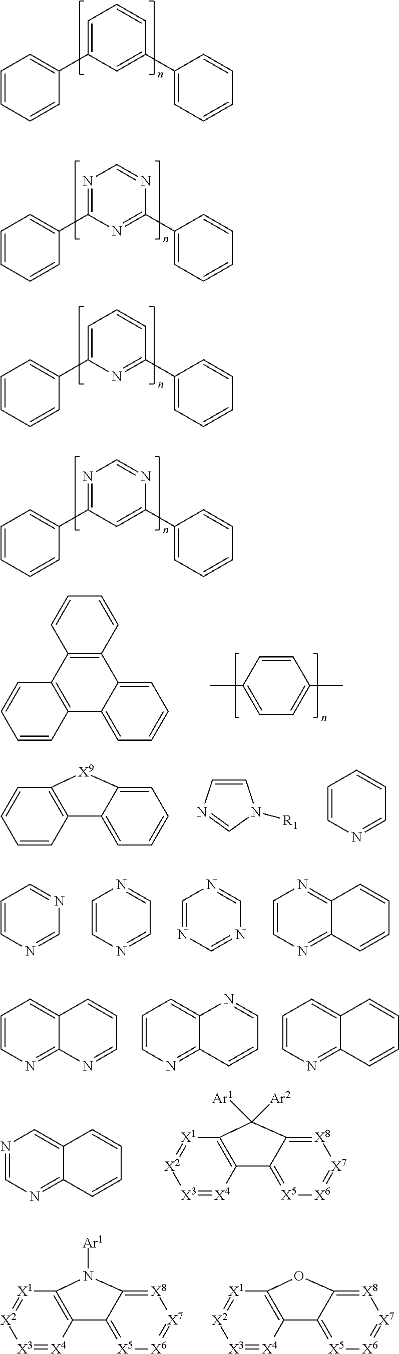

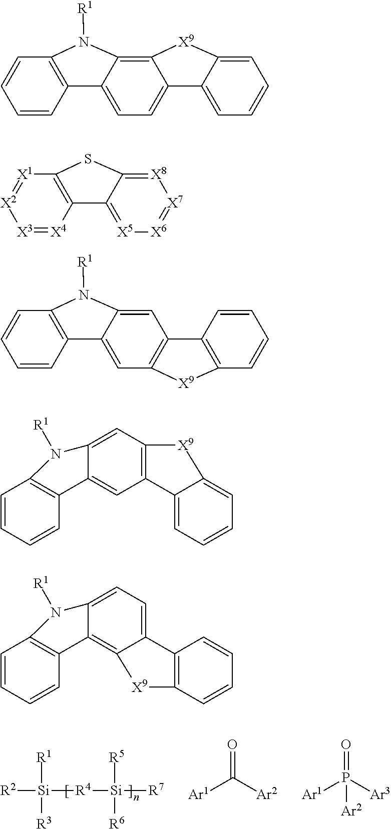

wherein, R¹-R⁷ may be independently selected from the group consisting of hydrogen, alkyl, alkoxy, amino, alkenyl, alkynyl, aralkyl, heteroalkyl, aryl and heteroaryl, and have the same meaning as the Ar¹ and the Ar² described above when they are aryl or heteroaryl; n is selected from 1, 2, 3, 4, 5, 6, 7, 8, 9, 10, 11, 12, 13, 14, 15, 16, 17, 18, 19 or 20; X¹-X⁸ are selected from CH or N; and X⁹ is selected from CR²R¹ or NR¹.

Some suitable examples of the triplet host material are listed in the following table.

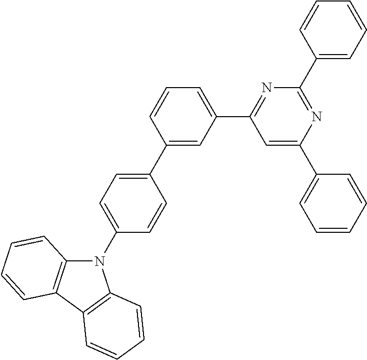 [SMILES: c1ccc(-c2cc(-c3cccc(-c4ccc(-n5c6ccccc6c6ccccc65)cc4)c3)nc(-c3ccccc3)n2)cc1]

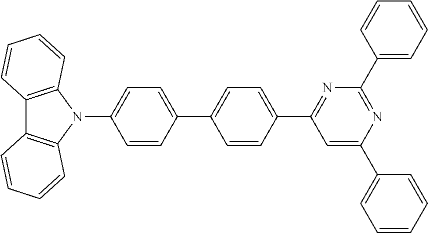 [SMILES: c1ccc(-c2cc(-c3ccc(-c4ccc(-n5c6ccccc6c6ccccc65)cc4)cc3)nc(-c3ccccc3)n2)cc1]

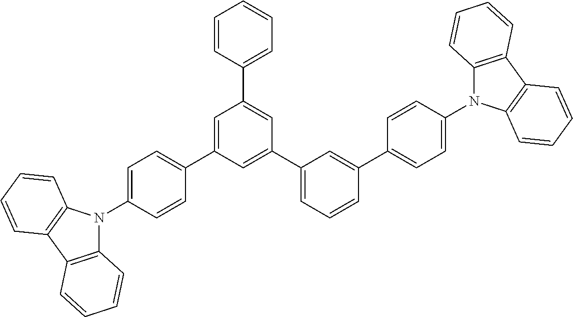 [SMILES: c1ccc(-c2cc(-c3ccc(-n4c5ccccc5c5ccccc54)cc3)cc(-c3cccc(-c4ccc(-n5c6ccccc6c6ccccc65)cc4)c3)c2)cc1]

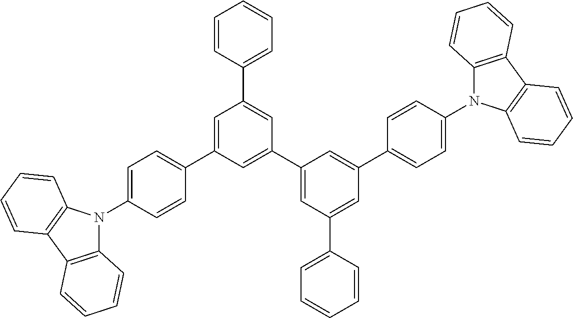 [SMILES: c1ccc(-c2cc(-c3ccc(-n4c5ccccc5c5ccccc54)cc3)cc(-c3cc(-c4ccccc4)cc(-c4ccc(-n5c6ccccc6c6ccccc65)cc4)c3)c2)cc1]

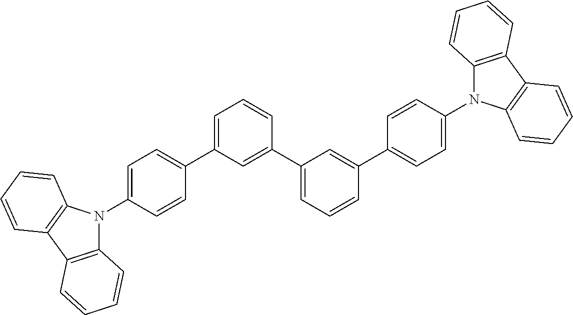 [SMILES: c1cc(-c2ccc(-n3c4ccccc4c4ccccc43)cc2)cc(-c2cccc(-c3ccc(-n4c5ccccc5c5ccccc54)cc3)c2)c1]

2. Triplet Emitter

Triplet emitters are also known as phosphorescent materials. In an embodiment, the triplet emitter is a metal complex containing the general formula M₂(L)n. Wherein, M₂ is a metal atom; and L may be the same or different at each occurrence and is an organic ligand which is bonded or coordinated to the metal atom M through one or more positions; n is an integer greater than 1, particularly 1, 2, 3, 4, 5, or 6. In an embodiment, these metal complexes are attached to a polymer through one or more positions, particularly through organic ligands.

In an embodiment, the metal atom M₂ is selected from the group consisting of transitional metal elements, lanthanide elements or actinide elements. In an embodiment, M is selected from the group consisting of Ir, Pt, Pd, Au, Rh, Ru, Os, Sm, Eu, Gd, Tb, Dy, Re, Cu or Ag. In an embodiment, M is selected from the group consisting of Os, Ir, Ru, Rh, Re, Pd or Pt.

In an embodiment, the triplet emitter may contain a chelating ligand, i.e., a ligand, coordinated to the metal by at least two bonding sites, and in an embodiment, the triplet emitter contains two or three identical or different bidentate or multidentate ligands. Chelating ligands help to improve the stability of metal complexes.

An example of the organic ligand is selected from the group consisting of phenylpyridine derivatives, 7,8-benzoquinoline derivatives, 2 (2-thienyl) pyridine derivatives, 2 (1-naphthyl) pyridine derivatives, and 2 phenylquinoline derivatives. All of these organic ligands may be substituted, for example, substituted by fluoromethyl or trifluoromethyl. The auxiliary ligand may be selected from acetone acetate or picric acid.

In an embodiment, the metal complex that can be used as triplet emitter has the following forms:

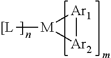

wherein, M is a metal and selected from transition metal elements, lanthanide elements or actinide elements.

Ar¹ is a cyclic group, which may be the same or different at each occurrence, and Ar¹ contains at least one donor atom, i.e. an atom containing a lone pair of electrons, such as nitrogen or phosphorus, coordinated to a metal thorough its cyclic group; Ar² is a cyclic group, which may be the same or different at each occurrence, and Ar² contains at least one C atom, which is attached to the metal through its cyclic group; Ar¹ and Ar² are covalently linked together and may each carry one or more substituent groups, which may also be linked together by a substituent group; L may be the same or different at each occurrence, and L is an auxiliary ligand, especially a bidentate chelating ligand, particularly a monoanionic bidentate chelating ligand; m is selected from 1, 2 or 3; n is selected from 0, 1 or 2. In an embodiment, L is a bidentate chelating ligand. In an embodiment, L is a monoanionic bidentate chelating ligand. In an embodiment, m is 2 or 3. In an embodiment, m is 3. In an embodiment, n is 0 or 1. In an embodiment, n is 0.

Some examples of triplet emitter materials and examples of applications thereof can be found in the following patent documents and references: WO 200070655, WO 200141512, WO 200202714, WO 200215645, EP 1191613, EP 1191612, EP 1191614, WO 2005033244, WO 2005019373, US 2005/0258742, WO 2009146770, WO 2010015307, WO 2010031485, WO 2010054731, WO 2010054728, WO 2010086089, WO 2010099852, WO 2010102709, US 20070087219 A1, US 20090061681 A1, US 20010053462 A1, Baldo, Thompson et al. Nature 403, (2000), 750-753, US 20090061681 A1, US 20090061681 A1, Adachi et al. Appl. Phys. Lett. 78 (2001), 1622-1624, J. Kido et al. Appl. Phys. Lett. 65 (1994), 2124, Kido et al. Chem. Lett. 657, 1990, US 2007/0252517 A1, Johnson et al., JACS 105, 1983, 1795, Wrighton, JACS 96, 1974, 998, Ma et al., Synth. Metals 94, 1998, 245, U.S. Pat. Nos. 6,824,895, 7,029,766, 6,835,469, 6,830,828, US 20010053462 A1, WO 2007095118 A1, US 2012004407A1, WO 2012007088A1, WO2012007087A1, WO 2012007086A1, US 2008027220A1, WO 2011157339A1, CN 102282150A, WO 2009118087A1. The entire contents of the above listed patent documents and literatures are hereby incorporated by reference.

Some suitable examples of triplet emitters are listed in the following table.

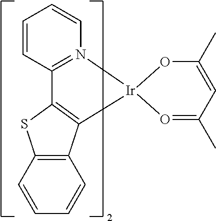

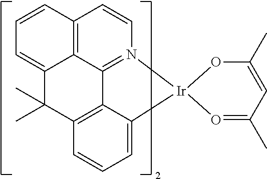

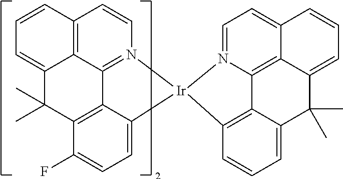

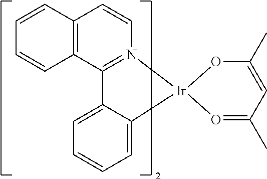

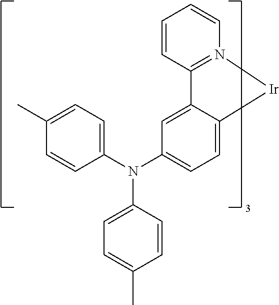

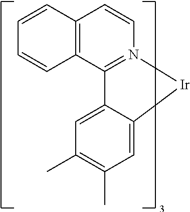

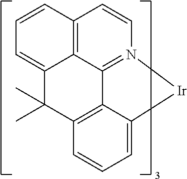

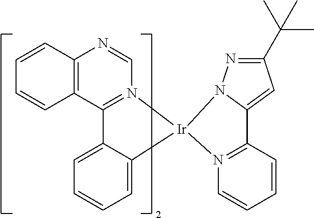

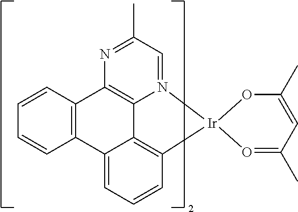

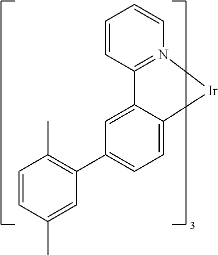

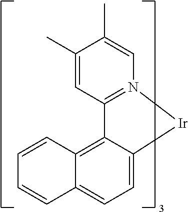

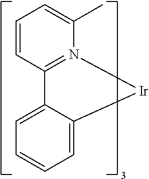

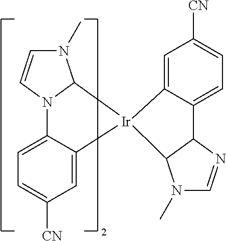

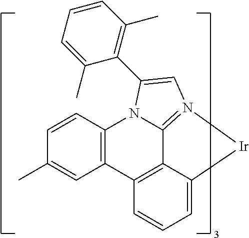

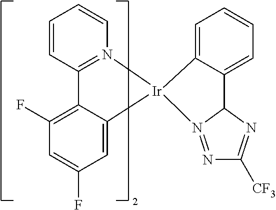

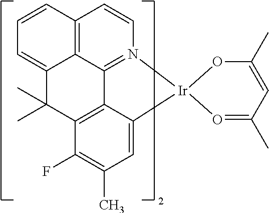

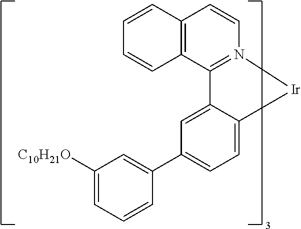

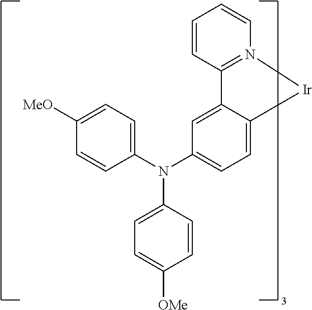

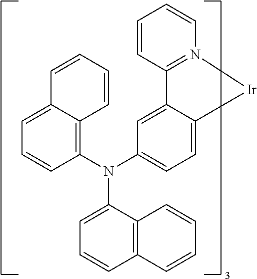

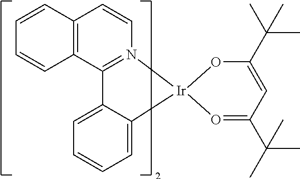

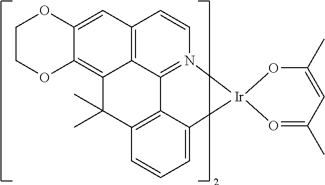

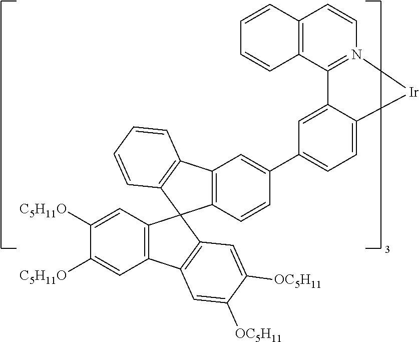

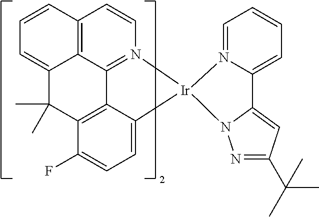

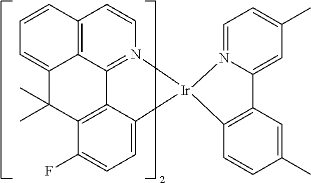

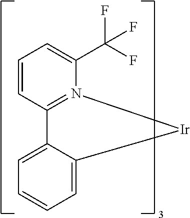

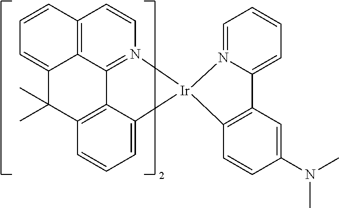

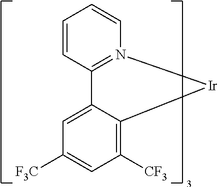

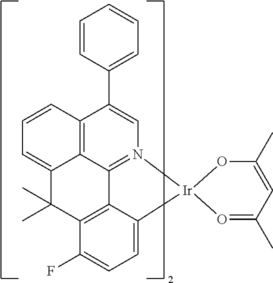

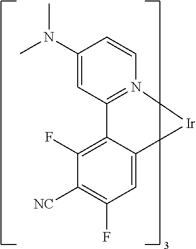

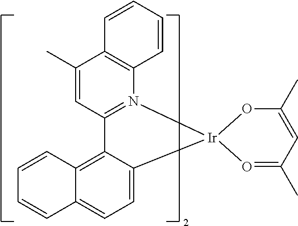

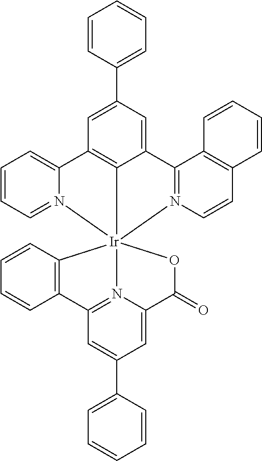

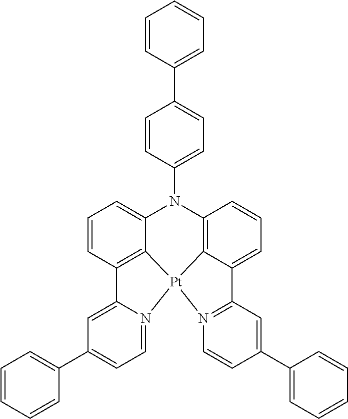

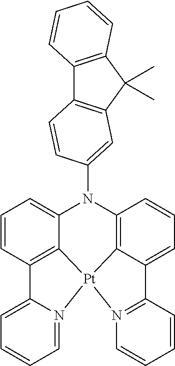

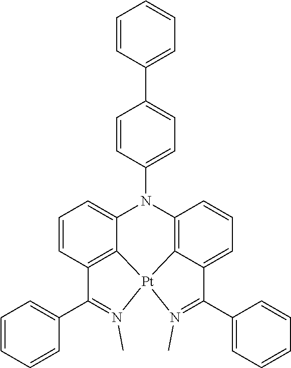

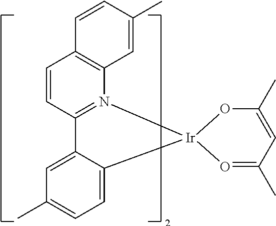

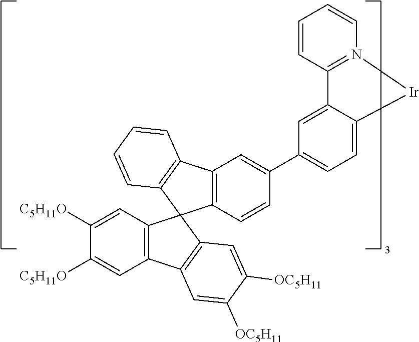

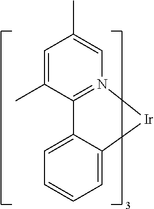

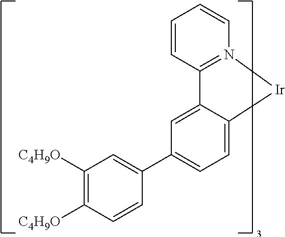

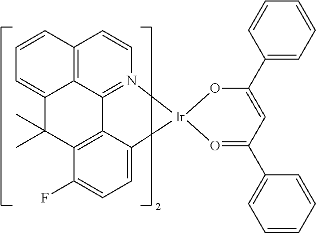

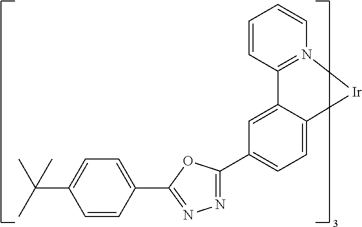

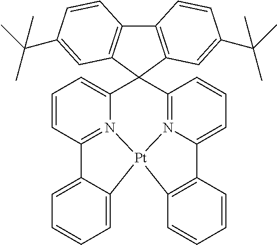

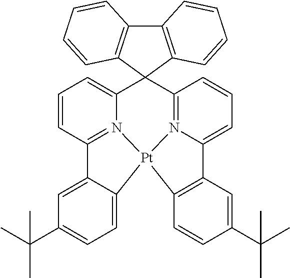

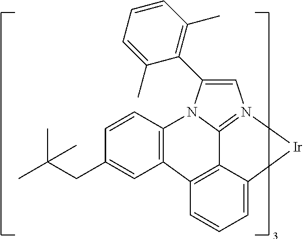

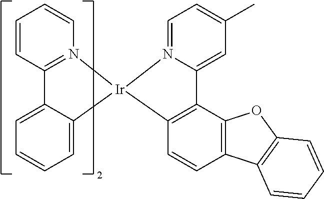

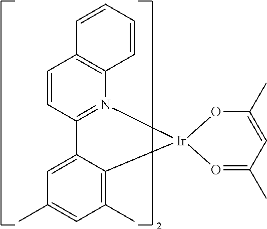

3. TADF Material

Traditional organic fluorescent materials can only emit light using 25% of singlet excitons formed by electrical excitation, and the internal quantum efficiency of the device is low (25% at most). Although the phosphorescent material enhances the intersystem crossing due to the strong spin-orbit coupling of the heavy atom center, light emission of the singlet excitons and the triplet excitons formed by the electric excitation can be effectively utilized, and the internal quantum efficiency of the device can reach 100%. However, the problems such as expensive phosphorescent materials, poor material stability, serious device efficiency roll-off and the like have limited the application of the phosphorescent materials in OLEDs. Thermally activated delayed fluorescent light-emitting materials are the third generation of organic light-emitting materials developed after organic fluorescent materials and organic phosphorescent materials. Such materials generally have a small singlet-triplet excited state energy level difference (ΔEst), and the triplet excitons can be converted to singlet excitons to emit light by inverted intersystem crossing. This can make full use of the singlet excitons and the triplet excitons formed under electric excitation. The device can achieve 100% of the internal quantum efficiency. At the same time, the material is controllable in structure, stable in property, low cost, unnecessary to use precious metals, and have a promising application prospect in the OLED field.

A TADF material needs to have a smaller singlet-triplet excited state energy level difference (ΔEst). In an embodiment, ΔEst<0.3 eV. In an embodiment, ΔEst<0.2 eV. In an embodiment, ΔEst<0.1 eV. In an embodiment, the TADF material has a relatively small ΔEst. In another embodiment, TADF has better fluorescence quantum efficiency. Some TADF materials can be found in the following patent documents: CN103483332(A), TW201309696(A), TW201309778(A), TW201343874(A), TW201350558(A), US20120217869(A1), WO2013133359(A1), WO2013154064(A1), Adachi, et. al. Adv. Mater., 21, 2009, 4802, Adachi, et. al. Appl. Phys. Lett., 98, 2011, 083302, Adachi, et. al. Appl. Phys. Lett., 101, 2012, 093306, Adachi, et. al. Chem. Commun., 48, 2012, 11392, Adachi, et. al. Nature Photonics, 6, 2012, 253, Adachi, et. al. Nature, 492, 2012, 234, Adachi, et. al. J. Am. Chem. Soc, 134, 2012, 14706, Adachi, et. al. Angew. Chem. Int. Ed, 51, 2012, 11311, Adachi, et. al. Chem. Commun., 48, 2012, 9580, Adachi, et. al. Chem. Commun., 48, 2013, 10385, Adachi, et. al. Adv. Mater., 25, 2013, 3319, Adachi, et. al. Adv. Mater., 25, 2013, 3707, Adachi, et. al. Chem. Mater., 25, 2013, 3038, Adachi, et. al. Chem. Mater., 25, 2013, 3766, Adachi, et. al. J. Mater. Chem. C., 1, 2013, 4599, Adachi, et. al. J. Phys. Chem. A., 117, 2013, 5607, the contents of the above-listed patents or article documents are hereby incorporated by reference in their entirety.

Some examples of suitable TADF light-emitting materials are listed in the following table.

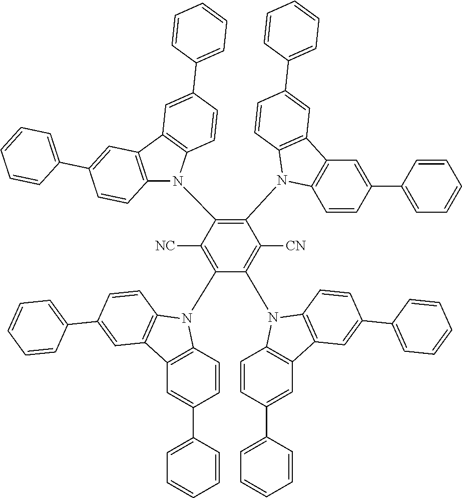 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

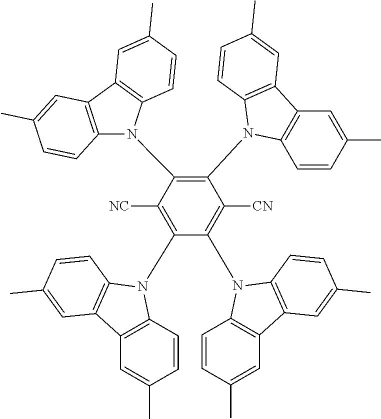

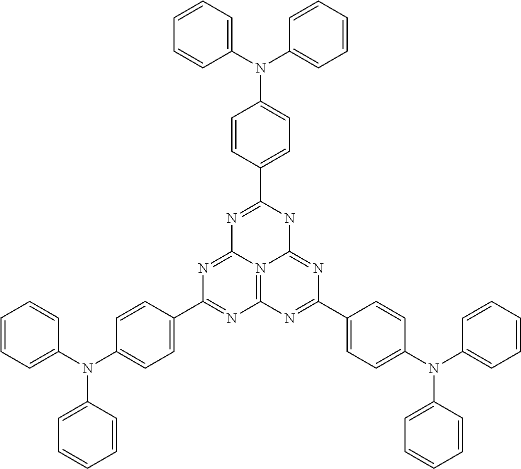

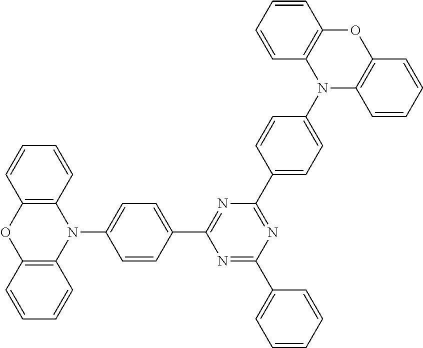 [SMILES: c1ccc(-c2nc(-c3ccc(N4c5ccccc5Oc5ccccc54)cc3)nc(-c3ccc(N4c5ccccc5Oc5ccccc54)cc3)n2)cc1]

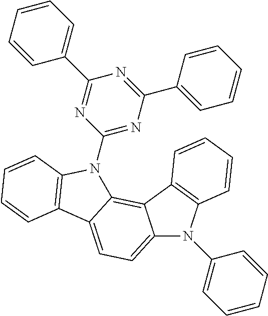 [SMILES: c1ccc(-c2nc(-c3ccccc3)nc(-n3c4ccccc4c4ccc5c(c6ccccc6n5-c5ccccc5)c43)n2)cc1]

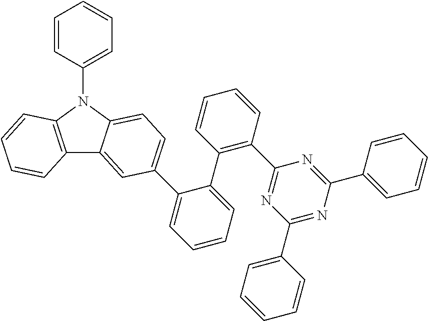 [SMILES: c1ccc(-c2nc(-c3ccccc3)nc(-c3ccccc3-c3ccccc3-c3ccc4c(c3)c3ccccc3n4-c3ccccc3)n2)cc1]

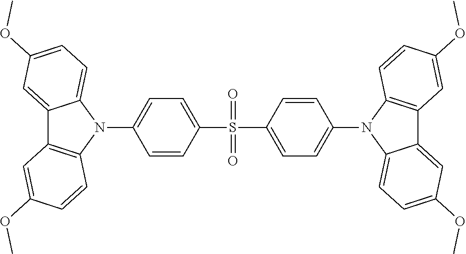 [SMILES: COc1ccc2c(c1)c1cc(OC)ccc1n2-c1ccc(S(=O)(=O)c2ccc(-n3c4ccc(OC)cc4c4cc(OC)ccc43)cc2)cc1]

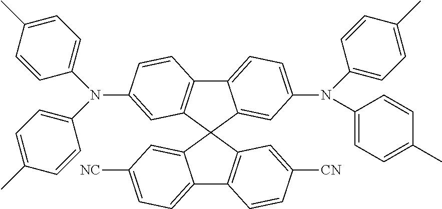

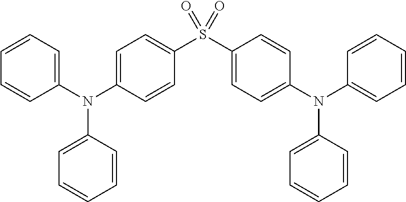 [SMILES: O=S(=O)(c1ccc(N(c2ccccc2)c2ccccc2)cc1)c1ccc(N(c2ccccc2)c2ccccc2)cc1]

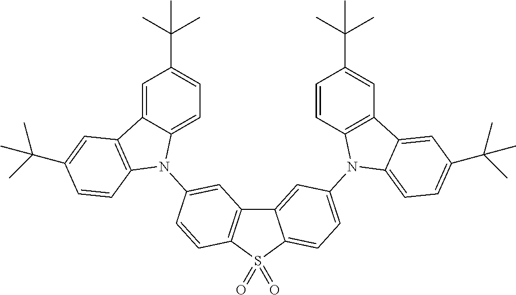 [SMILES: CC(C)(C)c1ccc2c(c1)c1cc(C(C)(C)C)ccc1n2-c1ccc2c(c1)-c1cc(-n3c4ccc(C(C)(C)C)cc4c4cc(C(C)(C)C)ccc43)ccc1S2(=O)=O]

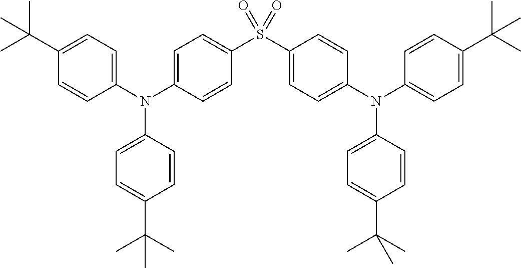 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

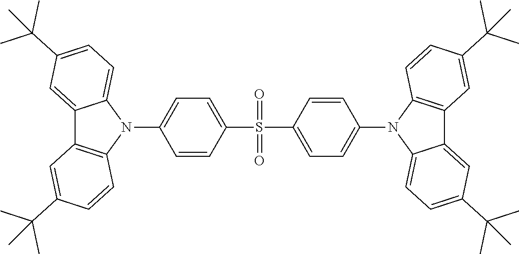 [SMILES: CC(C)(C)c1ccc2c(c1)c1cc(C(C)(C)C)ccc1n2-c1ccc(S(=O)(=O)c2ccc(-n3c4ccc(C(C)(C)C)cc4c4cc(C(C)(C)C)ccc43)cc2)cc1]

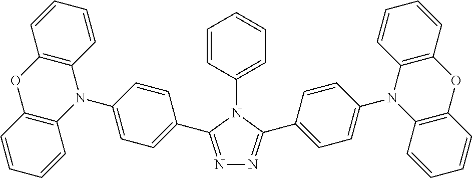 [SMILES: c1ccc(-n2c(-c3ccc(N4c5ccccc5Oc5ccccc54)cc3)nnc2-c2ccc(N3c4ccccc4Oc4ccccc43)cc2)cc1]

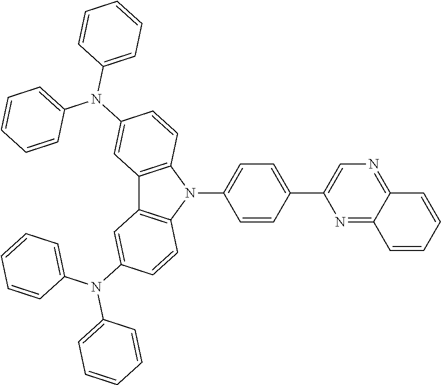 [SMILES: c1ccc(N(c2ccccc2)c2ccc3c(c2)c2cc(N(c4ccccc4)c4ccccc4)ccc2n3-c2ccc(-c3cnc4ccccc4n3)cc2)cc1]

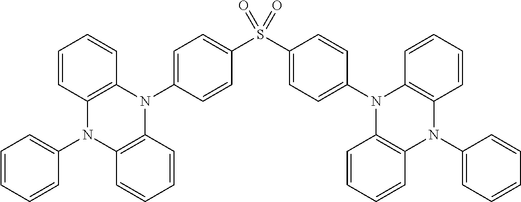 [SMILES: O=S(=O)(c1ccc(N2c3ccccc3N(c3ccccc3)c3ccccc32)cc1)c1ccc(N2c3ccccc3N(c3ccccc3)c3ccccc32)cc1]

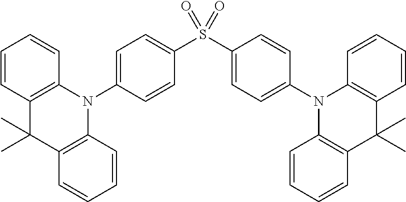 [SMILES: CC1(C)c2ccccc2N(c2ccc(S(=O)(=O)c3ccc(N4c5ccccc5C(C)(C)c5ccccc54)cc3)cc2)c2ccccc21]

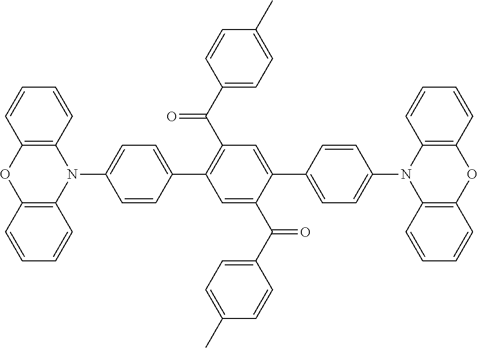 [SMILES: Cc1ccc(C(=O)c2cc(-c3ccc(N4c5ccccc5Oc5ccccc54)cc3)c(C(=O)c3ccc(C)cc3)cc2-c2ccc(N3c4ccccc4Oc4ccccc43)cc2)cc1]

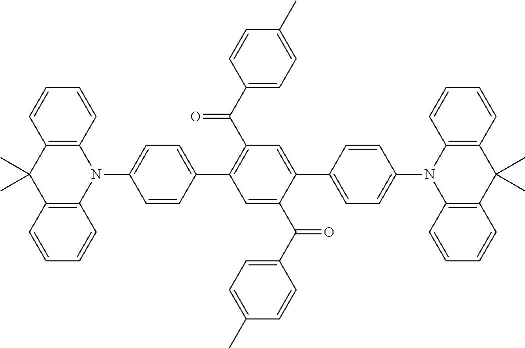

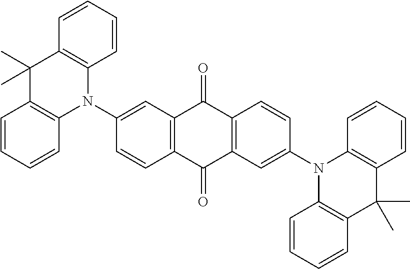 [SMILES: CC1(C)c2ccccc2N(c2ccc3c(c2)C(=O)c2ccc(N4c5ccccc5C(C)(C)c5ccccc54)cc2C3=O)c2ccccc21]

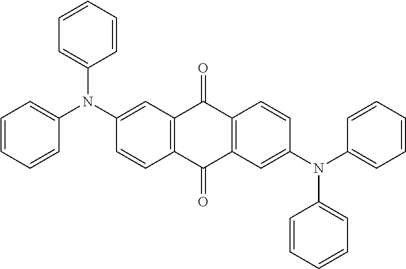 [SMILES: O=C1c2ccc(N(c3ccccc3)c3ccccc3)cc2C(=O)c2ccc(N(c3ccccc3)c3ccccc3)cc21]

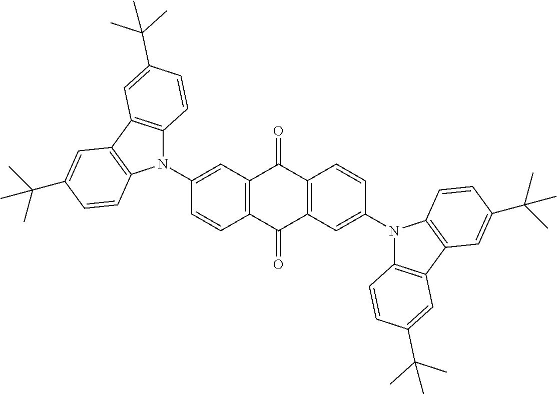 [SMILES: CC(C)(C)c1ccc2c(c1)c1cc(C(C)(C)C)ccc1n2-c1ccc2c(c1)C(=O)c1ccc(-n3c4ccc(C(C)(C)C)cc4c4cc(C(C)(C)C)ccc43)cc1C2=O]

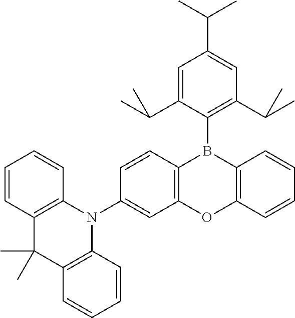 [SMILES: CC(C)c1cc(C(C)C)c(B2c3ccccc3Oc3cc(N4c5ccccc5C(C)(C)c5ccccc54)ccc32)c(C(C)C)c1]

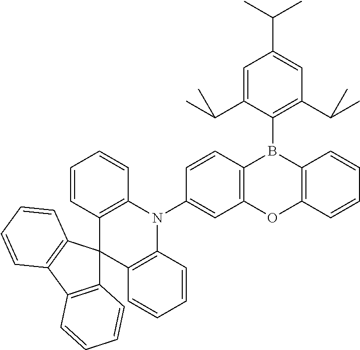 [SMILES: CC(C)c1cc(C(C)C)c(B2c3ccccc3Oc3cc(N4c5ccccc5C5(c6ccccc6-c6ccccc65)c5ccccc54)ccc32)c(C(C)C)c1]

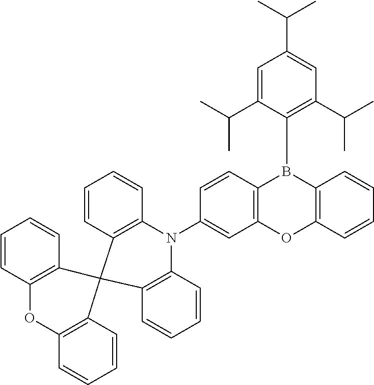 [SMILES: CC(C)c1cc(C(C)C)c(B2c3ccccc3Oc3cc(N4c5ccccc5C5(c6ccccc6Oc6ccccc65)c5ccccc54)ccc32)c(C(C)C)c1]

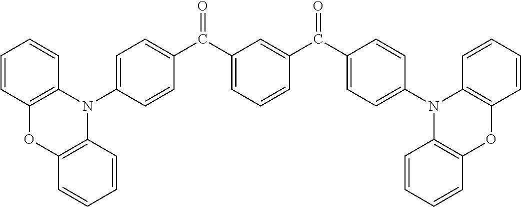 [SMILES: O=C(c1ccc(N2c3ccccc3Oc3ccccc32)cc1)c1cccc(C(=O)c2ccc(N3c4ccccc4Oc4ccccc43)cc2)c1]

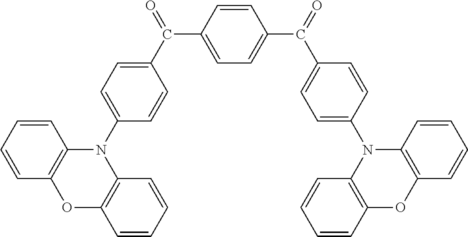 [SMILES: O=C(c1ccc(C(=O)c2ccc(N3c4ccccc4Oc4ccccc43)cc2)cc1)c1ccc(N2c3ccccc3Oc3ccccc32)cc1]

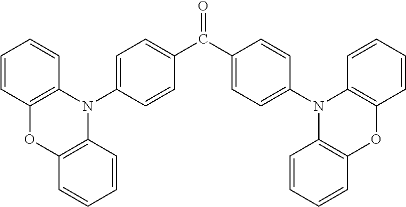 [SMILES: O=C(c1ccc(N2c3ccccc3Oc3ccccc32)cc1)c1ccc(N2c3ccccc3Oc3ccccc32)cc1]

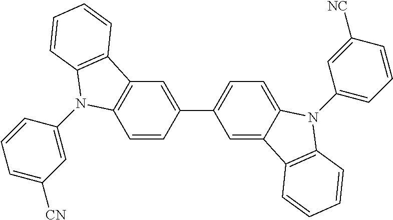 [SMILES: N#Cc1cccc(-n2c3ccccc3c3cc(-c4ccc5c(c4)c4ccccc4n5-c4cccc(C#N)c4)ccc32)c1]

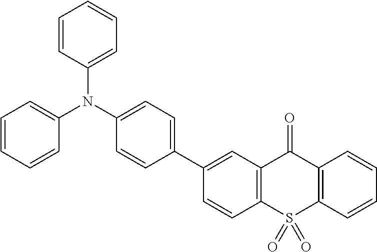 [SMILES: O=C1c2ccccc2S(=O)(=O)c2ccc(-c3ccc(N(c4ccccc4)c4ccccc4)cc3)cc21]

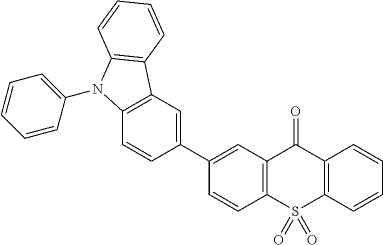 [SMILES: O=C1c2ccccc2S(=O)(=O)c2ccc(-c3ccc4c(c3)c3ccccc3n4-c3ccccc3)cc21]

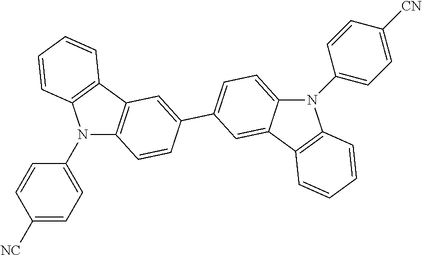 [SMILES: N#Cc1ccc(-n2c3ccccc3c3cc(-c4ccc5c(c4)c4ccccc4n5-c4ccc(C#N)cc4)ccc32)cc1]

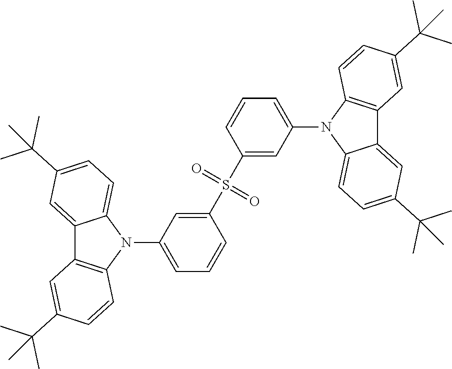 [SMILES: CC(C)(C)c1ccc2c(c1)c1cc(C(C)(C)C)ccc1n2-c1cccc(S(=O)(=O)c2cccc(-n3c4ccc(C(C)(C)C)cc4c4cc(C(C)(C)C)ccc43)c2)c1]

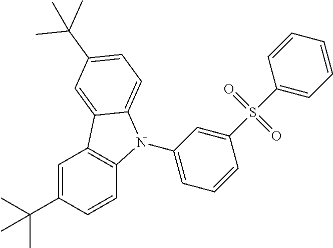 [SMILES: CC(C)(C)c1ccc2c(c1)c1cc(C(C)(C)C)ccc1n2-c1cccc(S(=O)(=O)c2ccccc2)c1]

In an embodiment, the transition metal complex is used for vaporized OLED devices. At this point, the molecular weight of the transition metal complex is ≤1000 g/mol. In an embodiment, the molecular weight of the transition metal complex is ≤900 g/mol. In an embodiment, the molecular weight of the transition metal complex is ≤850 g/mol. In an embodiment, the molecular weight of the transition metal complex is ≤800 g/mol. In an embodiment, the molecular weight of the transition metal complex is ≤700 g/mol.

In an embodiment, the transition metal complex is used for printed OLED devices. At this point, the molecular weight of the transition metal complex is ≥700 g/mol. In an embodiment, the molecular weight of the transition metal complex is ≥800 g/mol. In an embodiment, the molecular weight of the transition metal complex is ≥900 g/mol. In an embodiment, the molecular weight of the transition metal complex is ≥1000 g/mol. In an embodiment, the molecular weight of the transition metal complex is ≥1100 g/mol.

In an embodiment, the solubility of the aforementioned transition metal complex in toluene is ≥5 mg/ml at 25° C. In an embodiment, the solubility in toluene 8 mg/ml. In an embodiment, the solubility in toluene is ≥10 mg/ml.

The mixture of another embodiment comprises the above-mentioned polymer, and the various components and contents of the mixture are as described in the mixture of the above embodiment, and will not be described herein.

A formulation of an embodiment comprises an organic solvent and the above-mentioned transition metal complex or the polymer or the mixture. In this embodiment, the formulation is ink. The viscosity and surface tension of ink are important parameters when the formulation is used in the printing process. The surface tension parameters of suitable ink are suitable for a particular substrate and a particular printing method. Further, the present disclosure provides a thin film comprising the transition metal complex or the polymer according to the present disclosure prepared from a solution.

In an embodiment, the surface tension of the ink at working temperature or at 25° C. is in the range of 19 dyne/cm to 50 dyne/cm. In an embodiment, the surface tension of the ink at working temperature or at 25° C. is in the range of 22 dyne/cm to 35 dyne/cm. In an embodiment, the surface tension of the ink at working temperature or at 25° C. is in the range of 25 dyne/cm to 33 dyne/cm.

In an embodiment, the viscosity of the ink at working temperature or at 25° C. is in the range of 1 cps to 100 cps. In an embodiment, the viscosity of the ink at working temperature or at 25° C. is in the range of 1 cps to 50 cps. In an embodiment, the viscosity of the ink at working temperature or at 25° C. is in the range of 1.5 cps to 20 cps. In an embodiment, the viscosity of the ink at working temperature or at 25° C. is in the range of about 4.0 cps to 20 cps. Therefore, the formulation is more convenient for inkjet printing.

The viscosity can be adjusted by different methods, such as by selection of the appropriate solvent and the concentration of functional materials in the ink. The ink containing the transition metal complex or the polymer can facilitate the adjustment of the printing ink in an appropriate range according to the used printing method. The weight ratio of the organic functional material included in the formulation is 0.3 wt % to 30 wt %. In an embodiment, the weight ratio of the organic functional material included in the formulation is 0.5 wt % to 20 wt %. In an embodiment, the weight ratio of the organic functional material included in the formulation is 0.5 wt % to 15 wt %. In an embodiment, the weight ratio of the organic functional material included in the formulation is 0.5 wt % to 10 wt %. In an embodiment, the weight ratio of the organic functional material included in the formulation is 1 wt % to 5 wt %.

In an embodiment, the organic solvent comprises a first solvent selected from aromatic and/or heteroaromatic based solvents. Further, the first solvent may be an aliphatic chain/ring substituted aromatic solvent, an aromatic ketone solvent, or an aromatic ether solvent.

Examples of the first solvent include, but are not limited to, aromatic or heteroaromatic based solvents: p-diisopropylbenzene, pentylbenzene, tetrahydronaphthalene, cyclohexyl benzene, chloronaphthalene, 1,4-dimethylnaphthalene, 3-isopropylbiphenyl, p-cymene, dipentylbenzene, tripentylbenzene, pentyltoluene, o-xylene, m-xylene, p-xylene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, 1-methoxynaphthalene, cyclohexylbenzene, dimethylnaphthalene, 3-isopropylbiphenyl, p-cymene, 1-methylnaphthalene, 1,2,4-trichlorobenzene, 1,3-dipropoxybenzene, 4,4-difluorodiphenylmethane, 1,2-dimethoxy-4-(1-propenyl)benzene, diphenylmethane, 2-phenylpyridine, 3-phenylpyridine, N-methyldiphenylamine 4-isopropylbiphenyl, α, α-dichlorodiphenylmethane, 4-(3-phenylpropyl)pyridine, benzylbenzoate, 1,1-di(3,4-dimethylphenyl)ethane, 2-isopropylnaphthalene, dibenzylether, and etc.; solvents based on ketones: 1-tetralone, 2-tetralone, 2-(phenylepoxy)tetralone, 6-(methoxyl)tetralone, acetophenone, phenylacetone, benzophenone, and derivatives thereof, such as 4-methylacetophenone, 3-methylacetophenone, 2-methylacetophenone, 4-methylphenylacetone, 3-methylphenylacetone, 2-methylphenylacetone, isophorone, 2,6,8-trimethyl-4-nonanone, fenchone, 2-nonanone, 3-nonanone, 5-nonanone, 2-demayone, 2,5-hexanedione, phorone, di-n-amyl ketone; aromatic ether solvents: 3-phenoxytoluene, butoxybenzene, benzylbutylbenzene, p-anisaldehyde dimethyl acetal, tetrahydro-2-phenoxy-2H-pyran, 1,2-dimethoxy 4-(1-propenyl)benzene, 1,4-benzodioxane, 1,3-dipropylbenzene, 2,5-dimethoxytoluene, 4-ethylphenetole, 1,2,4-trimethoxybenzene, 4-(1-propenyl)-1,2-dimethoxybenzene, 1,3-dimethoxybenzene, glycidyl phenyl ether, dibenzyl ether, 4-tert-butylanisole, trans-p-propenylanisole, 1,2-dimethoxybenzene, 1-methoxynaphthalene, diphenyl ether, 2-phenoxymethyl ether, 2-phenoxytetrahydrofuran, ethyl-2-naphthyl ether, pentyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether; and ester solvents: alkyl octoate, alkyl sebacate, alkyl stearate, alkyl benzoate, alkyl phenylacetate, alkyl cinnamate, alkyl oxalate, alkyl maleate, alkyl lactone, alkyl oleate, and the like.

Further, the first solvent may also be one or more selected from the group consisting of aliphatic ketones, such as 2-nonanone, 3-nonanone, 5-nonanone, 2-demayone, 2,5-hexanedione, 2,6,8-trimethyl-4-demayone, phorone, di-n-pentyl ketone, and etc.; or aliphatic ethers, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethyl ether alcohol ethyl methyl ether, triethylene glycol butyl methyl ether, tripropylene glycol dimethyl ether, tetraethylene glycol dimethyl ether.

In an embodiment, the organic solvent further comprises a second solvent, and the second solvent is one or more selected from the group consisting of methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1,4-dioxane, acetone, methyl ethyl ketone, 1,2-dichloroethane, 3-phenoxy toluene, 1,1,1-trichloroethane, 1,1,2,2-tetrachloroethane, ethyl acetate, butyl acetate, dimethylformamide, dimethylacetamide, dimethyl sulfoxide, tetrahydronaphthalene, decalin and indene.

In an embodiment, the formulation may be a solution or a suspension, and it depends on the compatibility of the organic mixture with the organic solvent.

The use of the formulation as a coating or printing ink in the preparation of organic electronic devices is provided, specially preferably by the preparation method of printing or coating.

Wherein, the appropriate printing technology or coating technology includes, but is not limited to inkjet printing, nozzle printing, typography, screen printing, dip coating, spin coating, blade coating, roller printing, twist roller printing, lithography, flexography, rotary printing, spray coating, brush coating, or pad printing, or slot die coating, and the like. Preferred are gravure printing, nozzle printing and inkjet printing. The formulation may further include a component selected one or more from a surfactant compound, a lubricant, a wetting agent, a dispersant, a hydrophobic agent and a binder, so as to adjust the viscosity and the film forming property and to improve the adhesion property. For more information about printing technologies and relevant requirements thereof on related solutions, such as solvents and concentration, viscosity, etc., see Handbook of Print Media: Technologies and Production Methods, ISBN 3-540-67326-1, edited by Helmut Kipphan.

In an embodiment, the application of the aforementioned transition metal complex or polymer in the organic electronic device is provided. The organic electronic device may be selected from the group consisting of organic light-emitting diode (OLED), organic photovoltaic cell (OPV), organic light-emitting electrochemical cell (OLEEC), organic field effect transistor (OFET), organic light-emitting field effect transistor, organic laser, organic spintronic device, organic sensor, and organic plasmon emitting diode. In an embodiment, the organic electronic device is an OLED. Further, the transition metal complex is used for the light-emitting layer of the OLED.

An organic electronic device of an embodiment comprises at least one of the aforementioned transition metal complex or polymer or mixture. Wherein, the organic electronic device may comprise a cathode, an anode and a functional layer located between the cathode and the anode, and the functional layer comprises the aforementioned transition metal complex or aforementioned polymer or aforementioned mixture, or the functional layer is prepared by the aforementioned formulation. Specifically, the organic electronic device comprises at least a cathode, an anode and a functional layer located between the cathode and the anode, and the functional layer comprises at least one of the aforementioned transition metal complex or aforementioned polymer or aforementioned mixture, or the functional layer is prepared by the aforementioned formulation. The functional layer is one or more selected from the group consisting of hole injection layer, hole transport layer, hole blocking layer, electron injection layer, electron transport layer, electron blocking layer and light-emitting layer.

The organic electronic device may be selected from the group consisting of organic light-emitting diode (OLED), organic photovoltaic cell (OPV), organic light-emitting electrochemical cell (OLEEC), organic field effect transistor (OFET), organic light-emitting field effect transistor, organic laser, organic spintronic device, organic sensor, and organic plasmon emitting diode. In an embodiment, the organic electronic device is an organic electroluminescent device, such as OLED.

In an embodiment, the OLED comprises a substrate, an anode, a light-emitting layer and a cathode which are sequentially stacked. Wherein, the number of layers of the light-emitting layer is at least one layer.

The substrate may be opaque or transparent. The transparent substrate can be used to prepare a transparent light-emitting device, which may refers to Bulovic et al. Nature 1996, 380, p29, and Gu et al. Appl. Phys. Lett. 1996, 68, p2606. The substrate may be rigid or elastic. The substrate may be plastic, metal, semiconductor wafer or glass. Particularly, the substrate has a smooth surface. The substrate without surface defect is a particular desirable choice. In an embodiment, the substrate is flexible and may be selected from polymer thin film or plastic, with its glass transition temperature Tg of 150° C. or more. The flexible substrate may be polyethylene terephthalate (PET) or polyethylene 2,6-naphthalate (PEN). In an embodiment, the glass transition temperature T_{g} of the substrate is 200° C. or more. In an embodiment, the glass transition temperature T_{g} of the substrate is 250° C. or more. In an embodiment, the glass transition temperature T_{g} of the substrate is 300° C. or more.

The anode may include a conductive metal, a metallic oxide, or a conductive polymer. The anode can inject holes easily into the hole injection layer (HIL), or the hole transport layer (HTL), or the light-emitting layer. In an embodiment, the absolute value of the difference between the work function of the anode and the HOMO energy level or the valence band energy level of the emitter in the light-emitting layer or of the p-type semiconductor material as the HIL or HTL or the electron blocking layer (EBL) is less than 0.5 eV. In an embodiment, the absolute value of the difference between the work function of the anode and the HOMO energy level or the valence band energy level of the emitter in the light-emitting layer or of the p-type semiconductor material as the HIL or HTL or the electron blocking layer (EBL) is less than 0.3 eV. In an embodiment, the absolute value of the difference between the work function of the anode and the HOMO energy level or the valence band energy level of the emitter in the light-emitting layer or of the p-type semiconductor material as the HIL or HTL or the electron blocking layer (EBL) is less than 0.2 eV. Examples of the anode material include, but are not limited to Al, Cu, Au, Ag, Mg, Fe, Co, Ni, Mn, Pd, Pt, ITO, aluminum-doped zinc oxide (AZO), and the like. The anode material may also be other materials. The anode material may be deposited by any suitable technologies, such as the suitable physical vapor deposition method which includes radio frequency magnetron sputtering, vacuum thermal evaporation, e-beam, and the like. In other embodiments, the anode is patterned. Patterned ITO conductive substrates are commercially available and can be used to prepare the organic electronic device according to the present disclosure.

The cathode may include a conductive metal or metal oxide. The cathode can inject electrons easily into the EIL or ETL, or directly injected into the light-emitting layer. In an embodiment, the absolute value of the difference between the work function of the cathode and the LUMO energy level or the conduction band energy level of the emitter in the light-emitting layer or of the n type semiconductor material as the electron injection layer (EIL) or the electron transport layer (ETL) or the hole blocking layer (HBL) is less than 0.5 eV. In an embodiment, the absolute value of the difference between the work function of the cathode and the LUMO energy level or the conduction band energy level of the emitter in the light-emitting layer or of the n type semiconductor material as the electron injection layer (EIL) or the electron transport layer (ETL) or the hole blocking layer (HBL) is less than 0.3 eV. In an embodiment, the absolute value of the difference between the work function of the cathode and the LUMO energy level or the conduction band energy level of the emitter in the light-emitting layer or of the n type semiconductor material as the electron injection layer (EIL) or the electron transport layer (ETL) or the hole blocking layer (HBL) is less than 0.2 eV. All materials that can be used as the cathode of the OLED may be used as the cathode material of the organic electronic device of the present embodiment. Examples of the cathode materials comprise, but not limited to: Al, Au, Ag, Ca, Ba, Mg, LiF/Al, MgAg alloy, BaF₂/Al, Cu, Fe, Co, Ni, Mn, Pd, Pt, ITO, and the like. The cathode material may be deposited by any suitable technologies, such as the suitable physical vapor deposition method which includes radio frequency magnetron sputtering, vacuum thermal evaporation, e-beam, etc.

OLED may also comprise other functional layers such as hole injection layer (HIL), hole transport layer (HTL), electron blocking layer (EBL), electron injection layer (EIL), electron transport layer (ETL), and hole blocking layer (HBL). The materials suitable for use in such functional layers have been described in detail above.

In an embodiment, in the light-emitting device according to the present disclosure, the light-emitting layer comprises the transition metal complex or the polymer according to the present disclosure and light-emitting layer may be prepared by vacuum evaporation or solution processing method.

In an embodiment, the light emission wavelength of the organic electroluminescent device is between 300 and 1000 nm. In an embodiment, the light emission wavelength of the organic electroluminescent device is between 350 and 900 nm. In an embodiment, the light emission wavelength of the organic electroluminescent device is between 400 and 800 nm.

In an embodiment, application of the aforementioned organic electronic device in electronic equipment is provided. The electronic equipment is selected from display equipment, lighting equipment, light source or sensor. Wherein, the organic electronic device may be an organic electroluminescent device.

An electronic equipment comprising the aforementioned organic electronic device is provided.

The present disclosure will be described below with reference to the preferred embodiments, but the present disclosure is not limited to the following embodiments. It should be understood that the appended claims summarized the scope of the present disclosure. Those skilled in the art should realize that certain changes to the embodiments of the present disclosure that are made under the guidance of the concept of the present disclosure will be covered by the spirit and scope of the claims of the present disclosure.

### 1. Transition Metal Complex and its Energy Structure

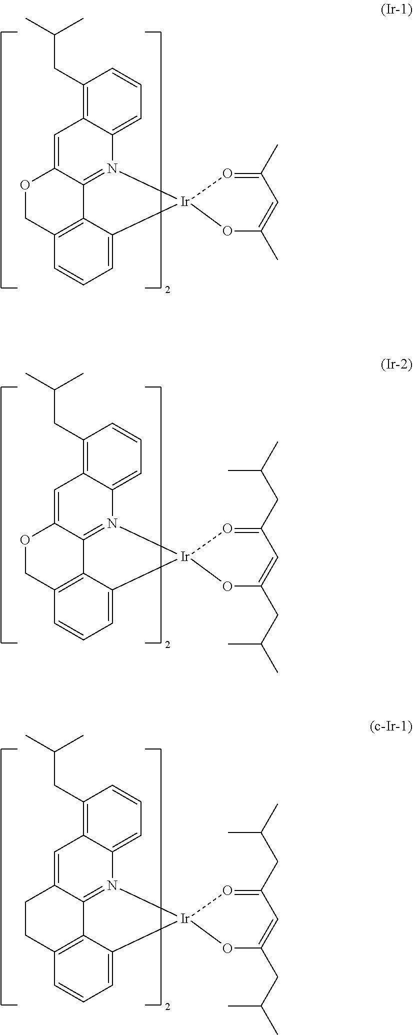

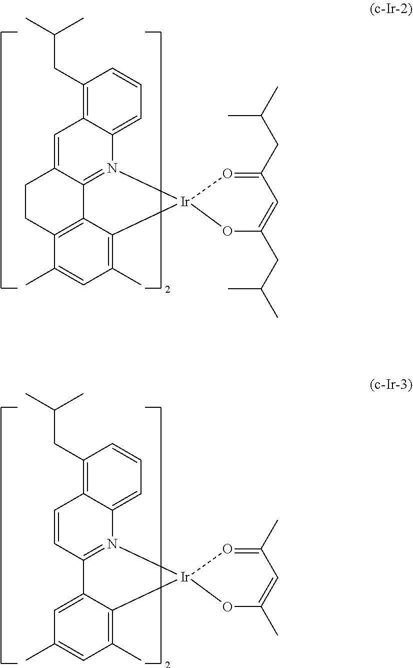

The energy levels of the transition metal complex can be obtained by quantum calculation, for example, by using TD-DFT (time-dependent density functional theory) through GaussianO3W (Gaussian Inc.), and specific simulation methods can be found in WO2011141110. First, the molecular geometry is optimized by semi-empirical method “Ground State/Hartree-Fock/Default Spin/LanL2 MB” (Charge 0/Spin Singlet), and then the energy structure of organic molecules is determined by TD-DFT (time-dependent density functional theory) Count “TD-SCF/DFT/Default Spin/B3PW91/gen geom=communication pseudo=lanl2” (Charge 0/Spin Singlet). The HOMO and LUMO energy levels are calculated using the following calibration formula, and S1 and T1 are used directly.

HOMO(eV)=((HOMO(Gaussian)×27.212)−0.9899)/1.1206

LUMO(eV)=((LUMO(Gaussian)×27.212)−2.0041)/1.385

wherein, HOMO(G) and LUMO(G) in the unit of Hartree are the direct calculation results of Gaussian 03W. The results were shown in Table 1:

TABLE 1

| Materials | HOMO [eV] | LUMO [eV] | T1 [eV] | S1 [eV] |
|---|---|---|---|---|
| Ir-1 | −5.35 | −2.70 | 2.35 | 2.55 |
| Ir-2 | −5.37 | −2.72 | 2.35 | 2.55 |
| c-Ir-1 | −5.17 | −2.63 | 2.29 | 2.51 |
| c-Ir-2 | −4.95 | −2.58 | 2.06 | 2.41 |
| c-Ir-3 | −5.10 | −2.68 | 2.15 | 2.36 |

### 2. Synthesis of the Transition Metal Complex

### Synthesis Example 1: Synthesis of Complex Ir-1

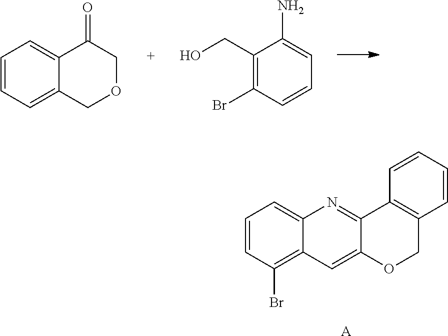

### Synthesis of Intermediate A

Isochroman-4-one (1.73 g, 1.1 eq), 2-bromo-6-aminobenzyl alcohol (2 g, 1 eq), RuCl₂(pph₃)₃ (0.12 g, 0.01 eq), potassium hydroxide (1.43 g, 2 eq) were placed in a dry 250 mL two-necked flask. The flask was evacuated and filled with nitrogen and the cycle was repeated for three times. Then anhydrous toluene (100 mL) was added, and then the reaction was carried out at 120° C. for 24 hours with stirring. After the reaction liquid was spun dry, dichloromethane (DCM) was added for extraction. After concentration, the purification was carried out by column with ethyl acetate: petroleum ether (EA/PE)=1:2 to obtain pale white intermediate A (yield 80%).

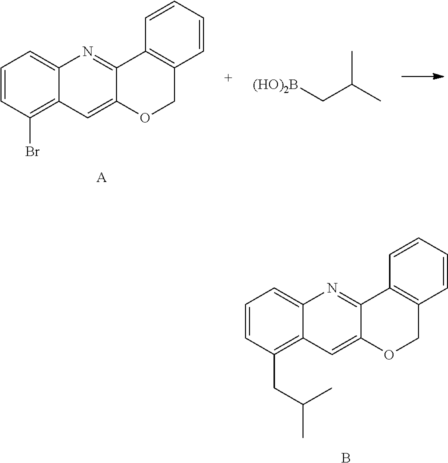

### Synthesis of Intermediate B

Intermediate A (1 g, 1 eq), isobutaneboronic acid (0.49 g, 1.5 eq), Pd₂(dba)₃ (0.09 g, 0.03 eq), S-phos (0.12 g, 0.06 eq), K₃PO₄ (2.73 g, 4 eq) were placed in a dry 250 mL two-necked flask. The flask was evacuated and filled with nitrogen and the cycle was repeated for three times. Then anhydrous toluene (60 mL) was added, and then the reaction was carried out at 120° C. for 24 hours with stirring. After the reaction liquid was spun dry, DCM was added for extraction. After concentration, the purification was carried out by silica gel with DCM:PE=1:4 to obtain pale white intermediate B (yield 85%).

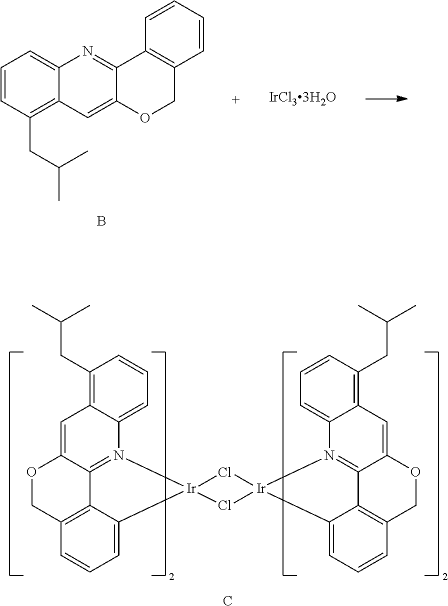

### Synthesis of Intermediate C

Intermediate B (1.50 g, 2.2 eq) and iridium trichloride trihydrate (0.83 g, 1 eq) were placed in a dry 250 ml flask. The flask was evacuated and filled with nitrogen and the cycle was repeated three times. Then a mixed solution (120 mL) of ethylene glycol ether:water in a ratio of 3:1 was added, the reaction was carried out at 110° C. for 24 hours with stirring. After adding water (1000 mL), the solid was filtered to obtain red-brown intermediate C (yield 28%).

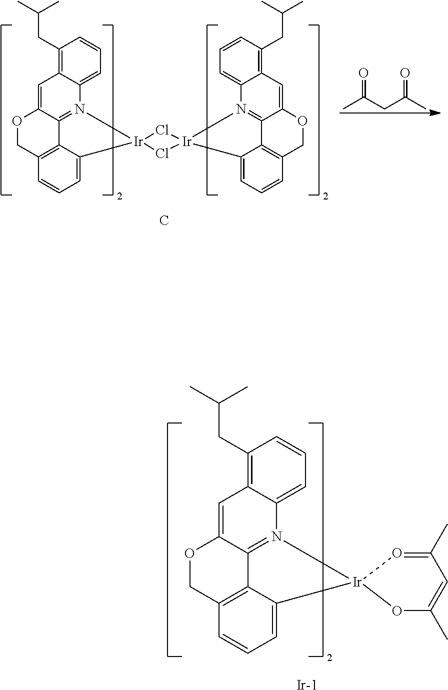

### Synthesis of Complex Ir-1

In an atmosphere filled with nitrogen, intermediate C (4 g, 1 eq), acetylacetone (2.5 g, 10 eq) and potassium carbonate (6.86 g, 20 eq) were placed in a 100 mL three-necked flask and then ethylene glycol ether (10 mL) was added into the flask, with stirring at 120° C. for 24 hours. Then water and dichloromethane were added for extraction, the lower organic solution was collected, and concentrated by vacuum distillation, then purified by silica gel with a mixture of petroleum ether to ethyl acetate in a ratio of 20:1, and the red component in maximum was obtained. The fraction was concentrated under reduced pressure, and recrystallized by an appropriate amount of ethanol to obtain salmon-colored complex Ir-1 (yield 13%).

### Synthesis Example 2: Synthesis of Complex Ir-2

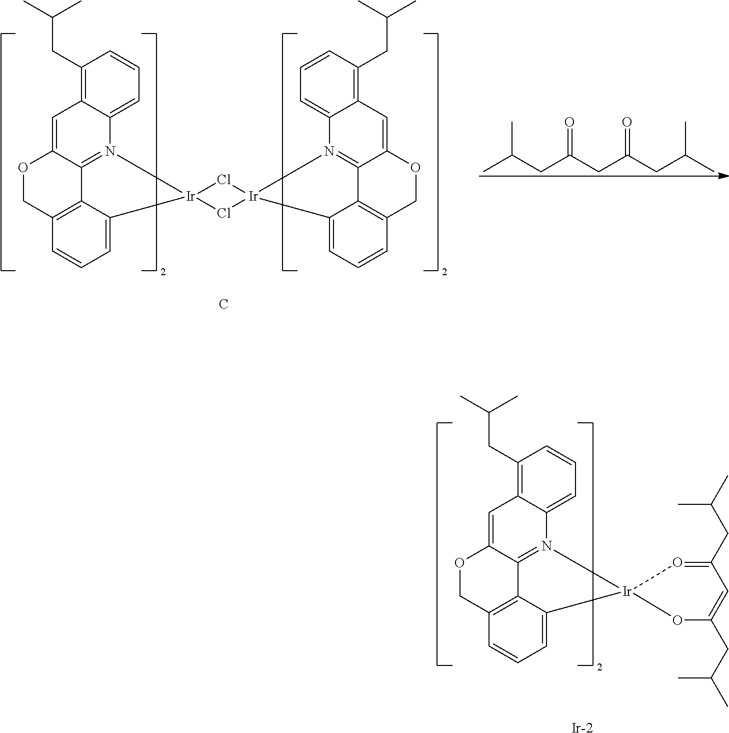

### Synthesis of Complex Ir-2

In an atmosphere filled with nitrogen, intermediate C (4 g, 1 eq), 2,8-dimethyl-4,6-nonanedione (4.58 g, 10 eq) and potassium carbonate (6.86 g, 20 eq) were placed in a 100 mL three-necked flask, and then ethylene glycol ether (10 mL) was added into the flask, with stirring at 120° C. for 24 hours. Then water and dichloromethane were added for extraction, the lower organic solution was collected, and concentrated by vacuum distillation, then purified by silica gel with a mixture of petroleum ether to ethyl acetate in a ratio of 20:1, and the red component in maximum was obtained. The fraction was concentrated under reduced pressure, and recrystallized by an appropriate amount of ethanol to obtain salmon-colored complex Ir-2 (yield 10%).

### Synthesis Example 3: Synthesis of Complex c-Ir-1

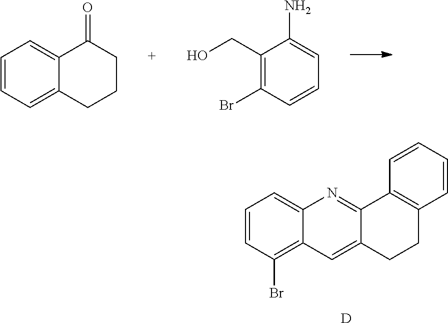

### Synthesis of Intermediate D

1-tetralone (1.70 g, 1.1 eq), 2-bromo-6-aminobenzyl alcohol (2 g, 1 eq), RuCl₂(pph₃)₃ (0.12 g, 0.01 eq), potassium hydroxide (1.43 g, 2 eq) were placed in a dry 250 mL two-necked flask. The flask was evacuated and filled with nitrogen and the cycle was repeated for three times. Then anhydrous toluene (100 mL) was added, and then the reaction was carried out at 120° C. for 24 hours with stirring. After the reaction liquid was spun dry, DCM was added for extraction. After concentration, the purification was carried out by column with EA:PE=1:2 to obtain pale white intermediate D (yield 73%).

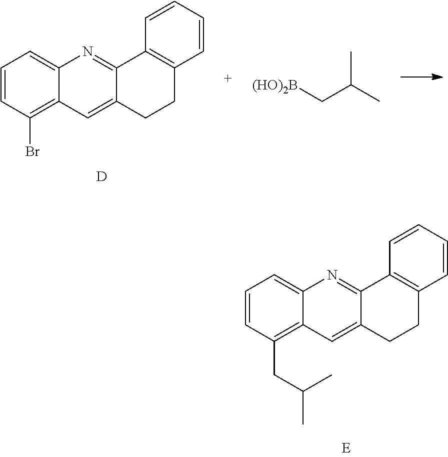

### Synthesis of Intermediate E

Intermediate D (1 g, 1 eq), isobutaneboronic acid (0.49 g, 1.5 eq), Pd₂(dba)₃ (0.09 g, 0.03 eq), S-phos (0.12 g, 0.06 eq), K₃PO₄ (2.73 g, 4 eq) were placed in a dry 250 mL two-necked flask. The flask was evacuated and filled with nitrogen and the cycle was repeated three times. Then anhydrous toluene (60 mL) was added, and then the reaction was carried out at 120° C. for 24 hours with stirring. After the reaction liquid was spun dry, DCM was added for extraction. After concentration, the purification was carried out by silica gel with DCM:PE=1:4 to obtain pale white intermediate B (yield 55%).

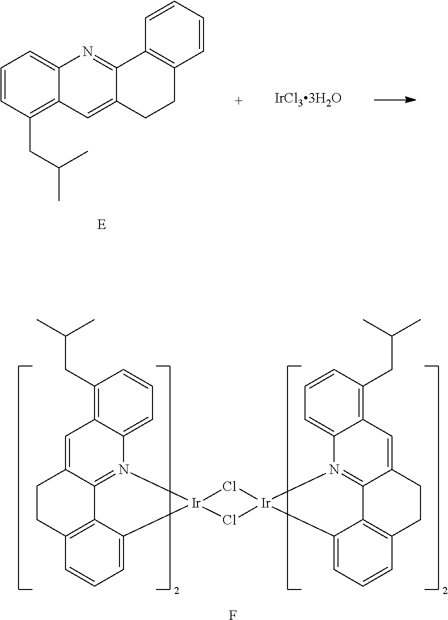

### Synthesis of Intermediate F

Intermediate E (1.49 g, 2.2 eq) and iridium trichloride trihydrate (0.83 g, 1 eq) were placed in a dry 250 ml flask. The flask was evacuated and filled with nitrogen and the cycle was repeated three times. Then a mixed solution (120 mL) of ethylene glycol ether:water in a ratio of 3:1 was added, the reaction was carried out at 110° C. for 24 hours with stirring. The water (1000 mL) was added, and the solid was filtered to obtain red-brown intermediate F (yield 19%).

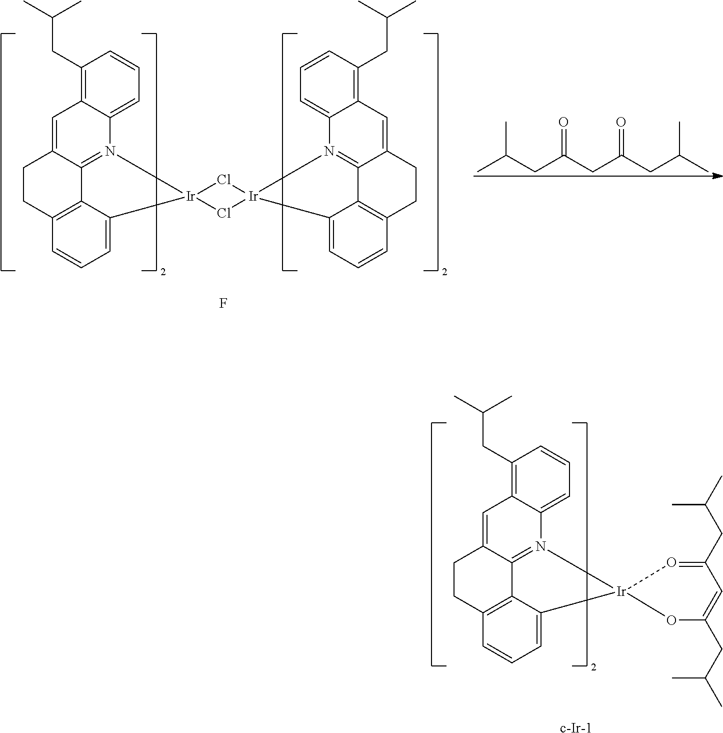

### Synthesis of Complex c-Ir-1

In an atmosphere filled with nitrogen, intermediate F (3.98 g, 1 eq), 2,8-dimethyl-4,6-nonanedione (4.58 g, 10 eq) and potassium carbonate (6.86 g, 20 eq) were placed in a 100 mL three-necked flask, and then ethylene glycol ether (10 mL) was added into the flask. The mixed solution was stirred at 120° C. for 24 hours. Then water and dichloromethane were added for extraction, the lower organic solution was collected, and concentrated by vacuum distillation, then purified by silica gel with a mixture of petroleum ether to ethyl acetate in a ratio of 20:1, and the red component in maximum was obtained. The fraction was concentrated under reduced pressure, and recrystallized by adding appropriate amount of ethanol to obtain salmon-colored complex c-Ir-1 (yield 15%).

### Synthesis Example 4: Synthesis of Complex c-Ir-2

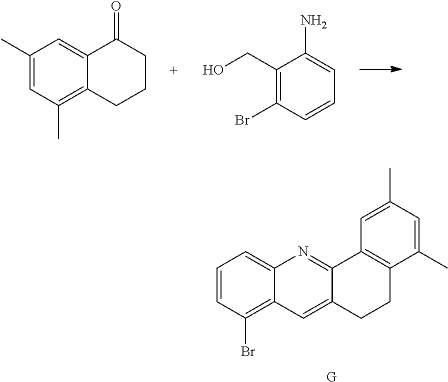

### Synthesis of Intermediate G

5,7-dimethyl-3,4-dihydro-2H-1-naphthalene (2.03 g, 1.1 eq), 2-bromo-6-aminobenzyl alcohol (2 g, 1 eq), RuCl₂(pph₃)₃ (0.12 g, 0.01 eq), potassium hydroxide (1.43 g, 2 eq) were placed in a dry 250 mL two-necked flask. The flask was evacuated and filled with nitrogen and the cycle was repeated for three times. Then anhydrous toluene (100 mL) was added, and then the reaction was carried out at 120° C. for 24 hours with stirring. After the reaction liquid was spun dry, DCM was added for extraction. After concentration, the purification was carried out by column with EA/PE=1:2 to obtain pale white intermediate G (yield 75%).

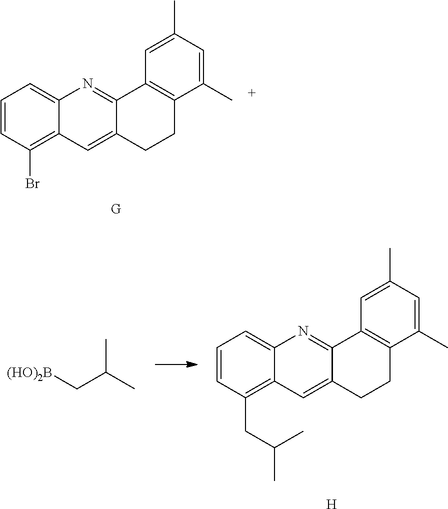

### Synthesis of Intermediate H

Intermediate G (1.1 g, 1 eq), isobutaneboronic acid (0.49 g, 1.5 eq), Pd₂(dba)₃ (0.09 g, 0.03 eq), S-phos (0.12 g, 0.06 eq), K₃PO₄ (2.73 g, 4 eq) were placed in a dry 250 mL two-necked flask. The flask was evacuated and filled with nitrogen and the cycle was repeated for three times. Then anhydrous toluene (60 mL) was added, and then the reaction was carried out at 120° C. for 24 hours with stirring. After the reaction liquid was spun dry, DCM was added for extraction. After concentration, the purification was carried out by silica gel with DCM/PE=1:4 to obtain pale white intermediate H (yield 47%).

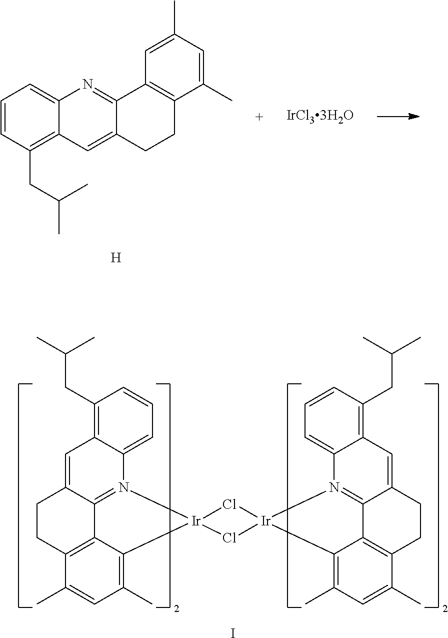

### Synthesis of Intermediate I

Intermediate H (1.63 g, 2.2 eq) and iridium trichloride trihydrate (0.83 g, 1 eq) were placed in a dry 250 ml flask. The flask was evacuated and filled with nitrogen and the cycle was repeated three times. Then a mixed solution (120 mL) of ethylene glycol ether:water in a ratio of 3:1 was added, the reaction was carried out at 110° C. for 24 hours with stirring. The water (1000 mL) was added, and the solid was filtered to obtain red-brown intermediate I (yield 24%).

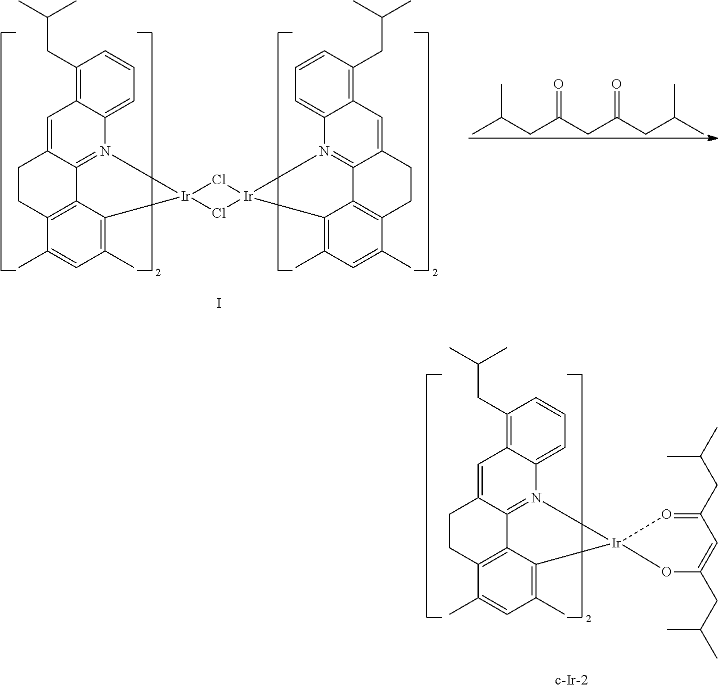

### Synthesis of Complex c-Ir-2

In an atmosphere filled with nitrogen, intermediate I (4.26 g, 1 eq), 2,8-dimethyl-4,6-nonanedione (4.58 g, 10 eq) and potassium carbonate (6.86 g, 20 eq) were placed in a 100 mL three-necked flask, and then ethylene glycol ether (10 mL) was added into the flask. The mixed solution was stirred at 120° C. for 24 hours. Then water and dichloromethane were added for extraction, the lower organic solution was collected, and concentrated by vacuum distillation, then purified by silica gel with a mixture of petroleum ether to ethyl acetate in a ratio of 20:1, and the red component in maximum was obtained. The fraction was concentrated under reduced pressure, and recrystallized by adding appropriate amount of ethanol to obtain salmon-colored complex c-Ir-2 (yield 18%).

### Synthesis Example 5: Synthesis of Complex c-Ir-3

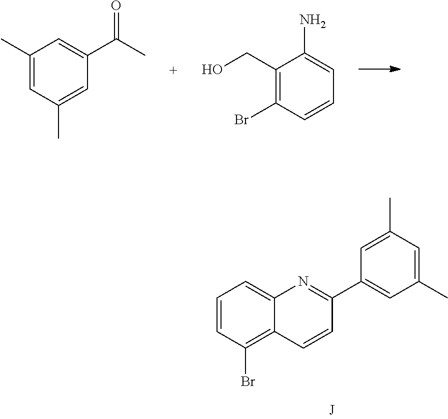 [SMILES: CC(=O)c1cc(C)cc(C)c1 ; Nc1cccc(Br)c1CO ; Cc1cc(C)cc(-c2ccc3c(Br)cccc3n2)c1]

### Synthesis of Intermediate J

3,5-dimethylacetophenone (1.72 g, 1.1 eq), 2-bromo-6-aminobenzyl alcohol (2 g, 1 eq), RuCl₂(pph₃)₃ (0.12 g, 0.01 eq), potassium hydroxide (1.43 g, 2 eq) were placed in a dry 250 mL two-necked flask. The flask was evacuated and filled with nitrogen and the cycle was repeated for three times. Then anhydrous toluene (100 mL) was added, and then the reaction was carried out at 120° C. for 24 hours with stirring. After the reaction liquid was spun dry, DCM was added for extraction. After concentration, the purification was carried out by column with EA/PE=1:2 to obtain pale white intermediate J (yield 80%).

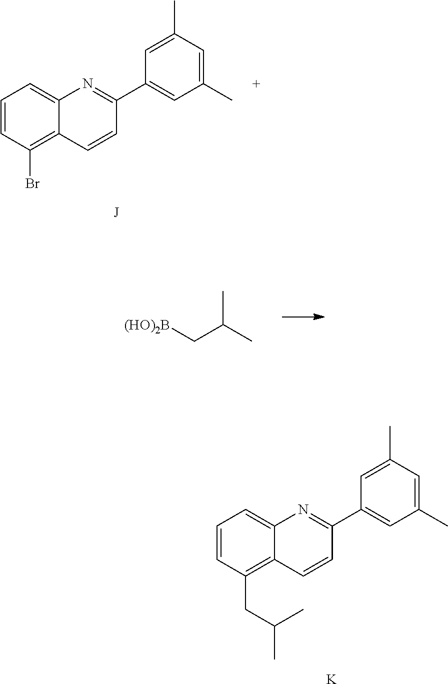

### Synthesis of Intermediate K

Intermediate J (1.04 g, 1 eq), isobutaneboronic acid (0.49 g, 1.5 eq), Pd₂(dba)₃ (0.09 g, 0.03 eq), S-phos (0.12 g, 0.06 eq), K₃PO₄ (2.73 g, 4 eq) were placed in a dry 250 mL two-necked flask. The flask was evacuated and filled with nitrogen and the cycle was repeated for three times. Then anhydrous toluene (60 mL) was added, and then the reaction was carried out at 120° C. for 24 hours with stirring. After the reaction liquid was spun dry, DCM was added for extraction. After concentration, the purification was carried out by silica gel with DCM/PE=1:4 to obtain pale white intermediate K (yield 58%).

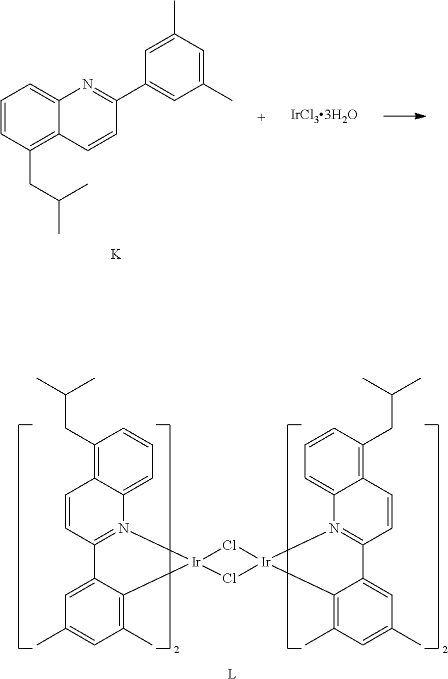

### Synthesis of Intermediate L

Intermediate K (1.50 g, 2.2 eq) and iridium trichloride trihydrate (0.83 g, 1 eq) were placed in a dry 250 ml flask. The flask was evacuated and filled with nitrogen and the cycle was repeated three times. Then a mixed solution (120 mL) of ethylene glycol ether:water in a ratio of 3:1 was added, the reaction was carried out at 110° C. for 24 hours with stirring. The water (1000 mL) was added, and the solid was filtered to obtain red-brown intermediate L (yield 34%).

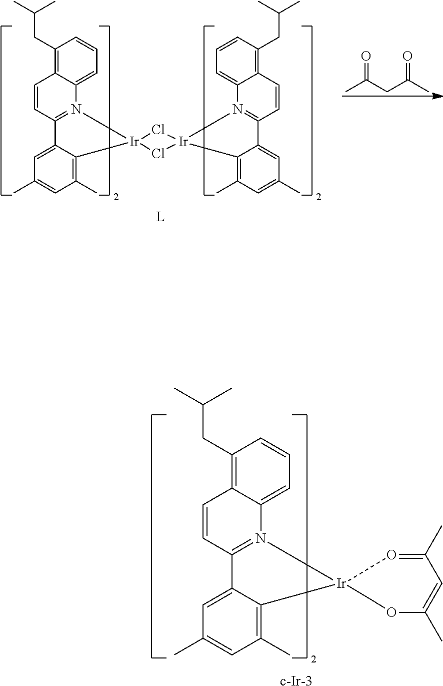

### Synthesis of Complex c-Ir-3

In an atmosphere filled with nitrogen, intermediate L (4.00 g, 1 eq), acetylacetone (2.5 g, 10 eq) and potassium carbonate (6.86 g, 20 eq) were placed in a 100 mL three-necked flask and then ethylene glycol ether (10 mL) was added into the flask. The mixed solution was stirred at 120° C. for 24 hours. Then water and dichloromethane were added for extraction, the lower organic solution was collected, and concentrated by vacuum distillation, then purified by silica gel with a mixture of petroleum ether to ethyl acetate in a ratio of 20:1, and the red component in maximum was obtained. The fraction was concentrated under reduced pressure, and recrystallized by adding appropriate amount of ethanol to obtain salmon-colored complex c-Ir-3 (yield 25%).

### 3, the Photophysical Properties of the Complexes

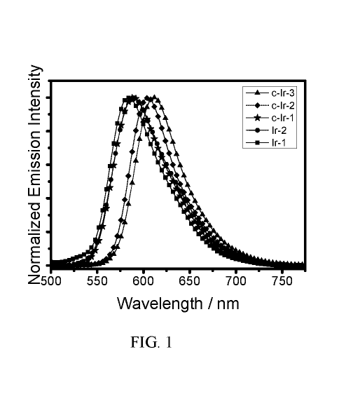

It can be seen from FIG. 1 that, from the PL spectrum of Ir-1, Ir-2, c-Ir-1, c-Ir-2 and c-Ir-3 in dichloromethane solution, the spectrum of all complexes exhibit narrow emission with a maximum peak of the emission spectrum between 550 and 650 nm, indicating that such complex is suitable for using in red-emitting electronic devices. The maximum luminous spectrum and half peak width of each example material are listed in table 2:

TABLE 2

| Materials | λMAX/nm | FWHM/nm |
|---|---|---|
| Ir-1 | 585 | 40 |
| Ir-2 | 590 | 43 |
| c-Ir-1 | 589 | 42 |
| c-Ir-2 | 607 | 32 |
| c-Ir-3 | 614 | 46 |

### 4. Preparation and Characterization of OLED Devices

The preparation steps of OLED devices containing ITO/NPD (60 nm)/15% Ir-1 to Ir-2:mCP (45 nm)/TPBi (35 nm)/LiF (1 nm)/A1 (150 nm)/cathode are as follows:

a. Cleaning of conductive glass substrates: when used for the first time, a variety of solvents, such as chloroform, ketone, and isopropyl alcohol, may be used for cleaning, followed by UV ozone plasma treatment;

b. HTL (60 nm), EML (45 nm), and ETL (35 nm): they were obtained by thermal evaporation in high vacuum (1×10⁻⁶ mbar);

c. preparing cathode: LiQ/Al (1 nm/150 nm) by thermal evaporation in a high vacuum (1×10−6 mbar);

d. encapsulating: encapsulating the device with UV curable resin in a glove box filled with nitrogen gas.

The current-voltage-luminance (JVL) characteristics of each OLED device are characterized by characterization equipment and important parameters such as efficiency and external quantum efficiency are recorded. The maximum external quantum efficiency of the OLED devices Ir-1 and Ir-2 were determined to be 8.4% and 8.7% respectively.

The structure of the OLED device may be further optimized, for example, the combination and the optimization of HTM, ETM and host material will further improve the properties of the device, especially efficiency, driving voltage and lifetime.

What is claimed is:

1. A transition metal complex for organic electronic devices having a structure represented by general formula (I): 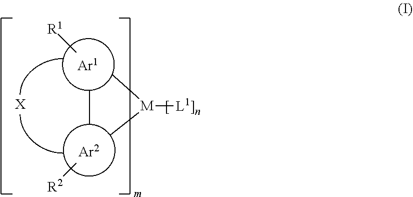
wherein
M is a metal atom selected from the group consisting of iridium, gold, platinum, ruthenium, rhodium, osmium, rhenium, nickel, copper, silver, zinc, tungsten or palladium;
m is selected from 1, 2, or 3;
L¹ is an auxiliary ligand selected from bidentate chelating ligand;
n is 0, 1 or 2;
Ar¹ is selected from the group consisting of an aromatic containing 5 to 20 ring atoms, a heteroaromatic containing 5 to 20 ring atoms, or a non-aromatic ring system containing 5 to 20 ring atoms; the Ar¹ has a substituent R¹, and the R¹ is the same or different in multiple occurrences;
Ar² is selected from the group consisting of an aromatic containing 5 to 20 ring atoms, a heteroaromatic containing 5 to 20 ring atoms, or a non-aromatic ring system containing 5 to 20 ring atoms; the Ar² has a substituent R², and the R² is the same or different in multiple occurrences;
X is selected from a non-aromatic doubly-bridging group;
the R¹ and the R² are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms.

2. The transition metal complex according to claim 1, wherein the R¹ and the R² are independently selected from the group consisting of hydrogen, deuterium, a linear alkyl group containing 1 to 20 carbon atoms, and a branched alkyl group containing 1 to 20 carbon atoms.

3. The transition metal complex according to claim 1, wherein the Ar¹ is selected from any one of the following groups: 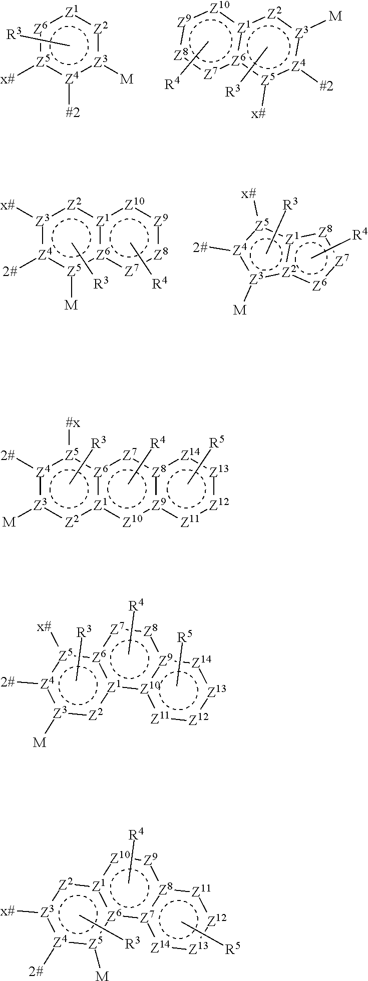 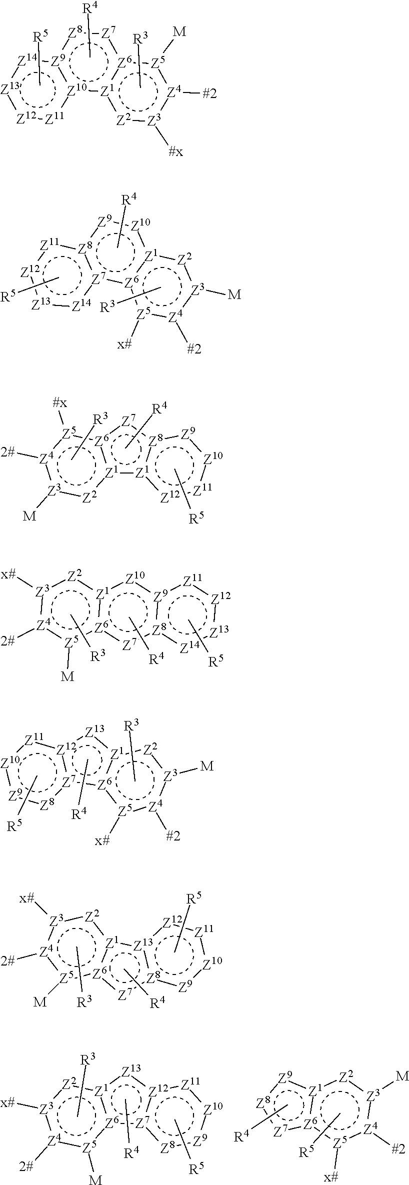 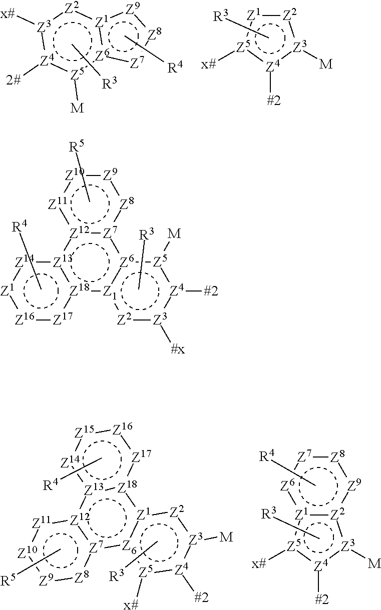
wherein #x indicates bonding to any one of the positions of the X; #2 indicates bonding to any one of the positions of the Ar²;
Z¹-Z¹⁸ independently contain at least one of the group consisting of nitrogen, oxygen, carbon, silicon, boron, sulfur and phosphorus atom;
R³-R⁵ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms.

4. The transition metal complex according to claim 1, wherein the Ar² is selected from any one of the following groups: 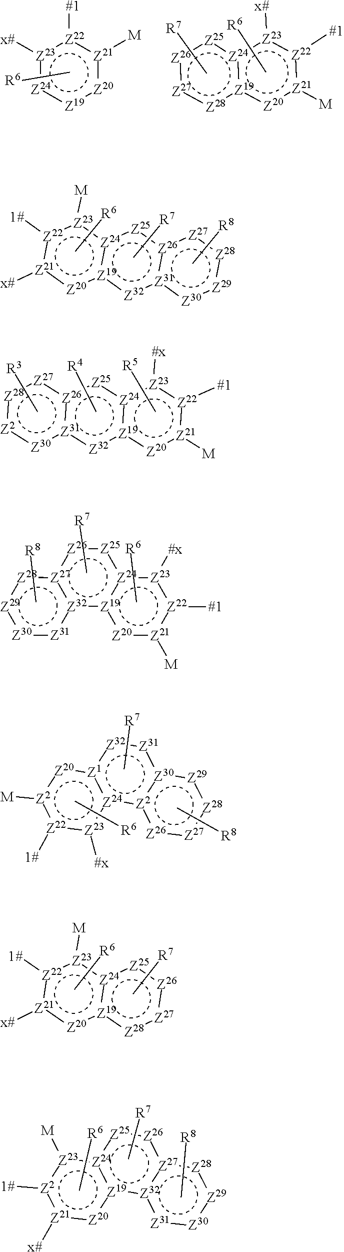 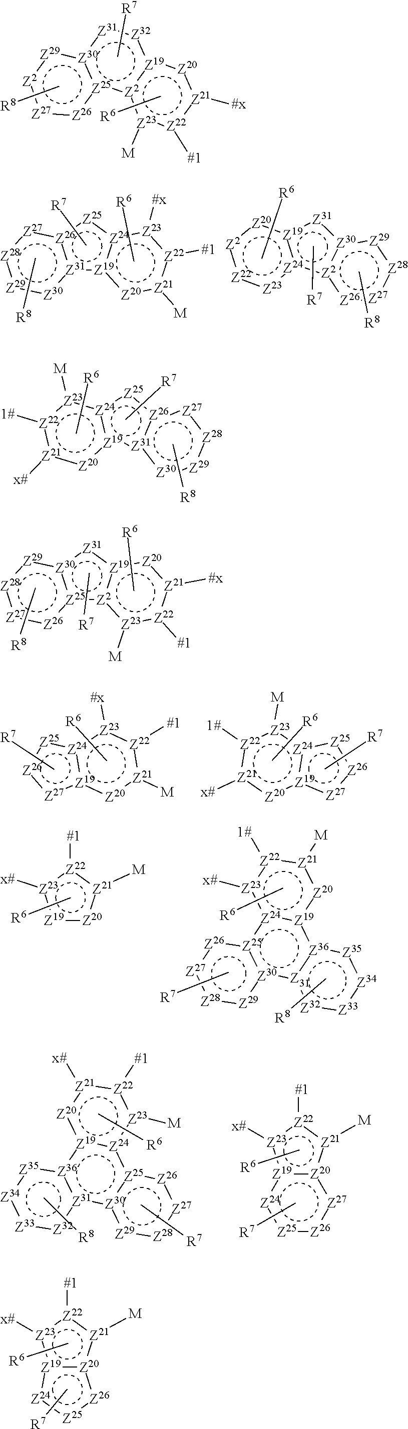
wherein #x indicates bonding to any one of the positions of the X; #1 indicates bonding to any one of the positions of the Ar¹;
Z¹⁹-Z³⁶ independently contain at least one of the group consisting of nitrogen, oxygen, carbon, silicon, boron, sulfur and phosphorus atom;
R⁶-R⁸ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms.

5. The transition metal complex according to claim 2, wherein the X is selected from any one of the following groups: 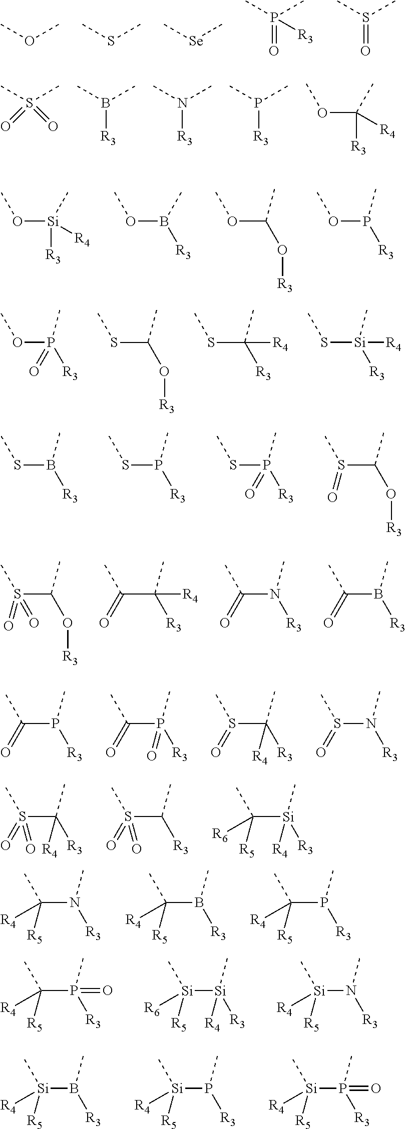 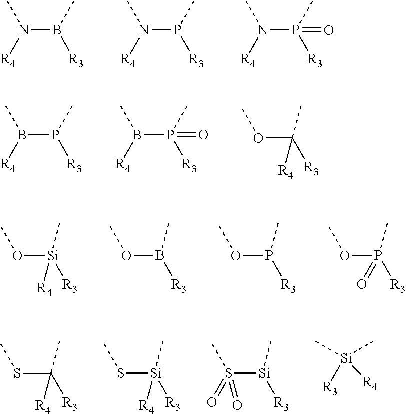
wherein, the R₃, R₄, and R₅, R₆ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms; the dotted line represents a bond bonded to the Ar¹ or Ar².

6. The transition metal complex according to claim 2, wherein the X is selected from any one of the following groups: 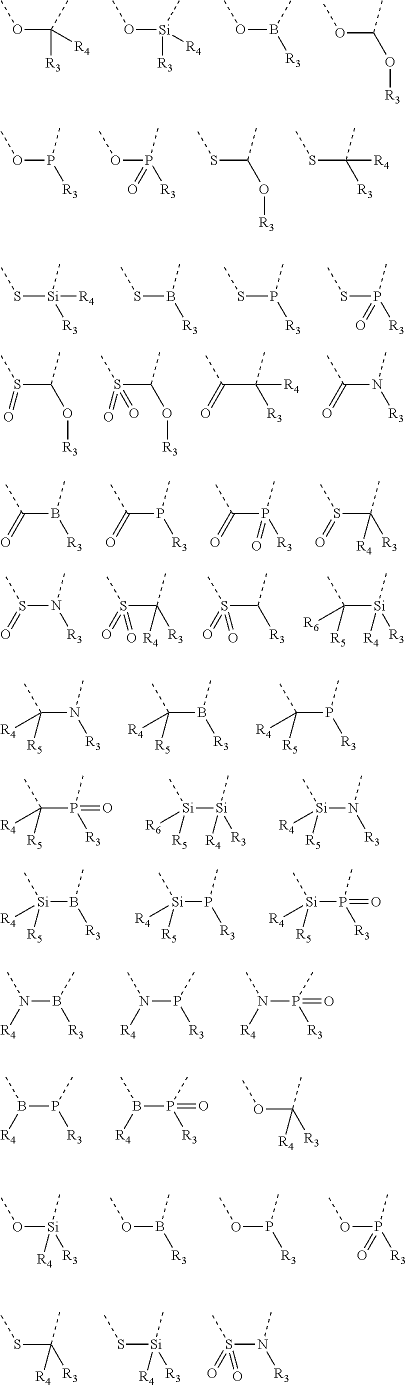
wherein, the R₃, R₄, and R₅, R₆ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms; the dotted line represents a bond bonded to the Ar¹ or Ar².

7. The transition metal complex according to claim 2, wherein the X is selected from the following groups: 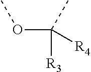
wherein, the R₃, and R₄ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms; the dotted line represents a bond bonded to the Ar¹ or Ar².

8. The transition metal complex according to claim 1, wherein the L¹ is selected from monoanionic bidentate chelating ligand.

9. The transition metal complex according to claim 8, wherein the L¹ is selected from any one of the following groups: 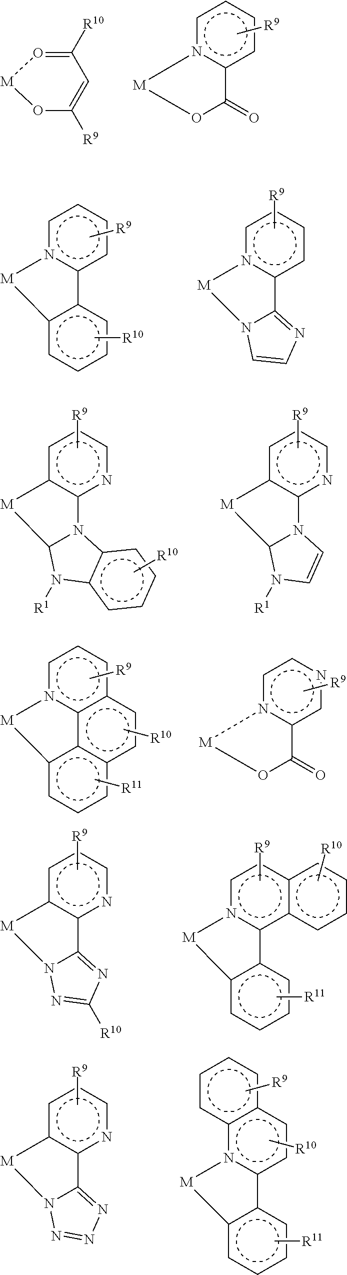 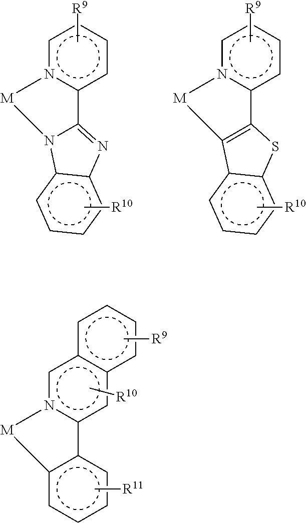
wherein, R⁹-R¹¹ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group containing 1 to 20 carbon atoms, an aromatic containing 1 to 20 carbon atoms, a heteroaromatic containing 1 to 20 carbon atoms or a non-aromatic ring system containing 1 to 20 carbon atoms.

10. The transition metal complex according to claim 1, wherein the transition metal complex is one selected from compounds represented by the general formulas (I-1) to (I-12): 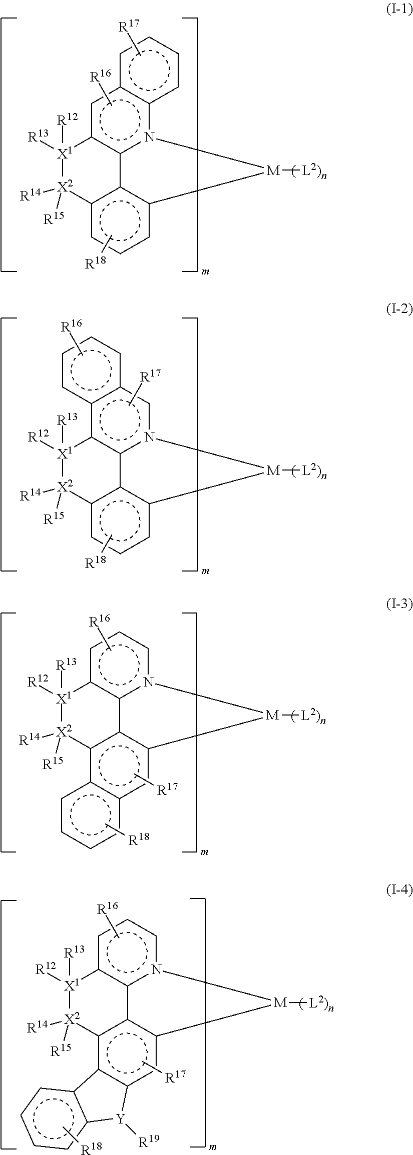 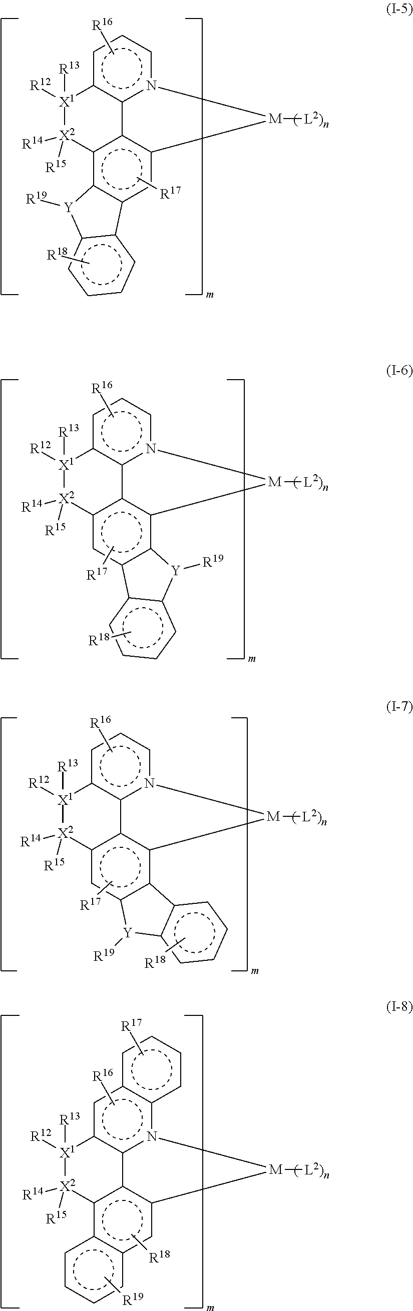 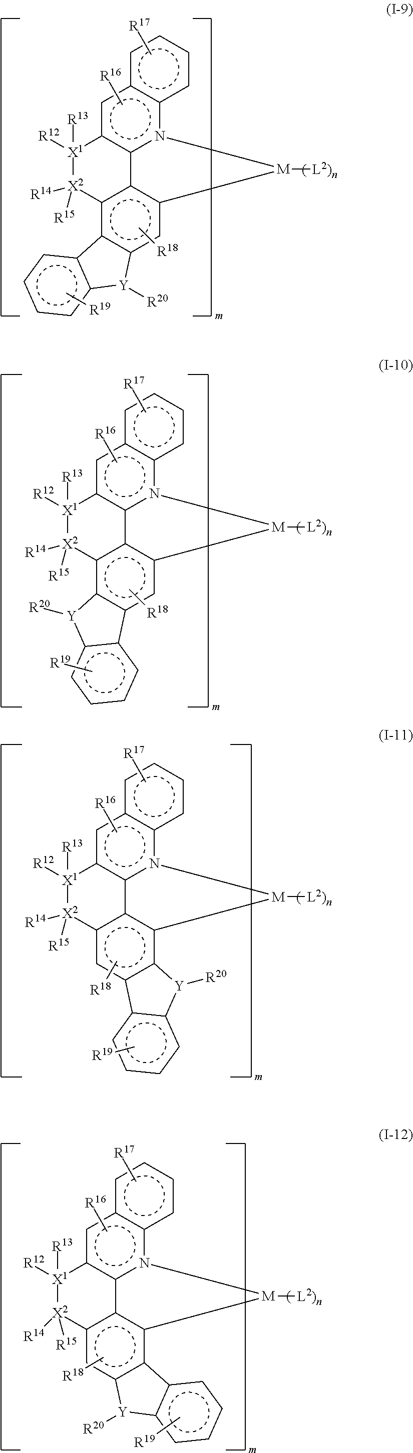
wherein X¹ and X² independently contain at least one non-carbon heteroatom selected from the group consisting of nitrogen, oxygen, silicon, boron, sulfur and phosphorus atoms;
Y is selected from the doubly-bridging group;
L² is an auxiliary ligand selected from bidentate chelating ligand;
R¹²-R²⁰ are independently selected from the group consisting of hydrogen, deuterium, a halogen atom, a linear alkyl group containing 1 to 20 carbon atoms, a branched alkyl group containing 1 to 20 carbon atoms, and a linear alkenyl group containing 1 to 20 carbon atoms, a branched alkenyl group containing 1 to 20 carbon atoms, an alkane ether group, an aromatic containing 1 to 20 carbon atoms, a heteroaromatic containing 1 to 20 carbon atoms or a non-aromatic ring system containing 1 to 20 carbon atoms.

11. The transition metal complex according to claim 10, R¹²-R²⁰ are independently selected from the group consisting of hydrogen, deuterium, a linear alkyl group containing 1 to 20 carbon atoms, and a branched alkyl group containing 1 to 20 carbon atoms.

12. The transition metal complex according to claim 11, wherein the X¹ and the X² are independently selected from different groups, and the X¹ or the X² comprise heteroatoms containing a non-carbon atom.

13. The transition metal complex according to claim 11, wherein the X¹ and the X² independently contain at least one oxygen atom.

14. The transition metal complex according to claim 1, M is a metal atom selected from the group consisting of iridium, gold and platinum.

15. The transition metal complex according to claim 1, M is a metal atom selected from iridium.

16. A mixture comprising at least one organic functional material or an organic solvent and the transition metal complex of claim 1, wherein the organic functional material is selected from the group consisting of hole injection material, hole transport material, electron transport material, electron injection material, electron blocking material, hole blocking material, emitter, host material, and doped material.

17. An organic electronic device comprising the transition metal complex of claim 1.

18. The organic electronic device according to claim 17, wherein the organic electronic device comprises a light-emitting layer, the light emitting layer comprises the transition metal complex.

19. The organic electronic device according to claim 17, wherein the organic electronic device is selected from the group consisting of organic light emitting diode, organic photovoltaic cell, organic light-emitting electrochemical cell, organic field effect transistor, organic light emitting field effect transistor, organic laser, organic spintronic device, organic sensor or organic plasmon emitting diode.
